(19) United States
(12) Patent Application Publication
(10) Pub. No.: US 2023/0276647 A1
(43) Pub. Date: Aug. 31, 2023

(54) LIGHT-EMITTING DEVICE, LIGHT-EMITTING APPARATUS, LIGHT-EMITTING MODULE, ELECTRONIC DEVICE, AND LIGHTING DEVICE

(71) Applicant: SEMICONDUCTOR ENERGY LABORATORY CO., LTD., Atsugi-shi, Kanagawa-ken (JP)

(72) Inventors: Yuta KAWANO, Yokohama, Kanagawa (JP); Airi UEDA, Zama, Kanagawa (JP); Takeyoshi WATABE, Atsugi, Kanagawa (JP); Nobuharu OHSAWA, Zama, Kanagawa (JP); Satoshi SEO, Sagamihara, Kanagawa (JP)

(21) Appl. No.: 18/005,981

(22) PCT Filed: Jul. 19, 2021
(86) PCT No.: PCT/IB2021/056481

§ 371 Date: Jan. 19, 2023

(30) Foreign Application Priority Data
Jul. 30, 2020 (JP) 2020-129055

(51) Int. Cl. H10K 50/15; H10K 50/858; H10K 85/60; H10K 85/30

(52) U.S. Cl. CPC H10K 50/156; H10K 50/858; H10K 85/633; H10K 85/636; H10K 85/657; H10K 85/6576; H10K 85/6572; H10K 85/654; H10K 85/342; H10K 2101/40

(57) ABSTRACT

A light-emitting device with high emission efficiency is provided. A light-emitting device with a low driving voltage is provided. The light-emitting device includes a first electrode, a first layer over the first electrode, a second layer over the first layer, a light-emitting layer over the second layer, and a second electrode over the light-emitting layer. The first layer includes a first organic compound, and the second layer includes a second organic compound. The proportion of carbon atoms forming bonds by the sp³ hybrid orbitals to the total number of carbon atoms in the first organic compound is higher than or equal to 23 percent and lower than or equal to 55 percent. The second organic compound contains fluorine.

### TECHNICAL FIELD

One embodiment of the present invention relates to optical devices such as a light-emitting device, a light-receiving device, and a light-emitting and light-receiving device. One embodiment of the present invention relates to apparatuses such as a light-emitting apparatus, a light-receiving apparatus, and a light-emitting and light-receiving apparatus. One embodiment of the present invention relates to modules such as a light-emitting module, a light-receiving module, a light-emitting and light-receiving module, a display module, and a lighting module. One embodiment of the present invention relates to an electronic device and a lighting device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Research and development has been actively conducted on light-emitting devices using organic electroluminescence (EL) phenomenon (also referred to as organic EL devices or organic EL elements). In a basic structure of an organic EL device, a layer including a light-emitting organic compound (hereinafter also referred to as a light-emitting layer) is sandwiched between a pair of electrodes. By application of voltage to the organic EL device, light emitted from the light-emitting organic compound can be obtained.

An organic EL device is suitable for a display apparatus because it has features such as ease of thinning and lightening, high-speed response to an input signal, and driving with a direct-current constant voltage source.

An organic EL device can be formed in a film form and thus can provide planar light emission. Accordingly, a large-area light-emitting device can be easily formed. This feature is difficult to obtain with a point light source typified by an LED (light-emitting diode) or a linear light source typified by a fluorescent lamp. Thus, an organic EL device also has great potential as a planar light source applicable to a lighting device and the like.

Organic EL devices have required further improvement in light extraction efficiency. Light attenuation due to reflection caused by a difference in refractive index between adjacent layers is a factor of a decrease in light extraction efficiency. In organic EL devices, the use of a low refractive index material can improve the light extraction efficiency. For example, Non-Patent Document 1 discloses an organic EL device including a layer with a low refractive index.

Meanwhile, it is difficult for a material used for an organic EL device to have both a low refractive index and high reliability or high heat resistance.

### REFERENCE

### Patent Document

[Patent Document 1] United States Patent Application Publication No. 2020/0176692

### SUMMARY OF THE INVENTION

### Problems to be Solved by the Invention

An object of one embodiment of the present invention is to provide a light-emitting device or a light-emitting and light-receiving device with high emission efficiency. An object of one embodiment of the present invention is to provide a light-emitting device or a light-emitting and light-receiving device with high light extraction efficiency. An object of one embodiment of the present invention is to provide a light-emitting device, a light-receiving device, or a light-emitting and light-receiving device with a low driving voltage. An object of one embodiment of the present invention is to provide a light-emitting device, a light-receiving device, or a light-emitting and light-receiving device with high heat resistance. An object of one embodiment of the present invention is to provide a light-emitting device, a light-receiving device, or a light-emitting and light-receiving device with a long lifetime. An object of one embodiment of the present invention is to provide a light-emitting device, a light-receiving device, or a light-emitting and light-receiving device with low power consumption.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a light-emitting device including a first electrode, a first layer over the first electrode, a second layer over the first layer, a light-emitting layer over the second layer, and a second electrode over the light-emitting layer. The first layer includes a first organic compound. The second layer includes a second organic compound. A proportion of carbon atoms forming bonds by sp³ hybrid orbitals to the total number of carbon atoms in the first organic compound is higher than or equal to 23% and lower than or equal to 55%. The second organic compound contains fluorine. A refractive index of a layer including the first organic compound with respect to light with a wavelength of 633 nm is higher than or equal to 1.45 and lower than or equal to 1.70.

Another embodiment of the present invention is a light-emitting device including a first electrode, a first layer over the first electrode, a second layer over the first layer, a light-emitting layer over the second layer, and a second electrode over the light-emitting layer. The first layer includes a first organic compound. The second layer includes a second organic compound. A glass transition temperature of the first organic compound is higher than or equal to 90° C. A refractive index of a layer including the first organic compound with respect to light with a wavelength of 633 nm is higher than or equal to 1.45 and lower than or equal to 1.70. The second organic compound contains fluorine.

The first organic compound is preferably an amine compound, further preferably a monoamine compound.

Another embodiment of the present invention is a light-emitting device including a first electrode, a first layer over the first electrode, a second layer over the first layer, a light-emitting layer over the second layer, and a second electrode over the light-emitting layer. The first layer includes a first organic compound. The second layer includes a second organic compound. The first organic compound is a monoamine compound. A refractive index of a layer including the first organic compound with respect to light with a wavelength of 633 nm is higher than or equal to 1.45 and lower than or equal to 1.70. The second organic compound contains fluorine.

The second layer may further include a third organic compound. The highest occupied molecular orbital (HOMO) level of the third organic compound is lower than a HOMO level of the first organic compound.

The light-emitting device having any of the above structures may further include a third layer. The third layer is positioned between the second layer and the light-emitting layer. The third layer includes the third organic compound. A HOMO level of the third organic compound is lower than a HOMO level of the first organic compound. Also in this case, the second layer may further include the third organic compound.

Another embodiment of the present invention is a light-emitting device including a first electrode, a first layer over the first electrode, a second layer over the first layer, a third layer over the second layer, a light-emitting layer over the third layer, and a second electrode over the light-emitting layer. The first layer includes a first organic compound. The second layer includes a second organic compound. The third layer includes a third organic compound. A HOMO level of the third organic compound is lower than a HOMO level of the first organic compound. A refractive index of a layer including the first organic compound is lower than a refractive index of a layer including the third organic compound. The second organic compound contains fluorine.

A difference between a refractive index of the layer including the first organic compound with respect to light with a wavelength of 633 nm and a refractive index of the layer including the third organic compound with respect to light with a wavelength of 633 nm is preferably greater than or equal to 0.05, further preferably greater than or equal to 0.1.

The second layer may further include the third organic compound. The third layer may further include the second organic compound.

The refractive index of the layer including the first organic compound with respect to light with a wavelength of 633 nm is preferably higher than or equal to 1.45 and lower than or equal to 1.70.

A glass transition temperature of the first organic compound is preferably higher than or equal to 90° C.

The first organic compound is preferably an amine compound, further preferably a monoamine compound.

The second organic compound preferably shows an electron-accepting property with respect to the third organic compound.

A proportion of carbon atoms forming bonds by sp³ hybrid orbitals to the total number of carbon atoms in the third organic compound is preferably higher than or equal to 23% and lower than or equal to 55%.

The refractive index of the layer including the third organic compound with respect to light with a wavelength of 633 nm is preferably higher than or equal to 1.45 and lower than or equal to 1.70.

A glass transition temperature of the third organic compound is preferably higher than or equal to 90° C.

The first layer is preferably in contact with the second layer.

The light-emitting device having any of the above structures may further include a fourth layer. The fourth layer is positioned between the first electrode and the first layer. The fourth layer includes the first organic compound and the second organic compound. The fourth layer is preferably in contact with the first electrode. The fourth layer is preferably in contact with the first layer.

A molecular weight of the first organic compound is preferably greater than or equal to 650 and less than or equal to 1200.

The first organic compound is preferably a triaryl monoamine compound.

An integral value of signals at lower than 4 ppm preferably exceeds an integral value of signals at 4 ppm or higher in a result of ¹H-NMR measurement of the first organic compound.

The first organic compound preferably includes at least one hydrocarbon group having 1 to 12 carbon atoms.

The first organic compound preferably includes at least one of an alkyl group having 3 to 8 carbon atoms and a cycloalkyl group having 6 to 12 carbon atoms.

The second organic compound preferably includes a cyano group.

The lowest unoccupied molecular orbital (LUMO) level of the second organic compound is preferably lower than or equal to −5.0 eV.

The second organic compound preferably shows an electron-accepting property with respect to the first organic compound.

The second organic compound preferably includes no metal element.

One embodiment of the present invention is an apparatus including the light-emitting device having any of the above structures, and at least one of a transistor and a substrate.

One embodiment of the present invention is a light-emitting module including the light-emitting apparatus, and at least one of a connector and an integrated circuit (IC). Examples of the connector include a flexible printed circuit (hereinafter referred to as an FPC) and a TCP (Tape Carrier Package). The IC can be mounted on an apparatus by a COG (Chip On Glass) method or a COF (Chip On Film) method. Note that the light-emitting module of one embodiment of the present invention may include only one of a connector and an IC or may include both of them.

One embodiment of the present invention is an electronic device including the above light-emitting apparatus and at least one of an antenna, a battery, a housing, a camera, a speaker, a microphone, and an operation button.

One embodiment of the present invention is a lighting device including the light-emitting device having any of the above structures and at least one of a housing, a cover, and a support base.

### Effect of the Invention

One embodiment of the present invention can provide a light-emitting device or a light-emitting and light-receiving device with high emission efficiency. One embodiment of the present invention can provide a light-emitting device or a light-emitting and light-receiving device with high light extraction efficiency. One embodiment of the present invention can provide a light-emitting device, a light-receiving device, or a light-emitting and light-receiving device with a low driving voltage. One embodiment of the present invention can provide a light-emitting device, a light-receiving device, or a light-emitting and light-receiving device with high heat resistance. One embodiment of the present invention can provide a light-emitting device, a light-receiving device, or a light-emitting and light-receiving device with a long lifetime. One embodiment of the present invention can provide a light-emitting device, a light-receiving device, or a light-emitting and light-receiving device with low power consumption.

Note that the description of the effects does not preclude the existence of other effects. One embodiment of the present invention does not need to have all the effects. Other effects can be derived from the descriptions of the specification, the drawings, and the claims.

### BRIEF DESCRIPTION OF THE DRAWINGS

FIG. 1A to FIG. 1E are cross-sectional views illustrating examples of light-emitting devices.

FIG. 2A is a top view illustrating an example of a light-emitting apparatus. FIG. 2B and FIG. 2C are cross-sectional views illustrating examples of the light-emitting apparatus.

FIG. 3A and FIG. 3C are cross-sectional views illustrating examples of light-emitting apparatuses.

FIG. 3B is a cross-sectional view illustrating examples of light-emitting devices.

FIG. 4A and FIG. 4B are cross-sectional views illustrating examples of light-emitting apparatuses.

FIG. 5A is a top view illustrating an example of a light-emitting apparatus. FIG. 5B is a cross-sectional view illustrating an example of the light-emitting apparatus. FIG. 5C and FIG. 5D are cross-sectional views of examples of transistors.

FIGS. 6A and 6B are cross-sectional views illustrating examples of light-emitting devices. FIG. 6C and FIG. 6D are diagrams illustrating examples of light-emitting and light-receiving apparatuses.

FIG. 7A to FIG. 7C are cross-sectional views illustrating examples of display apparatuses.

FIG. 8A to FIG. 8D are diagrams illustrating examples of electronic devices.

FIG. 9A to FIG. 9F are diagrams illustrating examples of electronic devices.

FIG. 10A to FIG. 10C are diagrams illustrating examples of automobiles.

FIG. 11A to FIG. 11E are diagrams illustrating examples of electronic devices.

FIG. 12 is a cross-sectional view illustrating a light-emitting device in Example.

FIG. 13 is a diagram showing measurement results of refractive indices of dchPAF and PCBBiF.

FIG. 14 is a diagram showing luminance-current density characteristics of light-emitting devices in Example 1.

FIG. 15 is a diagram showing current efficiency-luminance characteristics of light-emitting devices in Example 1.

FIG. 16 is a diagram showing current density-voltage characteristics of light-emitting devices in Example 1.

FIG. 17 is a diagram showing external quantum efficiency-luminance characteristics of light-emitting devices in Example 1.

FIG. 18 is a diagram showing emission spectra of light-emitting devices in Example 1.

FIG. 19 is a diagram showing results of reliability tests of light-emitting devices in Example 1.

FIG. 20 is a diagram showing measurement results of refractive indices of mmtBumTPoFBi-04.

FIG. 21 is a diagram showing luminance-current density characteristics of light-emitting devices in Example 2.

FIG. 22 is a diagram showing current efficiency-luminance characteristics of light-emitting devices in Example 2.

FIG. 23 is a diagram showing current density-voltage characteristics of light-emitting devices in Example 2.

FIG. 24 is a diagram showing external quantum efficiency-luminance characteristics of light-emitting devices in Example 2.

FIG. 25 is a diagram showing emission spectra of light-emitting devices in Example 2.

### MODE FOR CARRYING OUT THE INVENTION

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”.

### Embodiment 1

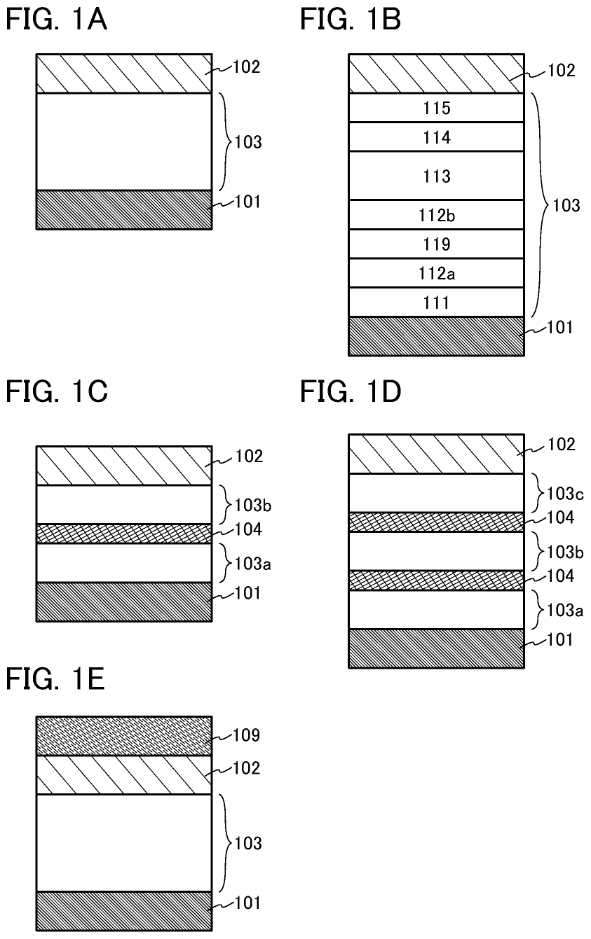

In this embodiment, a light-emitting device of one embodiment of the present invention will be described with reference to FIG. 1.

An organic EL device can have higher external quantum efficiency by using a material with a lower refractive index. In order to obtain a material with a low refractive index, a substituent with low atomic refraction is preferably introduced into a molecule. Examples of the substituent include a chain saturated hydrocarbon group and a cyclic saturated hydrocarbon group. However, these substituents hinder exhibition of a carrier-transport property. Thus, it is difficult to achieve both a high carrier-transport property and a low refractive index.

Furthermore, a material used for the organic EL device preferably has a high glass transition temperature (Tg) to increase the reliability of the organic EL device. The material needs to have a higher molecular weight to have a higher glass transition temperature. One of the possible methods for obtaining a material with high heat resistance and high reliability is introducing an unsaturated hydrocarbon group, particularly a cyclic unsaturated hydrocarbon group, into a molecule. However, introduction of a skeleton having an unsaturated bond into a molecule to increase the molecular weight results in a high refractive index of the material. Thus, it is also difficult to achieve both a high glass transition temperature and a low refractive index.

Among hole-transport materials that can be used for an organic EL device, 1,1-bis-(4-bis(4-methyl-phenyl)-amino-phenyl)-cyclohexane (abbreviation: TAPC), which is a material with a low refractive index, is known. With the use of TAPC, a light-emitting device with favorable external quantum efficiency is expected to be obtained.

In general, a high carrier-transport property and a low refractive index have a trade-off relationship. This is because the carrier-transport property of an organic compound largely depends on an unsaturated bond, and an organic compound having many unsaturated bonds tends to have a high refractive index. TAPC is a substance having a perfect balance between a carrier-transport property and a low refractive index. Meanwhile, in a compound including 1,1-disubstituted cyclohexane, such as TAPC, two bulky substituents are bonded to a carbon atom of cyclohexane; thus, steric repulsion becomes larger and instability of the molecule itself is induced, which is disadvantageous in terms of reliability. In addition, TAPC has a skeleton structure including cyclohexane and simple benzene rings and thus has a low glass transition temperature of 85° C. and a heat resistance problem.

As described above, it is not easy for a hole-transport material to increase the glass transition temperature for higher heat resistance and to improve reliability at the time of driving while achieving both a high carrier-transport property and a low refractive index. In order to overcome such a trade-off, the present inventors have found an organic compound having a high glass transition temperature, in which the proportion of carbon atoms forming bonds by the sp³ hybrid orbitals is within a certain range. Then, the present inventors have found a structure of a light-emitting device that includes a layer including the organic compound and has high emission efficiency and a low driving voltage.

Specifically, one embodiment of the present invention is a light-emitting device including a first electrode, a first layer over the first electrode, a second layer over the first layer, a light-emitting layer over the second layer, and a second electrode over the light-emitting layer. The first layer includes a first organic compound, and the second layer includes a second organic compound. The proportion of carbon atoms forming bonds by the sp³ hybrid orbitals to the total carbon atoms in the first organic compound is higher than or equal to 23% and lower than or equal to 55%. The second organic compound contains fluorine.

Another embodiment of the present invention is a light-emitting device including the first electrode, the first layer over the first electrode, the second layer over the first layer, the light-emitting layer over the second layer, and the second electrode over the light-emitting layer. The first layer includes the first organic compound, and the second layer includes the second organic compound. The glass transition temperature of the first organic compound is higher than or equal to 90° C. The refractive index of the layer including the first organic compound with respect to light with a wavelength of 633 nm is higher than or equal to 1.45 and lower than or equal to 1.70. The second organic compound contains fluorine.

Another embodiment of the present invention is a light-emitting device including the first electrode, the first layer over the first electrode, the second layer over the first layer, the light-emitting layer over the second layer, and the second electrode over the light-emitting layer. The first layer includes the first organic compound, and the second layer includes the second organic compound. The first organic compound is a monoamine compound. The refractive index of the layer including the first organic compound with respect to light with a wavelength of 633 nm is higher than or equal to 1.45 and lower than or equal to 1.70. The second organic compound contains fluorine.

In order to have a low refractive index, the first organic compound includes a substituent (one or both of a chain saturated hydrocarbon group and a cyclic saturated hydrocarbon group) containing carbon atoms forming bonds by the sp³ hybrid orbitals. These substituents are often bulky, and thus are likely to generate a carrier injection barrier (hole injection barrier here) between the first layer and an adjacent layer.

In view of this, in the light-emitting device of one embodiment of the present invention, the second layer including the second organic compound is provided between the first layer and the light-emitting layer.

The second organic compound shows an electron-accepting property with respect to the first organic compound. Thus, interaction is caused between the first organic compound and the second organic compound, whereby a charge-transfer complex is formed. This facilitates hole injection from the first layer to the light-emitting layer.

Providing the second layer in this manner enables smooth hole transport from the first layer to the light-emitting layer and a low driving voltage of the light-emitting device.

In particular, the second layer is preferably provided in contact with the first layer. As described above, a hole-injection barrier is likely to be generated between the first layer and an adjacent layer. With a structure where the first layer and the second layer are in contact with each other, the barrier can be reduced.

The second layer may include both the second organic compound and the third organic compound.

The second organic compound preferably shows an electron-accepting property with respect to the third organic compound. In addition, interaction is preferably caused between the second organic compound and the third organic compound to form a charge-transfer complex. This facilitates hole injection from the first layer to the light-emitting layer.

Alternatively, the second organic compound preferably shows an electron-accepting property with respect to both the first organic compound and the third organic compound. In addition, interaction is preferably caused between the second organic compound and at least one of the first organic compound and the third organic compound to form a charge-transfer complex. This facilitates hole injection from the first layer to the light-emitting layer.

The refractive index of the layer including the first organic compound is preferably lower than the refractive index of the layer including the third organic compound. In this case, a difference between the refractive index of the layer including the first organic compound with respect to light with a wavelength of 633 nm and the refractive index of the layer including the third organic compound with respect to light with a wavelength of 633 nm is preferably greater than or equal to 0.05, further preferably greater than or equal to 0.1, still further preferably greater than or equal to 0.15.

As described above, the second organic compound is an organic compound containing fluorine, for example, and is preferably an organic compound including a cyano group.

The lowest unoccupied molecular orbital (LUMO) level of the second organic compound is preferably lower than or equal to −5.0 eV.

When the second organic compound emits light, the amount of light emitted by a light-emitting substance contained in the light-emitting layer is reduced, resulting in a decrease in emission efficiency of the light-emitting device. For this reason, it is preferable that light emission from the second organic compound be not observed.

When a difference between the highest occupied molecular orbital (HOMO) level of the first organic compound and the HOMO level of the material (typically host material) used for the light-emitting layer is large, a hole injection barrier particularly becomes high and the driving voltage is likely to increase. Also in this case, providing the second layer between the first layer and the light-emitting layer enables smooth hole transport from the first layer to the light-emitting layer and a low driving voltage of the light-emitting device.

As the third organic compound, a hole-transport material and an electron-blocking material can be used. In particular, the third organic compound preferably has both a hole-transport property and an electron-blocking property. The third organic compound preferably has a low electron-injection property and a low electron-transport property.

The HOMO level of the third organic compound is preferably lower than the HOMO level of the first organic compound. In addition, the LUMO level of the third organic compound is preferably higher than the LUMO level of a material having the lowest LUMO level among the materials contained in the light-emitting layer.

The light-emitting device of one embodiment of the present invention may include a third layer between the second layer and the light-emitting layer. The third layer includes the third organic compound. The third layer is preferably in contact with the second layer.

Here, a case is considered where the second layer is not provided and the third layer is provided over the first layer. In this case, the driving voltage of the light-emitting device can be lower as the HOMO level of the third organic compound is higher. However, in the case of a light-emitting device that emits green phosphorescent light or phosphorescent light with a shorter wavelength than green light, the high HOMO level of the third organic compound facilitates formation of an exciplex between the third organic compound and the host material in the light-emitting layer, which might decrease the emission efficiency. Meanwhile, the low HOMO level of the third organic compound can increase the emission efficiency, but increases a hole-injection barrier between the first layer and the third layer, which results in a high driving voltage.

Furthermore, the first organic compound includes a substituent that hinders a carrier-transport property, such as a saturated hydrocarbon group not having a π orbital, which significantly reduces the property of carrier injection to the third organic compound and accordingly increases the driving voltage of the light-emitting device.

As described above, the light-emitting device of one embodiment of the present invention includes the second layer including the second organic compound between the first layer and the third layer. Accordingly, hole transport from the first layer to the light-emitting layer can be smooth even when the HOMO level of the third organic compound is low, so that the light-emitting device can have both high emission efficiency and a low driving voltage. Alternatively, hole transport from the first layer to the light-emitting layer can be smooth even when an organic compound having a low refractive index and a poor carrier-injection property is used for the first layer, so that the light-emitting device can have both high emission efficiency and a low driving voltage.

The third layer may include both the second organic compound and the third organic compound.

Note that the above structure can be employed for not only the light-emitting device, but also a light-receiving device such as an organic photodiode, a light-emitting and light-receiving device having light-emitting and light-receiving functions, and the like.

The light-emitting device of one embodiment of the present invention may further include a fourth layer between the first electrode and the first layer. The fourth layer includes the first organic compound and the second organic compound.

For the light-emitting device of one embodiment of the present invention, a composite material including the above-described first organic compound and second organic compound can be used.

The composite material can be used for a hole-injection layer, a hole-transport layer, a charge-generation layer, or the like of the light-emitting device. Alternatively, the composite material can be used as a carrier-transport material (hole-transport material) in a light-receiving device, a light-emitting and light-receiving device, and the like.

For a hole-injection layer and a charge-generation layer of an organic EL device, a composite material containing a hole-transport material and a material having an electron-accepting property with respect to the hole-transport material can be used, for example. In order that these layers have a hole-injection property or a charge-generation function, interaction needs to be caused between materials contained in the composite material to form a charge-transport exciplex.

Here, when the composite material contains a large amount of material having an electron-accepting property, light in the visible light region is absorbed and the emission efficiency of the organic EL device might decrease. Thus, the composite material preferably contains a hole-transport material more than a material having an electron-accepting property. For example, for the light-emitting device of one embodiment of the present invention, it is possible to use a composite material obtained by adding a slight amount of material having an electron-accepting property to a hole-transport material.

Since a lower refractive index of the material used for the organic EL device can increase the external quantum efficiency, the refractive index of the composite material is also desirably low. When the first organic compound that accounts for the major parts of the composite material has a low refractive index, the composite material can have a low refractive index.

### [First Organic Compound]

The proportion of carbon atoms forming bonds by the sp³ hybrid orbitals to the total carbon atoms in the first organic compound is preferably higher than or equal to 23% and lower than or equal to 55%. A substituent containing carbon atoms forming bonds by the sp³ hybrid orbitals is what is called a chain saturated hydrocarbon group or a cyclic saturated hydrocarbon group, and thus has low atomic refraction. Accordingly, the first organic compound can have a low refractive index.

The glass transition temperature of the first organic compound is preferably higher than or equal to 90° C., further preferably higher than or equal to 95° C., still further preferably higher than or equal to 100° C., yet further preferably higher than or equal to 110° C., and yet still further preferably higher than or equal to 120° C.

When including a cyclic saturated hydrocarbon group or a rigid tertiary hydrocarbon group, the first organic compound can maintain its glass transition temperature high and can have high heat resistance. In general, a compound to which a saturated hydrocarbon group, especially a chain saturated hydrocarbon group is introduced tends to decrease in at least one of the glass transition temperature and the melting point as compared with the case of introducing an equivalent aromatic group or heteroaromatic group (which is equivalent in the number of carbon atoms, for example). The lower glass transition temperature sometimes leads to lower heat resistance of an organic EL material. A variety of devices formed using the organic EL material is desired to show stable physical properties under various usage environments; thus, a material with a higher glass transition temperature is preferable among materials having substantially the same properties.

The refractive index of the layer including the first organic compound with respect to light with a wavelength of 633 nm is preferably higher than or equal to 1.45 and lower than or equal to 1.70. Note that the wavelength of 633 nm is usually used for refractive index measurement. The refractive index of the layer including the first organic compound with respect to a wavelength in the blue-light-emitting region (greater than or equal to 455 nm and less than or equal to 465 nm) is preferably higher than or equal to 1.50 and lower than or equal to 1.75. The refractive index of the layer including the first organic compound with respect to a wavelength in the green-light-emitting region (greater than or equal to 525 nm and less than or equal to 535 nm) is preferably higher than or equal to 1.48 and lower than or equal to 1.73. Note that in the case where the material has anisotropy, the refractive index with respect to an ordinary ray sometimes differs from the refractive index with respect to an extraordinary ray. In this case, the ordinary refractive index and the extraordinary refractive index can be separately calculated by performing anisotropy analysis. In this specification, when the measured material has both the ordinary refractive index and the extraordinary refractive index, the ordinary refractive index is used as an indicator.

Note that the first organic compound may be evaluated with the use of, as the refractive index of the layer including the first organic compound, a refractive index with respect to the peak wavelength of light emitted from the light-emitting device including the first organic compound or the peak wavelength of light emitted from the light-emitting substance contained in the light-emitting device. Also in this case, the refractive index of the layer including the first organic compound is preferably higher than or equal to 1.50 and lower than or equal to 1.75, higher than or equal to 1.48 and lower than or equal to 1.73, or higher than or equal to 1.45 and lower than or equal to 1.70. In the case where the light-emitting device is provided with a light-adjusting structure such as a color filter, the peak wavelength of the light emitted from the light-emitting device is a peak wavelength of the light not passing through the structure. The peak wavelength of light emitted from the light-emitting substance is calculated from a PL spectrum in a solution state. Since the dielectric constant of the organic compound included in the EL layer of the light-emitting device is approximately 3, in order to prevent inconsistency with the emission spectrum of the light-emitting device, the dielectric constant of the solvent for bringing the emission center substance into a solution state is preferably greater than or equal to 1 and less than or equal to 10, further preferably greater than or equal to 2 and less than or equal to 5 at room temperature. Specific examples of the solution include hexane, benzene, toluene, diethyl ether, ethyl acetate, chloroform, chlorobenzene, and dichloromethane. It is further preferable that the solution be a solvent that has a dielectric constant greater than or equal to 2 and less than or equal to 5 at room temperature, has high solubility, and is versatile. As the solution, toluene or chloroform is preferably used, for example.

The first organic compound is preferably an amine compound, further preferably a monoamine compound, still further preferably a triaryl monoamine compound.

When the first organic compound is an amine compound, the HOMO level is easily controlled to a desired level by adjusting the substitution site of an alky group, which is preferable.

In the first organic compound, the alkyl group is preferably bonded in the same plane as a plane forming the HOMO or in the vicinity thereof. That is, the alkyl group is preferably placed at a position where the HOMO is not blocked. In the case where the first organic compound is an aromatic amine compound, the plane forming the HOMO is, for example, a plane of an aromatic ring to which nitrogen is bonded. The alkyl group is preferably a tert-butyl group or a cyclohexyl group.

The first organic compound preferably includes an alkyl group functioning as an electron-donating group which is in a bonding position such that the HOMO energy is further unstabilized. For example, the alkyl group is preferably bonded at the para position of a nitrogen atom of triphenylamine. Accordingly, the HOMO level of the first organic compound can be high (shallow).

The first organic compound preferably includes a skeleton having a high carrier-transport property; in particular, an aromatic amine skeleton is a preferable skeleton because of its high hole-transport property. For further improvement in carrier-transport property, introduction of two amine skeletons can be considered as another method. However, as in the above-described TAPC, the diamine structure sometimes adversely affects the reliability depending on the substituents arranged around the amine skeletons.

As a compound that overcomes the trade-off and has a high carrier-transport property, a low refractive index, and high reliability, the present inventors have found a monoamine compound in which the proportion of carbon atoms forming bonds by the sp³ hybrid orbitals is within a certain range. In particular, the monoamine compound has high reliability equivalent to those of conventional hole-transport materials with a normal refractive index. Furthermore, the monoamine compound can be a material having more favorable characteristics when at least one of the number and position of substituents (e.g., an alkyl group and a cycloalkyl group) containing the carbon atoms forming bonds by the sp³ hybrid orbitals is adjusted. When the number of aromatic groups bonded to a saturated hydrocarbon group in a monoamine compound is limited to reduce the steric repulsion, the molecular stability can be increased. Thus, an optical device with a favorable lifetime can be obtained.

The molecular weight of the first organic compound is preferably greater than or equal to 650 and less than or equal to 1200. This can increase heat resistance of the first organic compound.

The integral value of signals at lower than 4 ppm preferably exceeds the integral value of signals at 4 ppm or higher in the results of ¹H-NMR measurement of the first organic compound.

The signals at lower than 4 ppm represent hydrogen in chain or cyclic saturated hydrocarbon groups, and the integral value of the signals exceeding that of the signals at 4 ppm or higher indicates that the number of hydrogen atoms contained in saturated hydrocarbon groups is larger than that of hydrocarbon atoms contained in unsaturated hydrocarbon groups. This enables estimation of the proportion of sp³ carbons in the molecule. Here, carbon in the unsaturated hydrocarbon group has a smaller number of bonds capable of bonding to hydrogen; for example, there is a difference of C₆H₆ and C₆H₁₂ when benzene and cyclohexane are compared. Considering the difference, the integral value of the signals at lower than 4 ppm exceeding the integral value of the signals at 4 ppm or higher in the results of the ¹H-NMR measurement indicates that approximately one-third of all the carbon atoms contained in the molecule exist in the saturated hydrocarbon group. As a result, the first organic compound is an organic compound with a low refractive index and thus can be suitably used as a hole-transport material.

An example of the first organic compound is a monoamine compound including a first aromatic group, a second aromatic group, and a third aromatic group, in which the first aromatic group, the second aromatic group, and the third aromatic group are directly bonded to the same nitrogen atom.

The monoamine compound preferably includes at least one fluorene skeleton because the hole-transport property becomes favorable. Thus, any one or more of the first aromatic group, the second aromatic group, and the third aromatic group described above are preferably fluorene skeletons. In addition, direct bonding between the fluorene skeleton and the nitrogen atom of the amine contributes to a higher HOMO level of the molecule and can facilitate hole transfer.

The first aromatic group and the second aromatic group each include one to three benzene rings. In addition, it is preferable that the first aromatic group and the second aromatic group be each a hydrocarbon group. In other words, it is preferable that the first aromatic group and the second aromatic group be each a phenyl group, a biphenyl group, a terphenyl group, or a naphthylphenyl group. Note that the first aromatic group or the second aromatic group is preferably a terphenyl group, in which case the glass transition temperature is increased and heat resistance becomes favorable.

In the case where the first aromatic group and the second aromatic group each include two or three benzene rings, the two or three benzene rings are preferably bonded to each other to form a substituent. It is preferable that one or both of the first aromatic group and the second aromatic group be a substituent in which two or three benzene rings are bonded to each other, that is, a biphenyl group or a terphenyl group, in which case the glass transition temperature is increased and heat resistance becomes favorable. It is further preferable that each of the first aromatic group and the second aromatic group be independently a biphenyl group or a terphenyl group.

One or both of the first aromatic group and the second aromatic group preferably include one or more hydrocarbon groups each having 1 to 12 carbon atoms forming bonds only by the sp³ hybrid orbitals. The hydrocarbon group is preferably an alkyl group having 3 to 8 carbon atoms or a cycloalkyl group having 6 to 12 carbon atoms.

The total number of carbon atoms included in the hydrocarbon group bonded to the first aromatic group or the second aromatic group is 6 or more. Furthermore, the total number of carbon atoms included in all of the hydrocarbon groups bonded to the first aromatic group and the second aromatic group is 8 or more, preferably 12 or more. When the hydrocarbon group with low atomic refraction is bonded in the above manner, the monoamine compound can be an organic compound with a low refractive index.

Note that a larger number of π electrons due to unsaturated bonds of carbon atoms are advantageous in carrier transport. Furthermore, the total number of carbon atoms contained in the hydrocarbon groups in the first aromatic group and the second aromatic group is preferably 36 or less, further preferably 30 or less so that the carrier-transport property is maintained high.

The third aromatic group is a substituted or unsubstituted monocyclic ring or a substituted or unsubstituted condensed ring composed of three or less rings. As the condensed ring has a larger number of rings, the refractive index tends to increase. In addition, when the condensed ring has a large number of rings, one or both of absorption and emission of light in the visible light region are observed. Thus, when the condensed ring has three or less rings, the material can maintain its refractive index low and can have a small influence of light absorption and emission. Note that the third aromatic group preferably has 6 to 13 carbon atoms in a ring to maintain the low refractive index. Specific examples of the aromatic group include a benzene ring, a naphthalene ring, a fluorene ring, and an acenaphthylene ring. In particular, the third aromatic group preferably includes a fluorene ring and further preferably is a fluorene ring, in which case the hole-transport property can be favorable.

As the first organic compound, any of organic compounds represented by General Formula (G1) to General Formula (G4) can be used, for example. The organic compounds represented by General Formula (G1) to General Formula (G4) can be regarded as examples of a monoamine compound and examples of a triaryl monoamine compound.

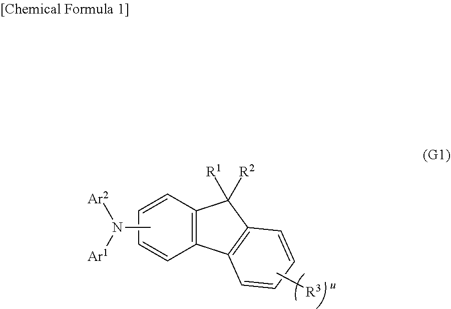

In General Formula (G1), each of Ar¹ and Ar² independently represents a substituted or unsubstituted benzene ring or a substituent in which two or three benzene rings that are each substituted or unsubstituted are bonded to each other. Note that one or both of Ar¹ and Ar² have one or more hydrocarbon groups each having 1 to 12 carbon atoms forming bonds only by the sp³ hybrid orbitals. The total number of carbon atoms included in all of the hydrocarbon groups bonded to Ar¹ and Ar² is 8 or more, and the total number of carbon atoms included in all of the hydrocarbon groups bonded to either Ar¹ or Ar² is 6 or more. Each of R¹ to R³ independently represents an alkyl group having 1 to 4 carbon atoms, and u represents an integer of 0 to 4. Note that R¹ and R² may be bonded to each other to form a ring.

Specific examples of Ar¹ and Ar² include a substituted or unsubstituted phenyl group, a substituted or unsubstituted biphenyl group, a substituted or unsubstituted terphenyl group, and a substituted or unsubstituted naphthylphenyl group.

As the hydrocarbon group having 1 to 12 carbon atoms forming bonds only by the sp³ hybrid orbitals, an alkyl group having 3 to 8 carbon atoms or a cycloalkyl group having 6 to 12 carbon atoms is preferable. Specific examples include a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a heptyl group, an octyl group, a cyclohexyl group, a 4-methylcyclohexyl group, a cycloheptyl group, a cyclooctyl group, a cyclononyl group, a cyclodecyl group, a decahydronaphthyl group, a cycloundecyl group, and a cyclododecyl group. A tert-butyl group, a cyclohexyl group, or a cyclododecyl group is particularly preferable.

Note that in the case where a plurality of straight-chain alkyl groups each having one or two carbon atoms are bonded to Ar¹ or Ar² as the hydrocarbon groups, the straight-chain alkyl groups may be bonded to each other to form a ring.

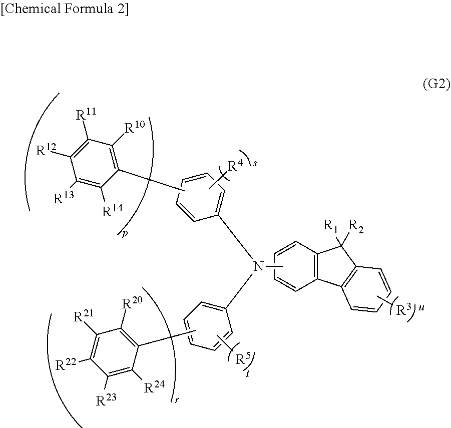

In General Formula (G2), each of n, m, p, and r independently represents 1 or 2, and each of s, t, and u independently represents an integer of 0 to 4. In addition, each of n+p and m+r is independently 2 or 3. Each of R¹ to R³ independently represents an alkyl group having 1 to 4 carbon atoms, each of R⁴ and R⁵ independently represents hydrogen or a hydrocarbon group having 1 to 3 carbon atoms, and each of R¹⁰ to R¹⁴ and R²⁰ to R²⁴ independently represents hydrogen or a hydrocarbon group having 1 to 12 carbon atoms forming bonds only by the sp³ hybrid orbitals. Note that the total number of carbon atoms included in R¹⁰ to R¹⁴ and R²⁰ to R²⁴ is 8 or more, and the total number of carbon atoms included in either R¹⁰ to R¹⁴ or R²⁰ to R²⁴ is 6 or more. Note that R¹ and R² may be bonded to each other to form a ring, and adjacent groups among R⁴, R⁵, R¹⁰ to R¹⁴, and R²⁰ to R²⁴ may be bonded to each other to form a ring.

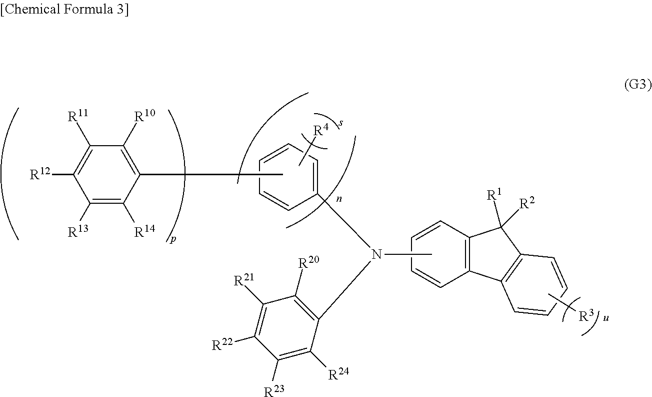

In General Formula (G3), each of n and p independently represents 1 or 2, and each of s and u independently represents an integer of 0 to 4. In addition, n+p is 2 or 3. Each of R¹ to R³ independently represents an alkyl group having 1 to 4 carbon atoms, R⁴ represents hydrogen or a hydrocarbon group having 1 to 3 carbon atoms, and each of R¹⁰ to R¹⁴ and R²⁰ to R²⁴ independently represents hydrogen or a hydrocarbon group having 1 to 12 carbon atoms forming bonds only by the sp³ hybrid orbitals. Note that the total number of carbon atoms included in R¹⁰ to R¹⁴ and R²⁰ to R²⁴ is 8 or more, and the total number of carbon atoms included in either R¹⁰ to R¹⁴ or R²⁰ to R²⁴ is 6 or more. Note that R¹ and R² may be bonded to each other to form a ring, and adjacent groups among R⁴, R¹⁰ to R¹⁴, and R²⁰ to R²⁴ may be bonded to each other to form a ring.

In General Formula (G2) and General Formula (G3), examples of the hydrocarbon group having 1 to 3 carbon atoms include a methyl group, an ethyl group, and a propyl group. Examples of the hydrocarbon group having 1 to 4 carbon atoms include a butyl group in addition to the above groups.

In the case where n is 2 in General Formula (G2) and General Formula (G3), the kind and number of substituents and the position of bonds included in two phenylene groups may be the same as or different from each other. Similarly, in the case where any of m, p, and r is 2, the kind and number of substituents and the position of bonds included in two phenylene groups may be the same as or different from each other.

It is preferable that each of s, t, and u be independently 0. Furthermore, in the case where s is an integer of 2 to 4, R⁴s may be the same as or different from each other. In the case where t is an integer of 2 to 4, R⁵s may be the same as or different from each other. In the case where u is an integer of 2 to 4, R³s may be the same as or different from each other.

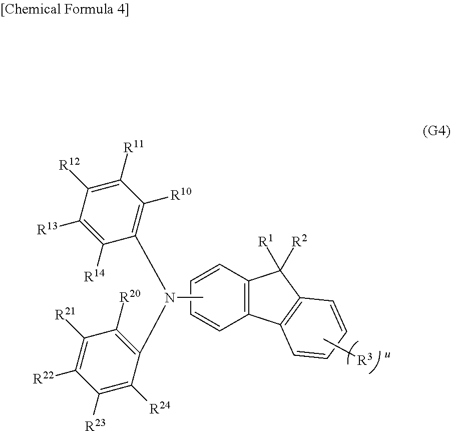

In General Formula (G4), u represents an integer of 0 to 4, each of R¹ to R³ independently represents an alkyl group having 1 to 4 carbon atoms, and each of R¹⁰ to R¹⁴ and R²⁰ to R²⁴ independently represents hydrogen or a hydrocarbon group having 1 to 12 carbon atoms forming bonds only by the sp³ hybrid orbitals. Note that the total number of carbon atoms included in R¹⁰ to R¹⁴ and R²⁰ to R²⁴ is 8 or more, and the total number of carbon atoms in either R¹⁰ to R¹⁴ or R²⁰ to R²⁴ is 6 or more. Note that R¹ and R² may be bonded to each other to form a ring, and adjacent groups among R¹⁰ to R¹⁴ and R²⁰ to R²⁴ may be bonded to each other to form a ring.

Note that u is preferably 0. In the case where u is an integer of 2 to 4, R³s may be the same as or different from each other.

In General Formula (G2) to General Formula (G4), it is preferable that each of R¹⁰ to R¹⁴ and R²⁰ to R²⁴ be independently any of hydrogen, a tert-butyl group, and a cyclohexyl group, in which case the refractive index can be lowered. It is also preferable that at least three of R¹⁰ to R¹⁴ and at least three of R²⁰ to R²⁴ be hydrogen, in which case the carrier-transport property is less likely to be hindered.

An example of the first organic compound is an arylamine compound including at least one aromatic group that includes first to third benzene rings and at least three alkyl groups. Note that the first to third benzene rings are bonded in this order and the first benzene ring is directly bonded to the nitrogen atom of amine.

The first benzene ring may further include a substituted or unsubstituted phenyl group and preferably includes an unsubstituted phenyl group. Furthermore, the second benzene ring or the third benzene ring may include a phenyl group substituted by an alkyl group.

Note that hydrogen is not directly bonded to carbon atoms at 1- and 3-positions in two or more of, preferably all of the first to third benzene rings, and the carbon atoms are bonded to any of the first to third benzene rings, the phenyl group substituted by the alkyl group, the at least three alkyl groups, and the nitrogen atom of the amine.

It is preferable that the arylamine compound further include a second aromatic group. It is preferable that the second aromatic group be a group having an unsubstituted monocyclic ring or a substituted or unsubstituted condensed ring composed of three or less rings; in particular, it is further preferable that the second aromatic group be a group having a substituted or unsubstituted condensed ring composed of three or less rings and 6 to 13 carbon atoms be included in the condensed ring. It is still further preferable that the second aromatic group be a group having a fluorene ring. Note that a dimethylfluorenyl group is preferable as the second aromatic group.

It is preferable that the arylamine compound further include a third aromatic group. The third aromatic group includes 1 to 3 benzene rings that are each substituted or unsubstituted.

It is preferable that the at least three alkyl groups and the alkyl group substituted for the phenyl group be each a chain alkyl group having 2 to 5 carbon atoms, further preferably a chain alkyl group having a branch and 3 to 5 carbon atoms, further preferably a tert-butyl group.

As the first organic compound, any of organic compounds represented by General Formula (G11) to General Formula (G13) can be used, for example. The organic compounds represented by General Formula (G11) to General Formula (G13) can be regarded as examples of a monoamine compound and examples of a triaryl monoamine compound.

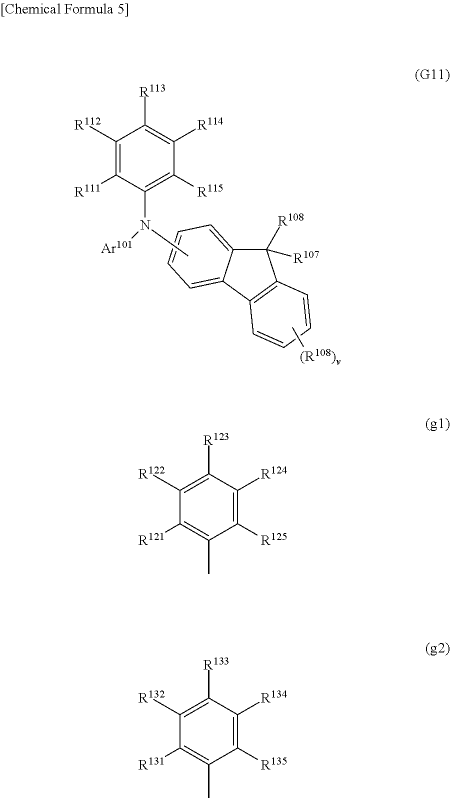

In General Formula (G11), Ar¹⁰¹ represents a substituted or unsubstituted benzene ring or a substituent in which two or three benzene rings that are each substituted or unsubstituted are bonded to each other; each of R¹⁰⁶ to R¹⁰⁸ independently represents an alkyl group having 1 to 4 carbon atoms; v represents an integer of 0 to 4; one of R¹¹¹ to R¹¹⁵ represents a substituent represented by General Formula (g1); and each of the others independently represents any one of hydrogen, an alkyl group having 1 to 6 carbon atoms, and a substituted or unsubstituted phenyl group. Note that the number of substituted or unsubstituted phenyl groups in R¹¹¹ to R¹¹⁵ is less than or equal to 1. The phenyl group is preferably unsubstituted. In the case where the phenyl group includes a substituent, the substituent is an alkyl group having 1 to 6 carbon atoms.

Specific examples of Ar¹⁰¹ include a substituted or unsubstituted phenyl group, a substituted or unsubstituted biphenyl group, a substituted or unsubstituted terphenyl group, and a substituted or unsubstituted naphthylphenyl group.

Note that when v is 2 or more, R¹⁰⁸s may be the same as or different from each other.

In General Formula (g1), one of R¹²¹ to R¹²⁵ represents a substituent represented by General Formula (g2), and each of the others independently represents any one of hydrogen, an alkyl group having 1 to 6 carbon atoms, and a phenyl group substituted by an alkyl group having 1 to 6 carbon atoms.

In General Formula (g2), each of R¹³¹ to R¹³⁵ independently represents any one of hydrogen, an alkyl group having 1 to 6 carbon atoms, and a phenyl group substituted by an alkyl group having 1 to 6 carbon atoms.

At least three of R¹¹¹ to R¹¹⁵, R¹²¹ to R¹²⁵, and R¹³¹ to R¹³⁵ each represent an alkyl group having 1 to 6 carbon atoms. Thus, the organic compound represented by General Formula (G11) can be an arylamine compound with a low refractive index.

The number of phenyl groups substituted by an alkyl group having 1 to 6 carbon atoms in R¹²¹ to R¹²⁵ and R¹³¹ to R¹³⁵ is less than or equal to 1, that is, the number of phenyl groups substituted by an alkyl group having 1 to 6 carbon atoms in R¹²¹ to R¹²⁵ and R¹³¹ to R¹³⁵ is 1 or 0.

Note that in at least two combinations of the three combinations R¹¹² and R¹¹⁴, R¹²² and R¹²⁴, and R¹³² and R¹³⁴, at least one R represents any of the substituents other than hydrogen. In other words, in each of two or more benzene rings of a benzene ring including R¹¹² and R¹¹⁴, a benzene ring including R¹²² and R¹²⁴, and a benzene ring including R¹³² and R¹³⁴, at least one of the carbon atoms at the meta positions is bonded to one which is not hydrogen, that is, has a substituent. At this time, it is preferable that at least one of R¹¹², R¹¹⁴, R¹²², and R¹²⁴ be any of the substituents other than hydrogen and at least one of R¹³² and R¹³⁴ be any of the substituents other than hydrogen.

Examples of the alkyl group having 1 to 4 carbon atoms include a methyl group, an ethyl group, a propyl group, an isopropyl group, a butyl group, a sec-butyl group, and an isobutyl group, and in particular, a tert-butyl group is preferred.

In the case where a benzene ring or a phenyl group includes a substituent, an alkyl group having 1 to 6 carbon atoms or a cycloalkyl group having 5 to 12 carbon atoms can be used as the substituent.

The alkyl group having 1 to 6 carbon atoms is preferably a chain alkyl group having 2 or more carbon atoms in terms of lowering the refractive index, and is preferably a chain alkyl group having 5 or less carbon atoms in terms of ensuring the carrier-transport property. A chain alkyl group having a branch and 3 or more carbon atoms is significantly effective in lowering the refractive index. That is, the alkyl group having 1 to 6 carbon atoms is preferably a chain alkyl group having 2 to 5 carbon atoms, and further preferably a chain alkyl group having a branch and 3 to 5 carbon atoms. Examples of the alkyl group having 1 to 6 carbon atoms include a methyl group, an ethyl group, a propyl group, an isopropyl group, a butyl group, a sec-butyl group, an isobutyl group, a tert-butyl group, a pentyl group, and a hexyl group, and in particular, a tert-butyl group is preferred.

Examples of the cycloalkyl group having 5 to 12 carbon atoms include a cyclohexyl group, a 4-methylcyclohexyl group, a cycloheptyl group, a cyclooctyl group, a cyclononyl group, a cyclodecyl group, a decahydronaphthyl group, a cycloundecyl group, and a cyclododecyl group. In terms of lowering the refractive index, a cycloalkyl group having 6 or more carbon atoms is preferred, and in particular, a cyclohexyl group or a cyclododecyl group is preferred.

General Formula (G12) is an example where Ar¹⁰¹ in General Formula (G11) is a substituent in which two or three benzene rings that are each substituted or unsubstituted are bonded to each other. Thus, description of portions similar to those in General Formula (G11) is omitted in some cases.

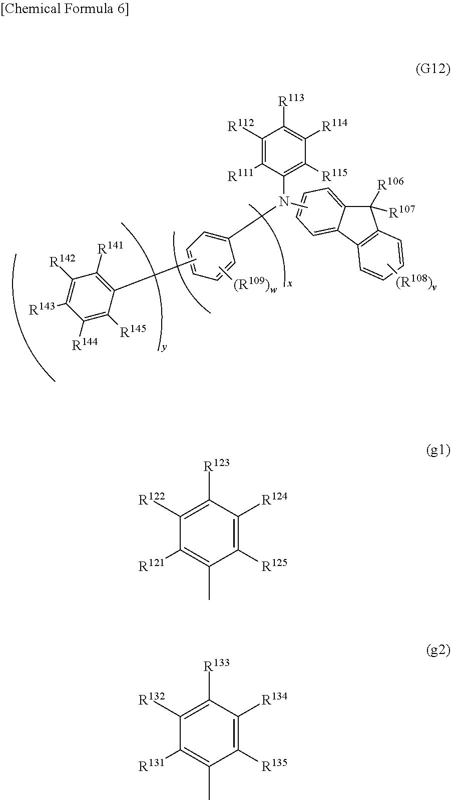

In General Formula (G12), each of R¹⁰⁶ to R¹⁰⁹ independently represents an alkyl group having 1 to 4 carbon atoms, each of v and w independently represents an integer of 0 to 4, each of x and y independently represents 1 or 2, and x+y is 2 or 3. Both x and y are preferably 1. Each of R¹⁴¹ to R¹⁴⁵ independently represents any one of hydrogen, an alkyl group having 1 to 6 carbon atoms, and a cycloalkyl group having 5 to 12 carbon atoms.

Note that when v is 2 or more, R¹⁰⁸s may be the same as or different from each other. Similarly, when w is an integer of 2 or more, R¹⁰⁹s may be the same as or different from each other.

When x is 2, the kind and number of substituents and the position of bonds included in two phenylene groups may be the same as or different from each other. When y is 2, the kind and number of substituents and the position of bonds included in two phenyl groups may be the same as or different from each other.

General Formula (G13) is an example where Ar¹⁰¹ in General Formula (G11) is one substituted or unsubstituted benzene ring. Thus, description of portions similar to those in General Formula (G11) is omitted in some cases.

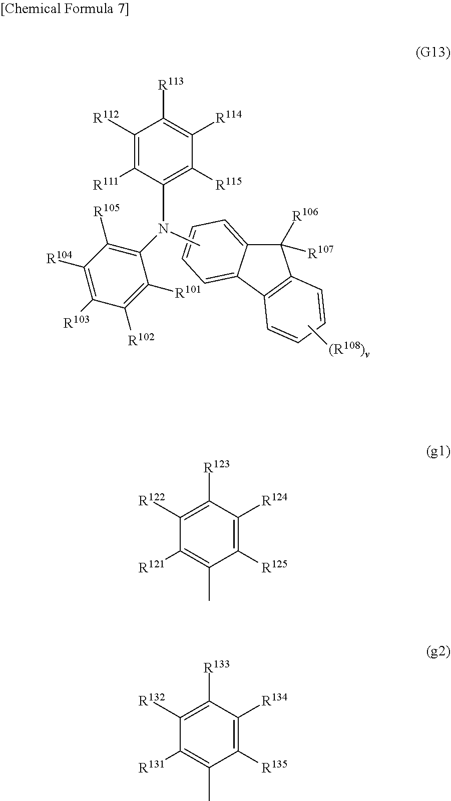

In General Formula (G13), each of R¹⁰¹ to R¹⁰⁵ independently represents any one of hydrogen, an alkyl group having 1 to 6 carbon atoms, a cycloalkyl group having 6 to 12 carbon atoms, and a substituted or unsubstituted phenyl group.

In R¹⁰¹ to R¹⁰⁵, it is preferable that R¹⁰³ be a cyclohexyl group and the others be all hydrogen. Alternatively, in R¹⁰¹ to R¹⁰⁵, it is preferable that R¹⁰¹ be an unsubstituted phenyl group and the others be all hydrogen, in which case the hole-transport property is improved.

Specific examples of the organic compound that can be used as the first organic compound include N,N-bis(4-cyclohexylphenyl)-9,9-dimethyl-9H-fluoren-2-amine (abbreviation: dchPAF), N-[(3′,5′-ditertiarybutyl)-1,1′-biphenyl-4-yl]-N-(4-cyclohexylphenyl)-9,9-dimethyl-9H-fluoren-2-amine (abbreviation: mmtBuBichPAF), N-(3,3″,5,5″-tetra-t-butyl-1,1′:3′,1″-terphenyl-5′-yl)-N-(4-cyclohexylphenyl)-9,9-dimethyl-9H-fluoren-2-amine (abbreviation: mmtBumTPchPAF), N-[(3,3′,5′-t-butyl)-1,1′-biphenyl-5-yl]-N-(4-cyclohexylphenyl)-9,9-dimethyl-9H-fluoren-2-amine (abbreviation: mmtBumBichPAF), N-(1,1′-biphenyl-2-yl)-N-[(3,3′,5′-tri-t-butyl)-1,1′-biphenyl-5-yl]-9,9-dimethyl-9H-fluoren-2-amine (abbreviation: mmtBumBioFBi), N-(4-tert-butylphenyl)-N-(3,3″,5,5″-tetra-t-butyl-1,1:3′,1″-terphenyl-5′-yl)-9,9-dimethyl-9H-fluoren-2-amine (abbreviation: mmtBumTPtBuPAF), N-(1,1′-biphenyl-2-yl)-N-(3,3″,5′,5″-tetra-t-butyl-1,1′:3′,1″-terphenyl-5-yl)-9,9-dimethyl-9H-fluoren-2-amine (abbreviation: mmtBumTPoFBi-02), N-(4-cyclohexylphenyl)-N-(3,3″,5′,5″-tetra-t-butyl-1,1′:3′,1″-terphenyl-5-yl)-9,9-dimethyl-9H-fluoren-2-amine (abbreviation: mmtBumTPchPAF-02), N-(1,1′-biphenyl-2-yl)-N-(3″,5′,5″-tri-t-butyl-1,1′:3′,1″-terphenyl-5-yl)-9,9-dimethyl-9H-fluoren-2-amine (abbreviation: mmtBumTPoFBi-03), N-(4-cyclohexylphenyl)-N-(3″,5′,5″-tri-t-butyl-1,1:3′,1″-terphenyl-5-yl)-9,9-dimethyl-9H-fluoren-2-amine (abbreviation: mmtBumTPchPAF-03), N-(1,1′-biphenyl-2-yl)-N-(3″,5′,5″-tri-t-butyl-1,1′:3′,1″-terphenyl-4-yl)-9,9-dimethyl-9H-fluoren-2-amine (abbreviation: mmtBumTPoFBi-04), and N-(4-cyclohexylphenyl)-N-(3″,5′,5″-tri-t-butyl-1,1′:3′,1″-terphenyl-4-yl)-9,9-dimethyl-9H-fluoren-2-amine (abbreviation: mmtBumTPchPAF-04). Note that synthesis methods of these organic compounds will be described in detail in reference example.

### [Second Organic Compound]

As described above, the second organic compound contains fluorine. It is particularly preferable that the second organic compound include a cyano group.

The second organic compound preferably shows an electron-accepting property with respect to the first organic compound. To achieve this, the LUMO level of the second organic compound is preferably lower than or equal to −5.0 eV.

Specific examples of the second organic compound include 7,7,8,8-tetracyano-2,3,5,6-tetrafluoroquinodimethane (abbreviation: F₄-TCNQ), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A [3]radialene derivative having an electron-withdrawing group (in particular, a halogen group such as a fluoro group, or a cyano group) has a very high electron-accepting property and thus is preferable; specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

It is preferable that the second organic compound do not contain a metal element, in which case deposition is easy.

In the case where the third organic compound is used for the light-emitting device of one embodiment of the present invention, the second organic compound preferably shows an electron-accepting property with respect to the third organic compound.

As described above, a composite material of the first organic compound and the second organic compound can be used for the light-emitting device of one embodiment of the present invention. The concentration percentage by mass of the second organic compound in the composite material is preferably lower than or equal to 10 wt %, further preferably lower than or equal to 5 wt %. The concentration percentage by volume of the second organic compound in the composite material is preferably lower than or equal to 10 vol %, further preferably lower than or equal to 5 vol %, still further preferably lower than or equal to 3 vol %. Lowering the concentration of the second organic compound can inhibit absorption of light in the visible light region. Thus, the emission efficiency of the light-emitting device can be increased, for example. Furthermore, in the case where a layer containing the composite material is formed in common to a plurality of light-emitting devices included in a light-emitting apparatus, occurrence of crosstalk can be inhibited.

### [Third Organic Compound]

As the third organic compound, a hole-transport material and an electron-blocking material can be used. It is particularly preferable that the third organic compound have both a hole-transport property and an electron-blocking property. Among hole-transport materials to be described later, a material having an electron-blocking property is preferably used. The third organic compound preferably has a low electron-injection property and a low electron-transport property.

The HOMO level of the third organic compound is preferably lower than the HOMO level of the first organic compound. To achieve this, the HOMO level of the third organic compound is preferably lower than or equal to −5.40 eV.

In addition, the LUMO level of the third organic compound is preferably higher than the LUMO level of a material having the lowest LUMO level among the materials contained in the light-emitting layer. To achieve this, the LUMO level of the third organic compound is preferably higher than or equal to −2.50 eV.

As the third organic compound, it is possible to use a compound that can be used as the first organic compound. Alternatively, a hole-transport material to be described later can be used as the third organic compound.

In addition, the refractive index of the layer including the first organic compound is preferably lower than the refractive index of the layer including the third organic compound. In this case, a difference between the refractive index of the layer including the first organic compound with respect to light with a wavelength of 633 nm and the refractive index of the layer including the third organic compound with respect to light with a wavelength of 633 nm is preferably greater than or equal to 0.05, further preferably greater than or equal to 0.1, still further preferably greater than or equal to 0.15.

The refractive index of the layer including the third organic compound with respect to light with a wavelength of 633 nm is preferably higher than or equal to 1.45 and lower than or equal to 1.70. The refractive index of the layer including the third organic compound with respect to a wavelength in the green-light-emitting region (greater than or equal to 525 nm and less than or equal to 535 nm) is preferably higher than or equal to 1.48 and lower than or equal to 1.73. The refractive index of the layer including the third organic compound with respect to a wavelength in the blue-light-emitting region (greater than or equal to 455 nm and less than or equal to 465 nm) is preferably higher than or equal to 1.50 and lower than or equal to 1.75.

The proportion of carbon atoms forming bonds by the sp³ hybrid orbitals to the total carbon atoms in the third organic compound is preferably higher than or equal to 23% and lower than or equal to 55%. A substituent including carbon atoms forming bonds by the sp³ hybrid orbitals is what is called a chain saturated hydrocarbon group or a cyclic saturated hydrocarbon group, and thus has low atomic refraction. Accordingly, the third organic compound can have a refractive index.

The glass transition temperature of the third organic compound is preferably higher than or equal to 90° C., further preferably higher than or equal to 95° C., still further preferably higher than or equal to 100° C., yet further preferably higher than or equal to 110° C., yet still further preferably higher than or equal to 120° C.

The third organic compound is preferably an amine compound, further preferably a monoamine compound, still further preferably a triaryl monoamine compound.

The molecular weight of the third organic compound is preferably greater than or equal to 650 and less than or equal to 1200. This can increase heat resistance of the first organic compound.

The integral value of signals at lower than 4 ppm preferably exceeds the integral value of signals at 4 ppm or higher in the results of ¹H-NMR measurement of the third organic compound.

The description of the first organic compound can be referred to for the specific examples of the third organic compound.

### Structure Example of Light-Emitting Device

### <<Basic Structure of Light-Emitting Device>>

FIG. 1A to FIG. 1E illustrate examples of light-emitting devices including an EL layer between a pair of electrodes.

The light-emitting device illustrated in FIG. 1A has a structure in which an EL layer 103 is interposed between a first electrode 101 and a second electrode 102 (a single structure). The EL layer 103 includes at least a light-emitting layer. The EL layer 103 can further include one or more of a variety of layers such as a hole-injection layer, a hole-transport layer, an electron-transport layer, an electron-injection layer, a carrier-blocking layer, an exciton-blocking layer, and a charge-generation layer.

FIG. 1B illustrates an example of a stacked-layer structure of the EL layer 103. In this embodiment, the case where the first electrode 101 functions as an anode and the second electrode 102 functions as a cathode is described as an example. The EL layer 103 has a structure in which a hole-injection layer 111, a first hole-transport layer 112a, a buffer layer 119, a second hole-transport layer 112b, a light-emitting layer 113, an electron-transport layer 114, and an electron-injection layer 115 are stacked in this order over the first electrode 101. Each of the hole-injection layer 111, the first hole-transport layer 112a, the buffer layer 119, the second hole-transport layer 112b, the light-emitting layer 113, the electron-transport layer 114, and the electron-injection layer 115 may have a single-layer structure or a stacked-layer structure. When the first electrode 101 serves as a cathode and the second electrode 102 serves as an anode, the stacking order is reversed.

The first layer can be used as the first hole-transport layer 112a, and the second layer can be used as the buffer layer 119. The third layer is preferably used as the second hole-transport layer 112b. The fourth layer is preferably used as the hole-injection layer 111.

An organic compound used for the buffer layer 119 and an organic compound used for the second hole-transport layer 112b may be mixed. Alternatively, an organic compound used for the buffer layer 119 may be added to the second hole-transport layer 112b without providing the buffer layer 119. Alternatively, an organic compound used for the second hole-transport layer 112b may be added to the buffer layer 119 without providing the second hole-transport layer 112b.

The light-emitting device may include a plurality of EL layers between a pair of electrodes. For example, it is preferable that the light-emitting device include n EL layers (n is an integer of 2 or more) and a charge-generation layer 104 be provided between an (n−1)th EL layer and an n-th EL layer.

FIG. 1C illustrates a light-emitting device with a tandem structure in which two EL layers (EL layers 103a and 103b) are provided between a pair of electrodes. FIG. 1D illustrates a light-emitting device with a tandem structure in which three EL layers (EL layers 103a, 103b, and 103c) are provided.

Each of the EL layers 103a, 103b, and 103c includes at least a light-emitting layer. In the case where a plurality of EL layers are provided as in the tandem structure illustrated in FIG. 1C and FIG. 1D, at least one of the EL layers can have a stacked-layer structure similar to that of the EL layer 103 illustrated in FIG. 1B. In particular, an EL layer emitting green phosphorescent light preferably has a stacked-layer structure similar to that of the EL layer 103 illustrated in FIG. 1i, in which case both high emission efficiency and a low driving voltage can be achieved. Each of the EL layers 103a, 103b, and 103c can include one or more kinds of the hole-injection layer 111, the first hole-transport layer 112a, the buffer layer 119, the second hole-transport layer 112b, the electron-transport layer 114, and the electron-injection layer 115.

The charge-generation layer 104 illustrated in FIG. 1C has a function of injecting electrons into one of the EL layer 103a and the EL layer 103b and injecting holes into the other of the EL layers when voltage is applied to the first electrode 101 and the second electrode 102. Thus, when voltage is applied in FIG. 1C such that the potential of the first electrode 101 is higher than that of the second electrode 102, the charge-generation layer 104 injects electrons into the EL layer 103a and injects holes into the EL layer 103b.

Note that in terms of light extraction efficiency, the charge-generation layer 104 preferably transmits visible light or near-infrared light (specifically, the transmittance of visible light or near-infrared light of the charge-generation layer 104 is preferably higher than or equal to 40%). The charge-generation layer 104 functions even when having lower conductivity than one or both of the first electrode 101 and the second electrode 102.

When the EL layers are provided in contact with each other and this shapes the same structure as the charge-generation layer 104, the EL layers can be provided in contact with each other without the charge-generation layer therebetween. For example, when a charge-generation region is formed over a surface of the EL layer, an EL layer can be provided in contact with the surface.

A light-emitting device with a tandem structure has higher current efficiency than a light-emitting device with a single structure, and needs a smaller amount of current when the devices emit light with the same luminance. Accordingly, the lifetime of the light-emitting device is long, and the display apparatus and the electronic device can have high reliability.

The light-emitting layer 113 contains a light-emitting substance and other substances in appropriate combination, whereby fluorescence or phosphorescence with a desired wavelength can be obtained. The light-emitting layer 113 may be a stack of layers having different emission wavelengths. Note that in this case, materials used as the light-emitting substances and other substances can be different between the stacked light-emitting layers. The EL layers 103a, 103b, and 103c illustrated in FIG. 1C and FIG. 1D may be configured to emit light with different wavelengths. Also in this case, the light-emitting substance and other substances can be materials different between the light-emitting layers. For example, in the structure in FIG. 1C, when the EL layer 103a emits red light and green light and the EL layer 103b emits blue light, the light-emitting device as a whole can emit white light. One light-emitting device may include a plurality of light-emitting layers or a plurality of EL layers that emit light of the same color. For example, in the structure in FIG. 1D, when the EL layer 103a emits first blue light, the EL layer 103b emits yellow light, yellowish green light, or green light and red light, and the EL layer 103c emits second blue light, the light-emitting device as a whole can emit white light.

The light-emitting device of one embodiment of the present invention may have a structure in which light obtained from the EL layer is resonated between the pair of electrodes in order to intensify the light. For example, when the first electrode 101 is formed as a reflective electrode and the second electrode 102 is formed as a transflective electrode in FIG. 1B to form a micro optical resonator (microcavity) structure, light obtained from the EL layer 103 can be intensified.

With the use of the microcavity structure for the light-emitting device, light with different wavelengths (monochromatic light) can be extracted even if the same EL layer is used. Thus, formation of functional layers for respective pixels (what is called separate coloring) is not necessary for obtaining different emission colors. Therefore, higher resolution can be easily achieved. In addition, a combination with coloring layers (color filters) is also possible. Furthermore, the emission intensity of light with a specific wavelength in the front direction can be increased, whereby power consumption can be reduced.

Note that in the case where the first electrode 101 of the light-emitting device is a reflective electrode having a stacked-layer structure of a conductive film having a property of reflecting visible light or near-infrared light and a conductive film having a property of transmitting visible light or near-infrared light, optical adjustment can be performed by controlling the thicknesses of the conductive film having the transmitting property. Specifically, when the wavelength of light obtained from the light-emitting layer 113 is λ, the distance between the first electrode 101 and the second electrode 102 is preferably adjusted to be in the neighborhood of mλ/2 (m is a natural number).

To amplify desired light (wavelength: k) obtained from the light-emitting layer 113, the optical path length from the first electrode 101 to a region where the desired light is obtained in the light-emitting layer 113 (a light-emitting region) and the optical path length from the second electrode 102 to the region where the desired light is obtained in the light-emitting layer 113 (a light-emitting region) are preferably adjusted to be in the neighborhood of (2m′+1)λ/4 (m′ is a natural number). Here, the light-emitting region refers to a region where holes and electrons are recombined in the light-emitting layer 113.

By performing such optical adjustment, the spectrum of light obtained from the light-emitting layer 113 can be narrowed, and light emission with high color purity can be obtained.

Note that in the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the electrodes; thus, it is assumed that the above effect can be sufficiently obtained with given positions in the first electrode 101 and the second electrode 102 being supposed to be the reflective regions. Furthermore, the optical path length between the first electrode 101 and the light-emitting layer from which the desired light is obtained, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer from which the desired light is obtained; thus, it is assumed that the above effect can be sufficiently obtained with a given position in the first electrode 101 being supposed to be the reflective region and a given position in the light-emitting layer from which the desired light is obtained being supposed to be the light-emitting region.

At least one of the first electrode 101 and the second electrode 102 has a property of transmitting visible light or near-infrared light. The transmittance of visible light or near-infrared light of the electrode having a property of transmitting visible light or near-infrared light is higher than or equal to 40%. In the case where the electrode having a transmitting property with respect to visible light or near-infrared light is the above-described transflective electrode, the reflectance of visible light or near-infrared light of the electrode is higher than or equal to 20% and lower than or equal to 80%, preferably higher than or equal to 40% and lower than or equal to 70%. These electrodes preferably have a resistivity lower than or equal to 1×10⁻² Ωcm.

When the first electrode 101 or the second electrode 102 is an electrode having a property of reflecting visible light or near-infrared light (a reflective electrode), the reflectance of visible light or near-infrared light of the reflective electrode is higher than or equal to 40% and lower than or equal to 100%, preferably higher than or equal to 70% and lower than or equal to 100%. This electrode preferably has a resistivity lower than or equal to 1×10⁻² Ωcm.

The light-emitting device illustrated in FIG. 1E includes a buffer layer 109 over the second electrode 102. Examples of the buffer layer 109 include an organic film, a semiconductor film, and an inorganic insulating film. The light-emitting device illustrated in FIG. 1E has a structure in which light emission from the EL layer 103 is extracted toward the buffer layer 109 side; thus, the buffer layer 109 preferably has a function of transmitting visible light or infrared light. Thus, light absorption by the buffer layer 109 can be inhibited and the light extraction efficiency of the light-emitting device can be increased. An example of the organic film is a layer containing a substance with a high hole-injection property, a substance with a high hole-transport property, a hole-blocking material, a substance with a high electron-transport property, a substance with a high electron-injection property, an electron-blocking material, a substance with a bipolar property, or the like that can be used for the light-emitting device. As the semiconductor film, a semiconductor film that transmits visible light or infrared light can be given. As the organic insulating film, a silicon nitride film can be given. The buffer layer 109 preferably has a passivation function. This can inhibit the entry of impurities such as moisture into the light-emitting device. In the case where the second electrode 102 has a function of reflecting visible light or infrared light, provision of the buffer layer 109 can reduce loss of optical energy due to a surface plasmon in the second electrode 102.

### <<Specific Structure of Light-Emitting Device>>

Next, a specific structure of the light-emitting device will be described. Here, the light-emitting device having the single structure illustrated in FIG. 1B is used for the description.

### <Electrode>

As materials for forming the first electrode 101 and the second electrode 102, any of the following materials can be used in an appropriate combination as long as the functions of the electrodes described above can be fulfilled. For example, a metal, an alloy, an electrically conductive compound, a mixture of these, and the like can be used as appropriate. Specifically, an In—Sn oxide (also referred to as ITO), an In—Si—Sn oxide (also referred to as ITSO), an In—Zn oxide, or an In—W—Zn oxide can be given. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) and an alloy containing an appropriate combination of any of these metals (an alloy of silver, palladium, and copper (Ag—Pd—Cu (APC)) or the like). It is also possible to use an element belonging to Group 1 or Group 2 of the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, and the like.

Note that when a light-emitting device having a microcavity structure is fabricated, the first electrode 101 is formed as a reflective electrode and the second electrode 102 is formed as a transflective electrode. Thus, a single layer or stacked layers can be formed using one or more desired conductive materials. Note that the second electrode 102 is formed after formation of the EL layer 103, with the use of a material selected as described above. For fabrication of these electrodes, a sputtering method or a vacuum evaporation method can be used.

### <Hole-Injection Layer>

The hole-injection layer 111 is a layer injecting holes from the first electrode 101 serving as the anode to the EL layer 103, and is a layer containing a material with a high hole-injection property.

As the material with a high hole-injection property, a composite material containing a hole-transport material and an acceptor material (an electron-accepting material) can be used. In this case, the acceptor material extracts electrons from the hole-transport material, so that holes are generated in the hole-injection layer 111 and the holes are injected into the light-emitting layer 113 through the hole-transport layer. Note that the hole-injection layer 111 may be formed using a single layer of a composite material containing a hole-transport material and an acceptor material, or may be formed using a stack including a layer of a hole-transport material and a layer of an acceptor material.

For the hole-injection layer 111, a composite material of the first organic compound and the second organic compound is preferably used.

As the material with a high hole-injection property, a transition metal oxide such as molybdenum oxide, vanadium oxide, ruthenium oxide, tungsten oxide, or manganese oxide or a phthalocyanine-based compound such as phthalocyanine (abbreviation: H₂Pc) or copper phthalocyanine (abbreviation: CuPc) can be used, for example.

As the material with a high hole-injection property, it is possible to use, for example, an aromatic amine compound such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), or 3-[N-(1-naphthyl)-N-(9-phenylcarbazol-3-yl)amino]-9-phenylcarbazole (abbreviation: PCzPCN1).

As the material with a high hole-injection property, it is possible to use, for example, poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), or poly[N,N-bis(4-butylphenyl)-N,N-bis(phenyl)benzidine](abbreviation: Poly-TPD). Alternatively, it is also possible to use, for example, a high molecular compound to which acid is added, such as poly(3,4-ethylenedioxythiophene)/poly(styrenesulfonic acid) (abbreviation: PEDOT/PSS) or polyaniline/poly(styrenesulfonic acid) (PAni/PSS).

The hole-transport material used for the hole-injection layer 111 may include at least one of a carbazole skeleton, a dibenzofuran skeleton, a dibenzothiophene skeleton, and an anthracene skeleton. The hole-transport material may be an aromatic amine including a substituent that includes a dibenzofuran ring or a dibenzothiophene ring, an aromatic monoamine that includes a naphthalene ring, or an aromatic monoamine in which a 9-fluorenyl group is bonded to the nitrogen atom of the amine through an arylene group.

Examples of the hole-transport material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4-(2;1′-binaphthyl-6-yl)-4′,4″-diphenyltriphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4-(6;2′-binaphthyl-2-yl)-4′,4″-diphenyltriphenylamine (abbreviation: BBA(βN2)B), 4-(2;2′-binaphthyl-7-yl)-4′,4″-diphenyltriphenylamine (abbreviation: BBA(βN2)B-03), 4-(1;2′-binaphthyl-4-yl)-4′,4″-diphenyltriphenylamine (abbreviation: BBAβNαNB), 4-(1;2′-binaphthyl-5-yl)-4′,4″-diphenyltriphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-(1-naphthyl)-4′-phenyltriphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), and N-(1,1′-biphenyl-4-yl)-9,9-dimethyl-N-[4-(9-phenyl-9H-carbazol-3-yl)phenyl]-9H-fluoren-2-amine (abbreviation: PCBBiF).

Examples of the acceptor material that can be used for the hole-injection layer 111 include chloranil and 2,3,6,7,10,11-hexacyano-1,4,5,8,9,12-hexaazatriphenylene (abbreviation: HAT-CN).

As the acceptor material, an oxide of a metal belonging to any of Group 4 to Group 8 of the periodic table can also be used. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, organic acceptors such as a quinodimethane derivative, a chloranil derivative, and a hexaazatriphenylene derivative can be used.

### <Hole-Transport Layer>

The first hole-transport layer 112a is a layer transporting holes, which are injected from the first electrode 101 through the hole-injection layer 111, to the light-emitting layer 113, and is a layer containing a hole-transport material.

It is preferable that the hole-transport material used for the first hole-transport layer 112a have a HOMO level that is the same as or close to the HOMO level of the hole-injection layer 111.

The hole-transport material used for the first hole-transport layer 112a is preferably a substance with a hole mobility greater than or equal to 10⁻⁶ cm²/Vs. Note that other substances can also be used as long as they have a property of transporting more holes than electrons.

The first organic compound (hole-transport material) is used for the first hole-transport layer 112a.

Using the same first organic compound for both the hole-injection layer 111 and the first hole-transport layer 112a can reduce the refractive index difference and increase the light extraction efficiency.

The light-emitting device of one embodiment of the present invention includes the buffer layer 119 between the first hole-transport layer 112a and the light-emitting layer 113. The second organic compound is used for the buffer layer 119. The buffer layer 119 may further include the third organic compound (a hole-transport material with an electron-blocking property).

The light-emitting device of one embodiment of the present invention preferably further includes the second hole-transport layer 112b between the buffer layer 119 and the light-emitting layer 113. The second hole-transport layer 112b preferably has a function of an electron-blocking layer. The third organic compound (a hole-transport material with an electron-blocking property) is preferably used for the second hole-transport layer 112b. The second hole-transport layer 112b may further include the second organic compound.

For each of the first hole-transport layer 112a, the buffer layer 119, and the second hole-transport layer 112b, it is possible to use a material that can be used for the hole-injection layer 111.

As other hole-transport materials, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

Examples of the carbazole derivative (a compound having a carbazole skeleton) include a bicarbazole derivative (e.g., a 3,3′-bicarbazole derivative) and aromatic amine having a carbazolyl group.

Specific examples of the bicarbazole derivative (e.g., a 3,3′-bicarbazole derivative) include 3,3′-bis(9-phenyl-9H-carbazole) (abbreviation: PCCP), 9,9′-bis(1,1′-biphenyl-4-yl)-3,3′-bi-9H-carbazole, 9,9′-bis(1,1′-biphenyl-3-yl)-3,3′-bi-9H-carbazole, 9-(1,1′-biphenyl-3-yl)-9′-(1,1′-biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: βNCCP).

Specific examples of the aromatic amine having a carbazolyl group include N-(4-biphenyl)-N-(9,9-dimethyl-9H-fluoren-2-yl)-9-phenyl-9H-carbazol-3-amine (abbreviation: PCBiF), 4-phenyldiphenyl-(9-phenyl-9H-carbazol-3-yl)amine (abbreviation: PCA1BP), N,N-bis(9-phenylcarbazol-3-yl)-N,N-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), PCzPCA1, PCzPCA2, PCzPCN1, 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino]spiro-9,9′-bifluorene (abbreviation: PCASF), N-[4-(9H-carbazol-9-yl)phenyl]-N-(4-phenyl)phenylaniline (abbreviation: YGA1BP), N,N-bis[4-(carbazol-9-yl)phenyl]-N,N-diphenyl-9,9-dimethylfluorene-2,7-diamine (abbreviation: YGA2F), and 4,4′,4″-tris(carbazol-9-yl)triphenylamine (abbreviation: TCTA).

In addition to the above, other examples of the carbazole derivative include 3-[4-(9-phenanthryl)-phenyl]-9-phenyl-9H-carbazole (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the thiophene derivative (a compound having a thiophene skeleton) and the furan derivative (a compound having a furan skeleton) include compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV), 4,4′,4″-(benzene-1,3,5-triyl)tri(dibenzofuran) (abbreviation: DBF3P-II), and 4-{3-[3-(9-phenyl-9H-fluoren-9-yl)phenyl]phenyl}dibenzofuran (abbreviation: mmDBFFLBi-II).

Specific examples of the aromatic amine include 4,4′-bis[N-(1-naphthyl)-N-phenylamino]biphenyl (abbreviation: NPB or α-NPD), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]spiro-9,9′-bifluorene (abbreviation: DPA2SF), 4,4′,4″-tris[N-(1-naphthyl)-N-phenylamino]triphenylamine (abbreviation: 1′-TNATA), TDATA, m-MTDATA, N,N-di(p-tolyl)-N,N-diphenyl-p-phenylenediamine (abbreviation: DTDPPA), DPAB, DNTPD, and DPA3B.

As the hole-transport material, a high molecular compound such as PVK, PVTPA, PTPDMA, or Poly-TPD can also be used.

The hole-transport material is not limited to the above examples, and one of or a combination of various known materials can be used for the hole-injection layer 111, the first hole-transport layer 112a, the buffer layer 119, and the second hole-transport layer 112b.

In the light-emitting device of one embodiment of the present invention, the HOMO level of the hole-transport material used for the first hole-transport layer 112a is preferably lower than or equal to the HOMO level of the hole-transport material used for the hole-injection layer 111. A difference between the HOMO level of the hole-transport material used for the first hole-transport layer 112a and the HOMO level of the hole-transport material used for the hole-injection layer 111 is preferably less than or equal to 0.2 eV. It is further preferable that the hole-transport material used for the hole-injection layer 111 and the hole-transport material used for the first hole-transport layer 112a be the same because hole injection can be performed smoothly.

The HOMO level of the hole-transport material (the third organic compound) used for the second hole-transport layer 112b is preferably lower (deeper) than the HOMO level of the hole-transport material (the first organic compound) used for the first hole-transport layer 112a. Furthermore, a difference in the HOMO level between the two hole-transport materials is preferably less than or equal to 0.2 eV. Owing to the above-described relation between the hole-transport materials used for the hole-injection layer 111, the first hole-transport layer 112a, and the second hole-transport layer 112b, holes can be injected into each layer smoothly, which can prevent an increase in driving voltage and deficiency of holes in the light-emitting layer 113.

The hole-transport material (the third organic compound) used for the second hole-transport layer 112b preferably has a hole-transport skeleton. A carbazole skeleton, a dibenzofuran skeleton, a dibenzothiophene skeleton, and an anthracene skeleton, with which the HOMO levels of the hole-transport materials do not become too high, are preferably used as the hole-transport skeleton.

### <Light-Emitting Layer>

The light-emitting layer 113 is a layer containing a light-emitting substance. The light-emitting layer 113 can contain one or more kinds of light-emitting substances. As the light-emitting substance, a substance that exhibits an emission color of blue, purple, bluish purple, green, yellowish green, yellow, orange, red, or the like is appropriately used. As the light-emitting substance, a substance that emits near-infrared light can also be used. When different light-emitting substances are used for a plurality of light-emitting layers, different emission colors can be exhibited (for example, complementary emission colors are combined to obtain white light emission). Furthermore, one light-emitting layer may contain different light-emitting substances.

The light-emitting layer 113 preferably includes one or more kinds of organic compounds (e.g., a host material and an assist material) in addition to the light-emitting substance (guest material). As the one or more kinds of organic compounds, one or both of the hole-transport material and the electron-transport material described in this embodiment can be used. As the one or more kinds of organic compounds, a bipolar material may be used.

There is no particular limitation on the light-emitting substance that can be used for the light-emitting layer 113, and it is possible to use a light-emitting substance that converts singlet excitation energy into light emission in the visible light region or the near-infrared light region or a light-emitting substance that converts triplet excitation energy into light emission in the visible light region or the near-infrared light region.

As an example of the light-emitting substance that converts singlet excitation energy into light, a substance that exhibits fluorescence (a fluorescent material) can be given; examples include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N-bis(3-methylphenyl)-N,N-bis[3-(9-phenyl-9H-fluoren-9-yl)phenyl]pyrene-1,6-diamine (abbreviation: 1,6mMemFLPAPrn), (N,N-diphenyl-N,N-bis[4-(9-phenyl-9H-fluoren-9-yl)phenyl]pyrene-1,6-diamine) (abbreviation: 1,6FLPAPrn), N,N-bis(dibenzofuran-2-yl)-N,N-diphenylpyrene-1,6-diamine (abbreviation: 1,6FrAPrn), N,N-bis(dibenzothiophen-2-yl)-N,N-diphenylpyrene-1,6-diamine (abbreviation: 1,6ThAPrn), N,N-(pyrene-1,6-diyl)bis[(N-phenylbenzo[b]naphtho[1,2-d]furan)-6-amine] (abbreviation: 1,6BnfAPrn), N,N-(pyrene-1,6-diyl)bis[(N-phenylbenzo[b]naphtho[1,2-d]furan)-8-amine](abbreviation: 1,6BnfAPrn-02), and N,N-(pyrene-1,6-diyl)bis[(6,N-diphenylbenzo[b]naphtho[1,2-d]furan)-8-amine] (abbreviation: 1,6BnfAPrn-03).

In addition, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra(tert-butyl)perylene (abbreviation: TBP), N,N′-(2-tert-butylanthracene-9,10-diyldi-4,1-phenylene)bis[N,N,N-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), 3,10-bis[N-(9-phenyl-9H-carbazol-2-yl)-N-phenylamino]naphtho[2,3-b; 6,7-b′]bisbenzofuran (abbreviation: 3,10PCA2Nbf(IV)-02), 3,10-bis[N-(dibenzofuran-3-yl)-N-phenylamino]naphtho[2,3-b; 6,7-b′]bisbenzofuran (abbreviation: 3,10FrA2Nbf(IV)-02), or the like.

Examples of the light-emitting substance that converts triplet excitation energy into light include a substance that exhibits phosphorescence (a phosphorescent material) and a thermally activated delayed fluorescence (TADF) material that exhibits thermally activated delayed fluorescence.

Examples of a phosphorescent material include an organometallic complex, a metal complex (platinum complex), and a rare earth metal complex. These substances exhibit different emission colors (emission peaks), and thus are used through appropriate selection as needed.

As a phosphorescent material that exhibits blue or green and whose emission spectrum has a peak wavelength at greater than or equal to 450 nm and less than or equal to 570 nm, the following substances can be given.

The examples include organometallic complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organometallic complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic complexes having an imidazole skeleton, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); and organometallic complexes in which a phenylpyridine derivative having an electron-withdrawing group is a ligand, such as bis[2-(4′,6′-difluorophenyl)pyridinato-N,C²]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF₃ppy)₂(pic)]), and bis[2-(4′,6′-difluorophenyl)pyridinato-N,C²′]iridium(III) acetylacetonate (abbreviation: FIr(acac)).

As a phosphorescent material that exhibits green or yellow and whose emission spectrum has a peak wavelength at greater than or equal to 495 nm and less than or equal to 590 nm, the following substances can be given.

The examples include organometallic iridium complexes including a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN3]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes including a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes including a pyridine skeleton, such as tris(2-phenylpyridinato-N,C²)iridium(III) (abbreviation: [Ir(ppy)₃]), bis(2-phenylpyridinato-N,C²)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²)iridium(III) (abbreviation: [Ir(pq)₃]), bis(2-phenylquinolinato-N,C²)iridium(III) acetylacetonate (abbreviation: [Ir(pq)₂(acac)]), [2-(4-phenyl-2-pyridinyl-κN)phenyl-κC]bis[2-(2-pyridinyl-κN)phenyl-κC]iridium(III) (abbreviation: [Ir(ppy)₂(4dppy)]), and bis[2-(2-pyridinyl-κN)phenyl-κC][2-(4-methyl-5-phenyl-2-pyridinyl-κN)phenyl-κC]; organometallic complexes such as bis(2,4-diphenyl-1,3-oxazolato-N,C²)iridium(III) acetylacetonate (abbreviation: [Ir(dpo)₂(acac)]), bis{2-[4′-(perfluorophenyl)phenyl]pyridinato-N,C²′}iridium(III) acetylacetonate (abbreviation: [Ir(p-PF-ph)₂(acac)]), and bis(2-phenylbenzothiazolato-N,C²)iridium(III) acetylacetonate (abbreviation: [Ir(bt)₂(acac)]); and rare earth metal complexes such as tris(acetylacetonato) (monophenanthroline)terbium(III) (abbreviation: [Tb(acac)₃(Phen)]).

As a phosphorescent material that exhibits yellow or red and whose emission spectrum has a peak wavelength at greater than or equal to 570 nm and less than or equal to 750 nm, the following substances can be given.

The examples include organometallic complexes including a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(d1npm)₂(dpm)]), and tris(4-t-butyl-6-phenylpyrimidinato)iridium(III) (abbreviation: [Ir(tBuppm)₃]); organometallic complexes including a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-N]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), (acetylacetonato)bis[2-methyl-3-phenylquinoxalinato-N,C′]iridium(III) (abbreviation: [Ir(mpq)₂(acac)]), (acetylacetonato)bis(2,3-diphenylquinoxalinato-N,C²′)iridium(III) (abbreviation: [Ir(dpq)₂(acac)]), (acetylacetonato)bis[2,3-bis(4-fluorophenyl)quinoxalinato]iridium(III) (abbreviation: [Ir(Fdpq)₂(acac)]), and bis{4,6-dimethyl-2-[5-(5-cyano-2-methylphenyl)-3-(3,5-dimethylphenyl)-2-pyrazinyl-N]phenyl-κC}(2,2,6,6-tetramethyl-3,5-heptanedionato-κ²O,O′)iridium(III) (abbreviation: [Ir(dmdppr-m5CP)₂(dpm)]); organometallic complexes including a pyridine skeleton, such as tris(1-phenylisoquinolinato-N,C²)iridium(III) (abbreviation: [Ir(piq)₃]), bis(1-phenylisoquinolinato-N,C²)iridium(III) acetylacetonate (abbreviation: [Ir(piq)₂(acac)]), and bis[4,6-dimethyl-2-(2-quinolinyl-κN)phenyl-κC] (2,4-pentanedionato-κ²O,O′)iridium(III); platinum complexes such as 2,3,7,8,12,13,17,18-octaethyl-21H,23H-porphyrinplatinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[l-(2-thenoyl)-3,3,3-trifluoroacetonato](monophenanthroline)europium(III) (abbreviation: [Eu(TTA)₃(Phen)]).

As the organic compounds (e.g., the host material and the assist material) used for the light-emitting layer 113, one or more kinds of substances having a larger energy gap than the light-emitting substance can be used.

In the case where the light-emitting substance used for the light-emitting layer 113 is a fluorescent material, an organic compound used in combination with the light-emitting substance is preferably an organic compound that has a high energy level in a singlet excited state and has a low energy level in a triplet excited state.

In terms of a preferable combination with the light-emitting substance (the fluorescent material or the phosphorescent material), specific examples of the organic compounds are shown below although some of them overlap with the above specific examples.

In the case where the light-emitting substance is a fluorescent material, examples of the organic compound that can be used in combination with the light-emitting substance include condensed polycyclic aromatic compounds, such as an anthracene derivative, a tetracene derivative, a phenanthrene derivative, a pyrene derivative, a chrysene derivative, and a dibenzo[g,p]chrysene derivative.

Specific examples of the organic compound (the host material) used in combination with the fluorescent material include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), PCPN, 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), 4-(9H-carbazol-9-yl)-4′-(10-phenyl-9-anthryl)triphenylamine (abbreviation: YGAPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), CzPA, 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)-biphenyl-4′-yl}anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

In the case where the light-emitting substance is a phosphorescent material, as the organic compound used in combination with the light-emitting substance, an organic compound that has higher triplet excitation energy (energy difference between a ground state and a triplet excited state) than the light-emitting substance is selected.

In the case where a plurality of organic compounds (e.g., a first host material and a second host material (or an assist material)) are used in combination with the light-emitting substance in order to form an exciplex, the plurality of organic compounds are preferably mixed with a phosphorescent material (in particular, an organometallic complex).

Such a structure makes it possible to efficiently obtain light emission utilizing ExTET (Exciplex-Triplet Energy Transfer), which is energy transfer from an exciplex to a light-emitting substance. Note that a combination of a plurality of organic compounds that easily forms an exciplex is preferable, and it is particularly preferable to combine a compound that easily accepts holes (a hole-transport material) and a compound that easily accepts electrons (an electron-transport material). As the hole-transport material and the electron-transport material, specifically, any of the materials described in this embodiment can be used. With this structure, high efficiency, low-voltage driving, and a long lifetime of the light-emitting device can be achieved at the same time.

In the case where the light-emitting substance is a phosphorescent material, examples of the organic compounds that can be used in combination with the light-emitting substance include an aromatic amine, a carbazole derivative, a dibenzothiophene derivative, a dibenzofuran derivative, a zinc-based metal complex, an aluminum-based metal complex, an oxadiazole derivative, a triazole derivative, a benzimidazole derivative, a quinoxaline derivative, a dibenzoquinoxaline derivative, a pyrimidine derivative, a triazine derivative, a pyridine derivative, a bipyridine derivative, and a phenanthroline derivative.

Among the above-described compounds, specific examples of the aromatic amine, (a compound having an aromatic amine skeleton), the carbazole derivative, the dibenzothiophene derivative (thiophene derivative), and the dibenzofuran derivative (furan derivative), which are organic compounds having a high hole-transport property, are the same as the compounds given above as specific examples of the hole-transport material.

Specific examples of the zinc-based metal complex and the aluminum-based metal complex, which are organic compounds having a high electron-transport property, include metal complexes including a quinoline skeleton or a benzoquinoline skeleton, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), and bis(8-quinolinolato)zinc(II) (abbreviation: Znq).

A metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), or the like can also be used.

Specific examples of the oxadiazole derivative, the triazole derivative, the benzimidazole derivative, the quinoxaline derivative, the dibenzoquinoxaline derivative, and the phenanthroline derivative, which are organic compounds having a high electron-transport property, include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOs), bathophenanthroline (abbreviation: BPhen), bathocuproine (abbreviation: BCP), 2,9-bis(naphthalen-2-yl)-4,7-diphenyl-1,10-phenanthroline (abbreviation: NBPhen), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), and 6-[3-(dibenzothiophen-4-yl)phenyl]dibenzo[f,h]quinoxaline (abbreviation: 6mDBTPDBq-II).

Specific examples of a heterocyclic compound having a diazine skeleton, a heterocyclic compound having a triazine skeleton, and a heterocyclic compound having a pyridine skeleton, which are organic compounds having a high electron-transport property, include 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 3,5-bis(3-(9H-carbazol-9-yl)phenyl)pyridine (abbreviation: 35DCzPPy), and 1,3,5-tri[3-(3-pyridyl)phenyl]benzene (abbreviation: TmPyPB).

As the organic compound having a high electron-transport property, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can also be used.

The TADF material is a material that can up-convert a triplet excited state into a singlet excited state (reverse intersystem crossing) using a little thermal energy and efficiently exhibit light emission (fluorescence) from the singlet excited state. The thermally activated delayed fluorescence is efficiently obtained under the condition where the energy difference between the triplet excited level and the singlet excited level is greater than or equal to 0 eV and less than or equal to 0.2 eV, preferably greater than or equal to 0 eV and less than or equal to 0.1 eV. Note that delayed fluorescence by the TADF material refers to light emission having a spectrum similar to that of normal fluorescence and an extremely long lifetime. The lifetime is 10⁻⁶ seconds or longer, preferably 10⁻³ seconds or longer.

Examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

It is also possible to use a heterocyclic compound having a π-electron rich heteroaromatic ring and a π-electron deficient heteroaromatic ring, such as 2-(biphenyl-4-yl)-4,6-bis(12-phenylindolo[2,3-a]carbazol-11-yl)-1,3,5-triazine (abbreviation: PIC-TRZ), PCCzPTzn, 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Note that a substance in which a π-electron rich heteroaromatic ring is directly bonded to a π-electron deficient heteroaromatic ring is particularly preferable because both the donor property of the π-electron rich heteroaromatic ring and the acceptor property of the π-electron deficient heteroaromatic ring are improved and the energy difference between the singlet excited state and the triplet excited state becomes small.

Note that in the case where a TADF material is used, the TADF material can also be used in combination with another organic compound. In particular, the TADF material can be used in combination with the host material, the hole-transport material, or the electron-transport material described above.

Furthermore, when used in combination with a low molecular material or a high molecular material, the above materials can be used to form the light-emitting layer 113. For the deposition, a known method (an evaporation method, a coating method, a printing method, or the like) can be used as appropriate.

### <Electron-Transport Layer>

The electron-transport layer 114 is a layer transporting electrons, which are injected from the second electrode 102 by the electron-injection layer 115, to the light-emitting layer 113. Note that the electron-transport layer 114 is a layer containing an electron-transport material. The electron-transport material used for the electron-transport layer 114 is preferably a substance having an electron mobility greater than or equal to 1×10⁻⁶ cm²/Vs. Note that other substances can also be used as long as they have a property of transporting more electrons than holes.

As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

As the electron-transport material, specifically, the above-described materials can be used.

In the light-emitting device of one embodiment of the present invention, the electron-transport layer 114 preferably contains an electron-transport material and an organometallic complex of an alkali metal or an alkaline earth metal.

In this case, the electron-transport material preferably has an anthracene skeleton, and further preferably has an anthracene skeleton and a heterocyclic skeleton. The heterocyclic skeleton is preferably a nitrogen-containing five-membered ring skeleton. It is particularly preferable that the nitrogen-containing five-membered ring skeleton include two heteroatoms in a ring, like a pyrazol ring, an imidazole ring, an oxazole ring, or, a thiazole ring.

As the organometallic complex of an alkali metal or an alkaline earth metal, an organic complex of lithium is preferable, and 8-quinolinolato-lithium (abbreviation: Liq) is particularly preferable.

Lowering the electron-transport property of the electron-transport layer 114 enables control of the amount of electrons injected into the light-emitting layer 113 and can prevent the light-emitting layer 113 from having excess electrons. In addition, when the light-emitting region in the light-emitting layer 113 is widened to disperse the burden on materials contained in the light-emitting layer 113, a light-emitting device with a long lifetime and high emission efficiency can be provided.

The electron-transport layer 114 preferably includes portions where the mixing ratio of the electron-transport material to the organometallic complex of an alkali metal or an alkaline earth metal differs in the thickness direction. The electron-transport layer 114 may have a concentration gradient and may have a stacked-layer structure of a plurality of layers having different mixing ratios of the electron-transport material to the organometallic complex of an alkali metal or an alkaline earth metal.

The mixing ratios can be estimated from the amount of atoms or molecules detected by time-of-flight secondary ion mass spectrometry (ToF-SIMS). In portions that contain the same two kinds of materials with different mixture ratios, values measured by ToF-SIMS analysis correspond to the amounts of target atoms or molecules. Therefore, comparing the detected amounts of the electron-transport material and the organometallic complex allows estimation of their mixture ratio.

The amount of organometallic complex contained in the electron-transport layer 114 is preferably smaller on the second electrode 102 side than on the first electrode 101 side. In other words, the electron-transport layer 114 is preferably formed such that the concentration of the organometallic complex increases from the second electrode 102 side to the first electrode 101 side. That is, in the electron-transport layer 114, a portion where the amount of electron-transport material is small is closer to the light-emitting layer 113 than a portion where the amount of electron-transport material is large is. In other words, in the electron-transport layer 114, a portion where the amount of organometallic complex is large is closer to the light-emitting layer 113 than a portion where the amount of organometallic complex is small is.

A change in carrier balance in the light-emitting device of one embodiment of the present invention is probably caused by a change in electron mobility of the electron-transport layer 114. In the light-emitting device of one embodiment of the present invention, there is a concentration difference of the organometallic complex of an alkali metal or an alkaline earth metal in the electron-transport layer 114. The electron-transport layer 114 includes a region having a high concentration of the organometallic complex between the region having a low concentration of the organometallic complex and the light-emitting layer 113. That is, the region with a low concentration of the organometallic complex is closer to the second electrode 102 than the region with a high concentration of the organometallic complex is. Since the electron mobility of the electron-transport layer 114 becomes higher as the concentration of the organometallic complex is higher, the electron mobility of the electron-transport layer 114 is limited by the region with a low concentration of the organometallic complex.

An organometallic complex of an alkali metal or an alkaline earth metal diffuses from the first electrode 101 side to the second electrode 102 side (from the region with a high concentration to the region with a low concentration) by voltage applied to the light-emitting device for driving. Since the region with a high concentration of the organometallic complex is closer to the first electrode 101 than the region with a low concentration of the organometallic complex is, the electron mobility of the electron-transport layer 114 increases with driving. This causes a change in carrier balance in the light-emitting device, which is accompanied by the movement of the recombination region; thus, the light-emitting device with a long lifetime can be obtained.

The light-emitting device of one embodiment of the present invention having the above structure has an extremely long lifetime. In particular, a lifetime in a region with extremely small decay, i.e., approximately LT95 (a time taken until the luminance decreases to 95% of the initial luminance), can be significantly extended.

### <Electron-Injection Layer>

The electron-injection layer 115 is a layer that contains a material with a high electron-injection property. For the electron-injection layer 115, an alkali metal, an alkaline earth metal, or a compound thereof such as Liq, lithium fluoride (LiF), cesium fluoride (CsF), calcium fluoride (CaF₂), or lithium oxide (LiOₓ) can be used. A rare earth metal compound like erbium fluoride (ErF₃) can also be used. In addition, an electride may be used for the electron-injection layer 115. Examples of the electride include a substance in which electrons are added at a high concentration to a mixed oxide of calcium and aluminum. Note that any of the above-described substances for forming the electron-transport layer 114 can also be used.

For the electron-injection layer 115, a composite material containing an electron-transport material and a donor material (an electron-donating material) may be used. Such a composite material is excellent in an electron-injection property and an electron-transport property because electrons are generated in the organic compound by the electron donor. The organic compound here is preferably a material excellent in transporting the generated electrons; specifically, for example, the above-described electron-transport materials used for the electron-transport layer 114 (e.g., a metal complex or a heteroaromatic compound) can be used. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, ytterbium, and the like are given. In addition, an alkali metal oxide and an alkaline earth metal oxide are preferable, and lithium oxide, calcium oxide, barium oxide, and the like are given. A Lewis base such as magnesium oxide can be used. Furthermore, an organic compound such as tetrathiafulvalene (abbreviation: TTF) can be used.

### <Charge-Generation Layer>

In the light-emitting device illustrated in FIG. 1C, the charge-generation layer 104 has a function of injecting electrons into the EL layer 103a and injecting holes into the EL layer 103b when voltage is applied between the first electrode 101 (the anode) and the second electrode 102 (the cathode).

The charge-generation layer 104 may contain a hole-transport material and an acceptor material (an electron-accepting material) or may contain an electron-transport material and a donor material. Forming the charge-generation layer 104 with such a structure can suppress an increase in the driving voltage that would be caused by stacking EL layers.

For the charge-generation layer 104, a composite material of the first organic compound and the second organic compound can be used.

As the hole-transport material, the acceptor material, the electron-transport material, and the donor material, the above-described materials can also be used.

For fabrication of the light-emitting device described in this embodiment, a vacuum process such as an evaporation method or a solution process such as a spin coating method or an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the functional layers (the hole-injection layer, the hole-transport layer, the light-emitting layer, the electron-transport layer, and the electron-injection layer) included in the EL layer and the charge-generation layer can be formed by an evaporation method (a vacuum evaporation method or the like), a coating method (a dip coating method, a die coating method, a bar coating method, a spin coating method, a spray coating method, or the like), a printing method (an ink-jet method, a screen printing (stencil) method, an offset printing (planography) method, a flexography (relief printing) method, a gravure printing method, a micro-contact printing method, or the like), or the like.

Materials of the functional layers included in the EL layer 103 and the charge-generation layer are not limited to the above-described corresponding materials. For example, as the materials of the functional layers, a high molecular compound (e.g., an oligomer, a dendrimer, and a polymer), a middle molecular compound (a compound between a low molecular compound and a high molecular compound with a molecular weight of greater than or equal to 400 and less than or equal to 4000), or an inorganic compound (e.g., a quantum dot material) may be used. As the quantum dot material, a colloidal quantum dot material, an alloyed quantum dot material, a core-shell quantum dot material, a core quantum dot material, or the like can be used.

As described above, a hole-transport material with a low refractive index is used for the first layer of the light-emitting device of this embodiment. In addition, over the first layer, a layer containing a material with a high electron-accepting property with respect to the hole-transport material is included as the second layer. Accordingly, a light-emitting device with high emission efficiency and a low driving voltage can be obtained.

This embodiment can be combined with any of the other embodiments as appropriate. In the case where a plurality of structure examples are described in one embodiment in this specification, the structure examples can be combined as appropriate.

### Embodiment 2

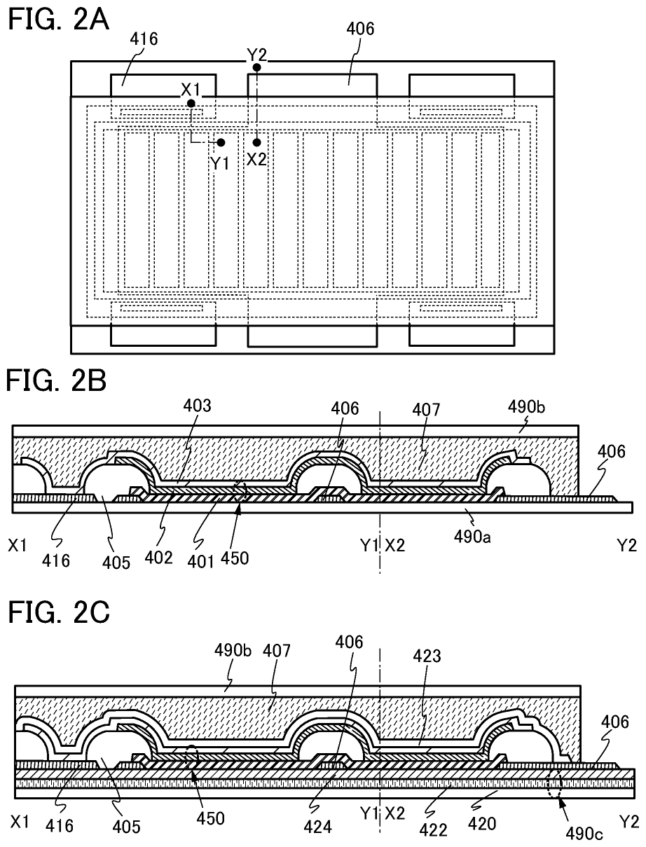

In this embodiment, a light-emitting apparatus of one embodiment of the present invention will be described with reference to FIG. 2 to FIG. 5.

### Structure Example 1 of Light-Emitting Apparatus

FIG. 2A is a top view of a light-emitting apparatus, and FIG. 2B and FIG. 2C are cross-sectional views along the dashed-dotted lines X1-Y1 and X2-Y2 in FIG. 2A. The light-emitting apparatus illustrated in FIG. 2A to FIG. 2C can be used as a lighting device, for example. The light-emitting apparatus can have a bottom-emission, top-emission, or dual-emission structure.

The light-emitting apparatus illustrated in FIG. 2B includes a substrate 490a, a substrate 490b, a conductive layer 406, a conductive layer 416, an insulating layer 405, an organic EL device 450 (a first electrode 401, an EL layer 402, and a second electrode 403), and an adhesive layer 407. The organic EL device 450 can also be referred to as a light-emitting element, an organic EL element, a light-emitting device, or the like. For the organic EL device 450, the light-emitting device of one embodiment of the present invention described in Embodiment 1 is preferably used.

The organic EL device 450 includes the first electrode 401 over the substrate 490a, the EL layer 402 over the first electrode 401, and the second electrode 403 over the EL layer 402. The organic EL device 450 is sealed by the substrate 490a, the adhesive layer 407, and the substrate 490b.

End portions of the first electrode 401, the conductive layer 406, and the conductive layer 416 are each covered with the insulating layer 405. The conductive layer 406 is electrically connected to the first electrode 401, and the conductive layer 416 is electrically connected to the second electrode 403. The conductive layer 406 covered with the insulating layer 405 with the first electrode 401 positioned therebetween functions as an auxiliary wiring and is electrically connected to the first electrode 401. It is preferable that the auxiliary wiring electrically connected to the electrode of the organic EL device 450 be provided, in which case a voltage drop due to the resistance of the electrode can be inhibited. The conductive layer 406 may be provided over the first electrode 401. An auxiliary wiring that is electrically connected to the second electrode 403 may be provided, for example, over the insulating layer 405.

For each of the substrate 490a and the substrate 490b, glass, quartz, ceramic, sapphire, an organic resin, or the like can be used. When a flexible material is used for the substrate 490a and the substrate 490b, the flexibility of the display device can be increased.

A light-emitting surface of the light-emitting apparatus may be provided with one or more of a light extraction structure for increasing the light extraction efficiency, an antistatic film preventing the attachment of a foreign substance, a water repellent film suppressing the attachment of stain, a hard coat film suppressing generation of a scratch in use, an impact absorption layer, and the like.

Examples of an insulating material that can be used for the insulating layer 405 include a resin such as an acrylic resin and an epoxy resin, and an inorganic insulating material such as silicon oxide, silicon oxynitride, silicon nitride oxide, silicon nitride, and aluminum oxide.

For the adhesive layer 407, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component resin may be used. An adhesive sheet or the like may be used.

The light-emitting apparatus illustrated in FIG. 2C includes a barrier layer 490c, the conductive layer 406, the conductive layer 416, the insulating layer 405, the organic EL device 450, the adhesive layer 407, a barrier layer 423, and the substrate 490b.

The barrier layer 490c illustrated in FIG. 2C includes a substrate 420, an adhesive layer 422, and an insulating layer 424 having a high barrier property.

In the light-emitting apparatus illustrated in FIG. 2C, the organic EL device 450 is placed between the insulating layer 424 having a high barrier property and the barrier layer 423. Thus, even when resin films with relatively low water resistance or the like are used as the substrate 420 and the substrate 490b, a reduction in lifetime due to entry of impurities such as water into the organic EL device can be suppressed.

For each of the substrate 420 and the substrate 490b, for example, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for the substrate 420 and the substrate 490b.

An inorganic insulating film is preferably used as the insulating layer 424 having a high barrier property. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

The barrier layer 423 preferably includes at least a single-layer inorganic film. For example, the barrier layer 423 can have a single-layer structure of an inorganic film or a stacked-layer structure of an inorganic film and an organic film. As the inorganic film, the above-described inorganic insulating film is preferable. An example of the stacked-layer structure is a structure in which a silicon oxynitride film, a silicon oxide film, an organic film, a silicon oxide film, and a silicon nitride film are formed in this order. When the barrier layer has a stacked-layer structure of an inorganic film and an organic film, entry of impurities that can enter the organic EL device 450 (typically, hydrogen, water, and the like) can be suitably suppressed.

The insulating layer 424 having a high barrier property and the organic EL device 450 can be directly formed on the substrate 420 having flexibility. In that case, the adhesive layer 422 is not necessary. The insulating layer 424 and the organic EL device 450 can be formed over a rigid substrate with a separation layer provided therebetween and then transferred to the substrate 420. For example, the insulating layer 424 and the organic EL device 450 may be transferred to the substrate 420 in the following manner: the insulating layer 424 and the organic EL device 450 are separated from the rigid substrate by applying heat, force, laser light, or the like to the separation layer, and then the insulating layer 424 and the organic EL device 450 are bonded to the substrate 420 with the use of the adhesive layer 422. For the separation layer, a stacked-layer structure of inorganic films including a tungsten film and a silicon oxide film, or an organic resin film of polyimide or the like can be used, for example. In the case where a rigid substrate is used, the insulating layer 424 can be formed at high temperature as compared to the case where a resin substrate or the like is used; thus, the insulating layer 424 can have high density and an excellent barrier property.

### Structure Example 2 of Light-Emitting Apparatus

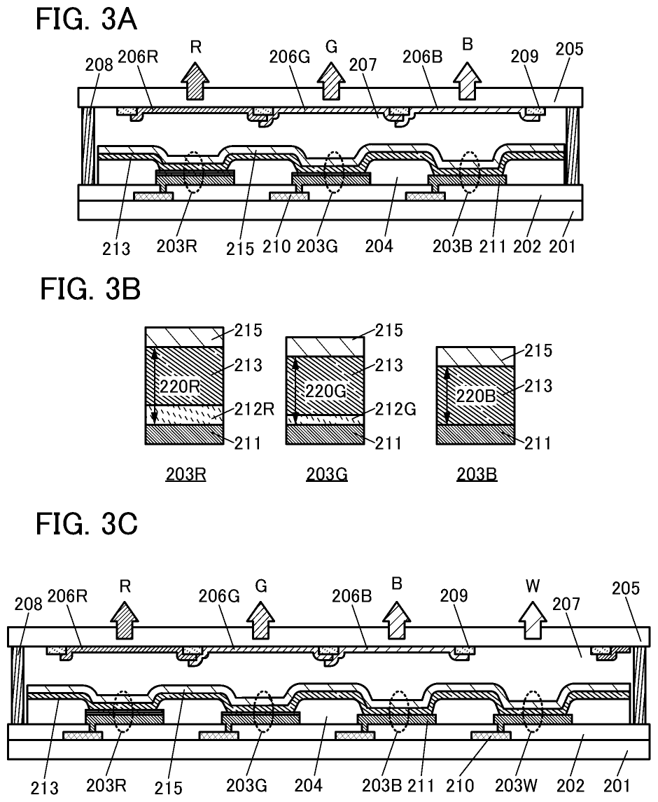

FIG. 3A is a top view of the light-emitting apparatus. The light-emitting apparatus illustrated in FIG. 3A is an active-matrix light-emitting apparatus in which a transistor is electrically connected to a light-emitting device.

The light-emitting apparatus illustrated in FIG. 3A includes a substrate 201, a transistor 210, a light-emitting device 203R, a light-emitting device 203G, a light-emitting device 203B, a color filter 206R, a color filter 206G, a color filter 206B, a substrate 205, and the like.

In FIG. 3A, the transistor 210 is provided over the substrate 201, the insulating layer 202 is provided over the transistor 210, and the light-emitting devices 203R, 203G, and 203B are provided over the insulating layer 202.

The transistor 210 and the light-emitting devices 203R, 203G, and 203B are sealed in a space 207 surrounded by the substrate 201, the substrate 205, and the adhesive layer 208. The space 207 can be filled with, for example, a reduced-pressure atmosphere, an inert atmosphere, or a resin.

In the light-emitting apparatus illustrated in FIG. 3A, one pixel includes a red subpixel (R), a green subpixel (G), and a blue subpixel (B).

The light-emitting apparatus of one embodiment of the present invention includes a plurality of pixels arranged in a matrix. One pixel includes one or more subpixels. One subpixel includes one light-emitting device. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y).

FIG. 3B illustrates detailed structures of the light-emitting device 203R, the light-emitting device 203G, and the light-emitting device 203B. The light-emitting devices 203R, 203G, and 203B include the EL layer 213 in common, and have microcavity structures in which the optical path length between electrodes of each light-emitting device is adjusted in accordance with the emission color of the light-emitting device. The light-emitting apparatus of this embodiment preferably includes the light-emitting device of one embodiment of the present invention described in Embodiment 1. In particular, in the case where a green phosphorescent device is used as the light-emitting device 203G, the light-emitting device 203G preferably employs the structure of the light-emitting device of one embodiment of the present invention, in which case high emission efficiency and a low driving voltage can be achieved. Note that the light-emitting device of one embodiment of the present invention can also be used as not only the light-emitting device 203G but also the light-emitting device 203R, the light-emitting device 203B, or the like.

The first electrode 211 functions as a reflective electrode and the second electrode 215 functions as a transflective electrode.

In the light-emitting device 203R, the optical path length between the first electrode 211 and the second electrode 215 is adjusted to be an optical path length 220R in order to enhance the intensity of red light. Similarly, in the light-emitting device 203G, the optical path length between the first electrode 211 and the second electrode 215 is adjusted to be an optical path length 220G in order to enhance the intensity of green light. In the light-emitting device 203B, the optical path length between the first electrode 211 and the second electrode 215 is adjusted to be an optical path length 220B in order to enhance the intensity of blue light.

Optical adjustment can be performed in such a manner that a conductive layer 212R is formed over the first electrode 211 in the light-emitting device 203R and a conductive layer 212G is formed over the first electrode 211 in the light-emitting device 203G as illustrated in FIG. 3B. Furthermore, in the light-emitting device 203B, the optical path length 220B may be adjusted by forming a conductive layer whose thickness is different from those of the conductive layer 212R and the conductive layer 212G over the first electrode 211. Note that as illustrated in FIG. 3A, end portions of the first electrode 211, the conductive layer 212R, and the conductive layer 212G are covered with an insulating layer 204.

The light-emitting apparatus illustrated in FIG. 3A is a top-emission light-emitting apparatus, which emits light obtained from the light-emitting devices through color filters formed on the substrate 205. The color filter can transmit visible light in a specific wavelength range and block visible light in a specific wavelength range.

In the red subpixel (R), light from the light-emitting device 203R is emitted through the red color filter 206R. As illustrated in FIG. 3A, the color filter 206R that transmits only light in the red wavelength range is provided in a position overlapping with the light-emitting device 203R, whereby red light emission can be obtained from the light-emitting device 203R.

Similarly, in the green subpixel (G), light from the light-emitting device 203G is emitted through the green color filter 206G, and in the blue subpixel (B), light from the light-emitting device 203B is emitted through the blue color filter 206B.

Note that the substrate 205 may be provided with a black matrix 209 (also referred to as a black layer). In this case, an end portion of the color filter preferably overlap with the black matrix 209. Furthermore, the color filters for the respective colors and the black matrix 209 may be covered with an overcoat layer that transmits visible light.

In the light-emitting apparatus illustrated in FIG. 3C, one pixel includes the red subpixel (R), the green subpixel (G), the blue subpixel (B), and a white subpixel (W). In FIG. 3C, light from a light-emitting device 203W included in the white subpixel (W) is emitted to the outside of the light-emitting apparatus without passing through a color filter.

Note that the optical path length between the first electrode 211 and the second electrode 215 in the light-emitting device 203W may be the same as the optical path length in any one of the light-emitting devices 203R, 203G, and 203B or may be different from the optical path lengths in the light-emitting devices 203R, 203G, and 203B.

In the case where the intensity of blue light is desired to be enhanced, for example, in the case where light emitted from the light-emitting device 203W is white light with a low color temperature, the optical path length in the light-emitting device 203W is preferably equal to the optical path length 220B in the light-emitting device 203B, as illustrated in FIG. 3C. Thus, light obtained from the light-emitting device 203W can be made closer to white light with a desired color temperature.

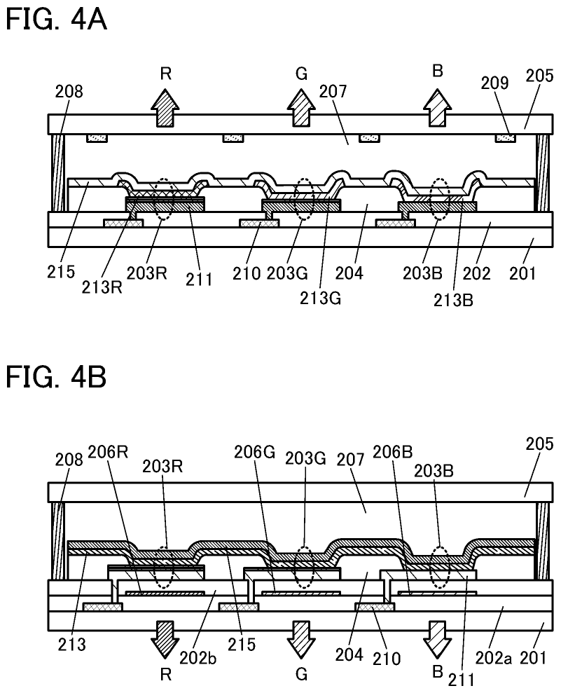

Although FIG. 3A illustrates an example where the light-emitting devices included in the subpixels use the EL layer 213 in common, different EL layers may be used for the light-emitting devices included in the subpixels as illustrated in FIG. 4A. The above-described microcavity structure can also be applied to FIG. 4A.

FIG. 4A illustrates an example where the light-emitting device 203R includes an EL layer 213R, the light-emitting device 203G includes an EL layer 213G, and the light-emitting device 203B includes an EL layer 213B. The EL layers 213R, 213G, and 213B may include a common layer. For example, the EL layers 213R, 213G, and 213B may include light-emitting layers with different structures and a common layer as another layer. In FIG. 4A, light emitted from the light-emitting devices 203R, 203G, and 203B may be emitted through a color filter or without passing through a color filter.

Although FIG. 3A illustrates the top-emission light-emitting apparatus, a light-emitting apparatus with a (bottom emission) structure in which light is extracted to the substrate 201 side where the transistor 210 is formed as illustrated in FIG. 4B is also one embodiment of the present invention.

In the bottom-emission light-emitting apparatus, color filters for the respective colors are preferably provided between the substrate 201 and the light-emitting devices. FIG. 4B illustrates an example where the transistor 210 is formed over the substrate 201, an insulating layer 202a is formed over the transistor 210, the color filters 206R, 206G, and 206B are formed over the insulating layer 202a, an insulating layer 202b is formed over the color filters 206R, 206G, and 206B, and the light-emitting devices 203R, 203G, and 203B are formed over the insulating layer 202b.

In the case of the top-emission light-emitting apparatus, a light-blocking substrate or a light-transmitting substrate can be used as the substrate 201, and a light-transmitting substrate can be used as the substrate 205.

In the case of the bottom-emission light-emitting apparatus, a light-blocking substrate or a light-transmitting substrate can be used as the substrate 205, and a light-transmitting substrate can be used as the substrate 201.

### Structure Example 3 of Light-Emitting Apparatus

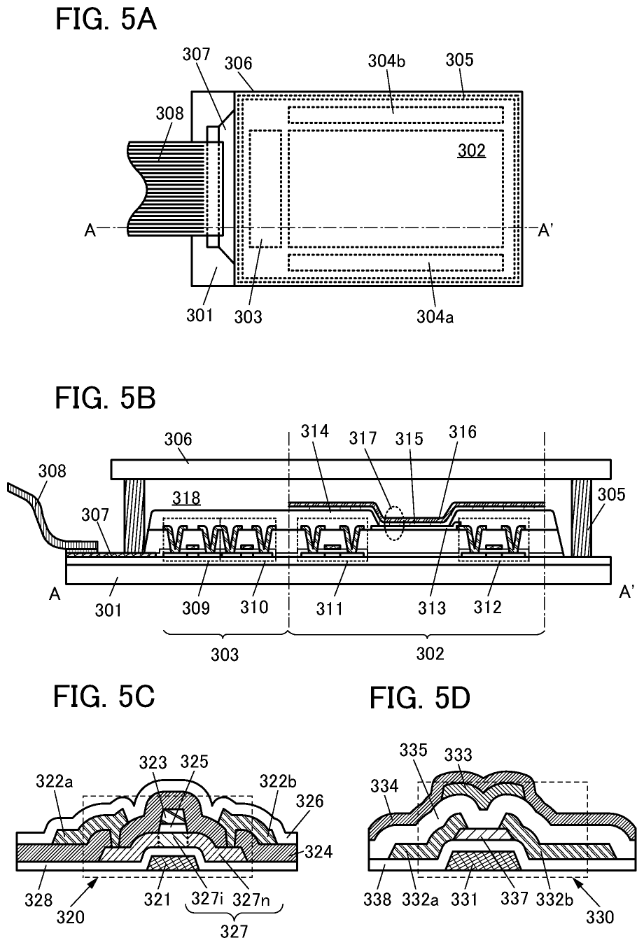

The light-emitting apparatus of one embodiment of the present invention can be of passive matrix type or active matrix type. An active-matrix light-emitting apparatus will be described with reference to FIG. 5.

FIG. 5A is a top view of the light-emitting apparatus. FIG. 5B is a cross-sectional view along the dashed-dotted line A-A′ illustrated in FIG. 5A.

The active-matrix light-emitting apparatus illustrated in FIG. 5A and FIG. 5B includes a pixel portion 302, a circuit portion 303, a circuit portion 304a, and a circuit portion 304b.

Each of the circuit portion 303, the circuit portion 304a, and the circuit portion 304b can function as a scan line driver circuit (a gate driver) or a signal line driver circuit (a source driver), or may be a circuit that electrically connects the pixel portion 302 to an external gate driver or source driver.

A lead wiring 307 is provided over a first substrate 301. The lead wiring 307 is electrically connected to an FPC 308 that is an external input terminal. The FPC 308 transmits signals (e.g., a video signal, a clock signal, a start signal, and a reset signal) and a potential from the outside to the circuit portion 303, the circuit portion 304a, and the circuit portion 304b. The FPC 308 may be provided with a printed wiring board (PWB). The structure illustrated in FIG. 5A and FIG. 5B can also be referred to as a light-emitting module including a light-emitting device (or a light-emitting apparatus) and an FPC.

The pixel portion 302 includes a plurality of pixels each including an organic EL device 317, a transistor 311, and a transistor 312. The transistor 312 is electrically connected to a first electrode 313 included in the organic EL device 317. The transistor 311 functions as a switching transistor. The transistor 312 functions as a current control transistor. Note that the number of transistors included in each pixel is not particularly limited and can be set appropriately as needed.

The circuit portion 303 includes a plurality of transistors, such as a transistor 309 and a transistor 310. The circuit portion 303 may be configured with a circuit including transistors having the same conductivity type (either n-channel transistors or p-channel transistors), or may be configured with a CMOS circuit including an n-channel transistor and a p-channel transistor. Furthermore, a driver circuit may be provided outside.

There is no particular limitation on the structure of the transistor included in the light-emitting apparatus of this embodiment. For example, a planar transistor, a staggered transistor, or an inverted staggered transistor can be used. A top-gate or a bottom-gate transistor structure may be used; or gates may be provided above and below a semiconductor layer where a channel is formed.

There is no particular limitation on the crystallinity of a semiconductor material used for the transistor, and an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of the transistor characteristics can be suppressed.

It is preferable that the semiconductor layer of the transistor contain a metal oxide (also referred to as an oxide semiconductor); or the semiconductor layer of the transistor may contain silicon. Examples of silicon include amorphous silicon and crystalline silicon (e.g., low-temperature polysilicon and single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable to use an oxide containing indium (In), gallium (Ga), and zinc (Zn) (also referred to as IGZO) for the semiconductor layer.

In the case where the semiconductor layer is an In-M-Zn oxide, a sputtering target used for depositing the In-M-Zn oxide preferably has the atomic proportion of In higher than or equal to the atomic proportion of M. Examples of the atomic ratio of the metal elements in such a sputtering target include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:6, In:M:Zn=5:1:7, In:M:Zn=5:1:8, In:M:Zn=6:1:6, and In:M:Zn=5:2:5.

The transistors included in the circuit portion 303, the circuit portion 304a, and the circuit portion 304b and the transistors included in the pixel portion 302 may have the same structure or different structures. A plurality of transistors included in the circuit portion 303, the circuit portion 304a, and the circuit portion 304b may have the same structure or two or more kinds of structures. Similarly, a plurality of transistors included in the pixel portion 302 may have the same structure or two or more kinds of structures.

An end portion of the first electrode 313 is covered with an insulating layer 314. For the insulating layer 314, one or both of an organic compound such as a negative photosensitive resin or a positive photosensitive resin (acrylic resin), and an inorganic compound such as silicon oxide, silicon oxynitride, or silicon nitride can be used. An upper end portion or a lower end portion of the insulating layer 314 preferably has a curved surface with curvature. In that case, favorable coverage with a film formed over the insulating layer 314 can be obtained.

An EL layer 315 is provided over the first electrode 313, and a second electrode 316 is provided over the EL layer 315. The EL layer 315 includes at least one of a light-emitting layer, a hole-injection layer, a hole-transport layer, an electron-transport layer, an electron-injection layer, and a charge-generation layer. As the organic EL device 317, the light-emitting device of one embodiment of the present invention described in Embodiment 1 is preferably used. This allows the organic EL device 317 to have higher emission efficiency and a lower driving voltage.

The plurality of transistors and the plurality of organic EL devices 317 are sealed by the first substrate 301, a second substrate 306, and a sealant 305. A space 318 surrounded by the first substrate 301, the second substrate 306, and the sealant 305 may be filled with an inert gas (e.g., nitrogen or argon) or an organic substance (including the sealant 305).

An epoxy resin, glass frit, or the like can be used for the sealant 305. A material that transmits moisture and oxygen as little as possible is preferably used for the sealant 305. In the case where glass frit is used for the sealant, the first substrate 301 and the second substrate 306 are preferably glass substrates in terms of adhesion.

FIG. 5C and FIG. 5D illustrate examples of transistors that can be used in a light-emitting apparatus.

A transistor 320 illustrated in FIG. 5C includes a conductive layer 321 functioning as a gate, an insulating layer 328 functioning as a gate insulating layer, a semiconductor layer 327 including a channel formation region 327i and a pair of low-resistance regions 327n, a conductive layer 322a connected to one of the pair of low-resistance regions 327n, a conductive layer 322b connected to the other of the pair of low-resistance regions 327n, an insulating layer 325 functioning as a gate insulating layer, a conductive layer 323 functioning as a gate, and an insulating layer 324 covering the conductive layer 323. The insulating layer 328 is positioned between the conductive layer 321 and the channel formation region 327i. The insulating layer 325 is positioned between the conductive layer 323 and the channel formation region 327i. The transistor 320 is preferably covered with an insulating layer 326. The insulating layer 326 may be included as a component in the transistor 320.

The conductive layer 322a and the conductive layer 322b are each connected to the low-resistance region 327n through openings in the insulating layer 324. One of the conductive layer 322a and the conductive layer 322b functions as a source and the other functions as a drain.

The insulating layer 325 is provided to overlap with at least the channel formation region 327i of the semiconductor layer 327. The insulating layer 325 may cover top surfaces and side surfaces of the pair of low-resistance regions 327n.

A transistor 330 illustrated in FIG. 5D includes a conductive layer 331 functioning as a gate, an insulating layer 338 functioning as a gate insulating layer, a conductive layer 332a and a conductive layer 332b which function as a source and a drain, a semiconductor layer 337, an insulating layer 335 functioning as a gate insulating layer, and a conductive layer 333 functioning as a gate. The insulating layer 338 is positioned between the conductive layer 331 and the semiconductor layer 337. The insulating layer 335 is positioned between the conductive layer 333 and the semiconductor layer 337. The transistor 330 is preferably covered with an insulating layer 334. The insulating layer 334 may be included as a component in the transistor 330.

The structure in which the semiconductor layer where a channel is formed is provided between two gates is used for the transistor 320 and the transistor 330. The two gates may be connected to each other and supplied with the same signal to drive the transistor. Alternatively, a potential for adjusting the threshold voltage may be supplied to one of the two gates and a potential for driving may be supplied to the other to adjust the threshold voltage of the transistor.

A material through which impurities such as water and hydrogen do not easily diffuse is preferably used for at least one of the insulating layers that cover the transistors. Thus, such an insulating layer can function as a barrier layer. Such a structure can effectively inhibit diffusion of impurities into the transistors from the outside and increase the reliability of the light-emitting apparatus.

An inorganic insulating film is preferably used as the insulating layer 325, the insulating layer 326, the insulating layer 328, the insulating layer 334, the insulating layer 335, and the insulating layer 338. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

Note that as materials that can be used for the conductive layers included in the light-emitting apparatus, metals such as aluminum, titanium, chromium, nickel, copper, yttrium, zirconium, molybdenum, silver, tantalum, and tungsten, alloys containing these metals as its main component, and the like can be given. A single layer or stacked-layer structure including a film including these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. Copper containing manganese is preferably used because it increases controllability of a shape by etching.

This embodiment can be combined with the other embodiments as appropriate.

### Embodiment 3

In this embodiment, a light-receiving device, a light-emitting and light-receiving device, and a light-emitting and light-receiving apparatus of one embodiment of the present invention will be described with reference to drawings.

### Structure Example of Light-Receiving Device

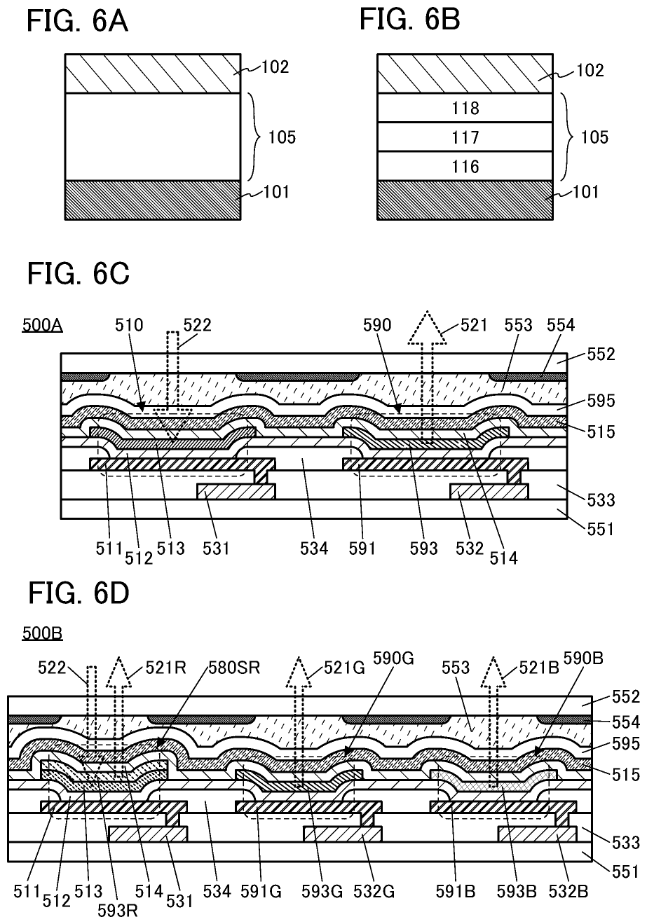

In this embodiment, a light-receiving device having a function of detecting visible light or near-infrared light will be described. FIG. 6A and FIG. 6B illustrate examples of a light-receiving device including a layer including an organic compound between a pair of electrodes.

The light-receiving device illustrated in FIG. 6A has a structure in which a layer 105 including an organic compound is interposed between the first electrode 101 and the second electrode 102. The layer 105 including an organic compound includes at least an active layer.

FIG. 6B illustrates an example of a stacked-layer structure of the layer 105 including an organic compound. This embodiment shows an example where the first electrode 101 functions as an anode and the second electrode 102 functions as a cathode. When the light-receiving device is driven by application of reverse bias between the first electrode 101 and the second electrode 102, light entering the light-receiving device can be detected and charge can be generated and extracted as current. The layer 105 including an organic compound has a structure in which a hole-transport layer 116, an active layer 117, and an electron-transport layer 118 are sequentially stacked over the first electrode 101. Each of the hole-transport layer 116, the active layer 117, and the electron-transport layer 118 may have a single-layer structure or a stacked-layer structure. When the first electrode 101 serves as a cathode and the second electrode 102 serves as an anode, the stacking order is reversed.

The active layer 117 includes a semiconductor. Examples of the semiconductor include an inorganic semiconductor such as silicon and an organic semiconductor including an organic compound. This embodiment shows an example where an organic semiconductor is used as the semiconductor included in the active layer. The use of an organic semiconductor is preferable because a light-emitting layer of a light-emitting device and the active layer 117 can be formed by the same method (e.g., a vacuum evaporation method) and thus the same manufacturing device can be used.

Examples of an n-type semiconductor material included in the active layer 117 include electron-accepting organic semiconductor materials such as fullerene (e.g., C60 and C70) and fullerene derivatives.

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material included in the active layer 117 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Other examples of the p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably higher than the HOMO level of the electron-accepting organic semiconductor material. The LUMO level of the electron-donating organic semiconductor material is preferably higher than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can improve the carrier-transport property.

For example, the active layer 117 is preferably formed by co-evaporation of an n-type semiconductor and a p-type semiconductor. Alternatively, the active layer 117 may have a stacked-layer structure of a layer including an n-type semiconductor and a layer including a p-type semiconductor.

Materials similar to those of the electrodes of the light-emitting device described in Embodiment 1 can be used for the first electrode 101 and the second electrode 102.

The hole-transport layer 116 preferably has a stacked-layer structure of the first hole-transport layer 112a, the buffer layer 119, and the second hole-transport layer 112b described in Embodiment 1. Alternatively, one or more of the materials that can be used for the hole-injection layer 111, the first hole-transport layer 112a, the buffer layer 119, and the second hole-transport layer 112b of the light-emitting device described in Embodiment 1, and the like can be used for the hole-transport layer 116. The hole-transport layer 116 may have a single-layer structure or a stacked-layer structure. In other words, the hole-transport layer 116 can have a structure similar to that of one or more of the hole-injection layer 111, the first hole-transport layer 112a, the buffer layer 119, and the second hole-transport layer 112b of the light-emitting device described in Embodiment 1.

One or more of the materials that can be used for the electron-transport layer 114 and the electron-injection layer 115 of the light-emitting device described in Embodiment 1, and the like can be used for the electron-transport layer 118. In other words, the electron-transport layer 118 can have a structure similar to that of one or both of the electron-transport layer 114 and the electron-injection layer 115 of the light-emitting device described in Embodiment 1.

### Structure Example of Light-Emitting and Light-Receiving Device

When the light-emitting layer 113 is provided in the layer 105 including an organic compound of the stacked-layer structure in FIG. 6A or FIG. 6B in addition to the hole-transport layer 116, the active layer 117, and the electron-transport layer 118, a function of a light-emitting and light-receiving device can be obtained.

The light-emitting layer 113 is preferably provided between the hole-transport layer 116 and the active layer 117 or between the active layer 117 and the electron-transport layer 118. Furthermore, a buffer layer is preferably provided between the light-emitting layer 113 and the active layer 117.

The light-emitting and light-receiving device can serve as both a light-emitting device and a light-receiving device, and therefore, the number of devices placed in one pixel can be reduced. Thus, higher resolution, a higher aperture ratio, higher definition, and the like can be easily achieved in a display apparatus.

### Structure Example of Light-Emitting and Light-Receiving Apparatus

A light-emitting and light-receiving apparatus has a light-receiving function and a light-emitting function. A display apparatus having a light-receiving function is described below as an example of a light-emitting and light-receiving apparatus.

The display apparatus of this embodiment includes a light-receiving device or a light-emitting and light-receiving device in addition to a light-emitting device.

The display apparatus of this embodiment has a function of displaying an image using the light-emitting device (and the light-emitting and light-receiving device). That is, the light-emitting device (and the light-emitting and light-receiving device) functions as a display device.

The light-emitting device functions as a display device (also referred to as a display element). As the light-emitting device, an EL device such as an OLED (Organic Light Emitting Diode) and a QLED (Quantum-dot Light Emitting Diode) is preferably used. Alternatively, an LED (Light Emitting Diode) such as a micro-LED can be used as the light-emitting device. The light-emitting device of one embodiment of the present invention described in Embodiment 1 has high light extraction efficiency and a low driving voltage, and thus can be favorably used in the display apparatus of one embodiment of the present invention.

The display apparatus of this embodiment has a function of detecting light using the light-receiving device or the light-emitting and light-receiving device.

When the light-receiving device or the light-emitting and light-receiving device is used as an image sensor, the display apparatus of this embodiment can capture an image. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared to the case where a biometric authentication sensor is provided separately from the display apparatus; thus, the size and weight of the electronic device can be reduced.

When the light-receiving device or the light-emitting and light-receiving device is used as a touch sensor, the display apparatus of this embodiment can detect the proximity or touch of an object.

For example, a pn or pin photodiode can be used as the light-receiving device. It is particularly preferable to use an organic photodiode including a layer containing an organic compound, as the light-receiving device. An organic photodiode, which is easily made thin, lightweight, and large in area and has a high degree of freedom for shape and design, can be used in a variety of display apparatuses. The light-receiving device of one embodiment of the present invention described in this embodiment can be favorably used for the display apparatus of one embodiment of the present invention.

The display apparatus of one embodiment of the present invention includes an organic EL device as the light-emitting device and an organic photodiode as the light-receiving device. The organic EL device and the organic photodiode can be formed over the same substrate. Thus, the organic photodiode can be incorporated in the display apparatus including the organic EL device.

The light-emitting and light-receiving device can be manufactured by adding an active layer of a light-receiving device to the above-described structure of the light-emitting device. For the light-emitting and light-receiving device, an active layer of a pn photodiode or a pin photodiode can be used, for example. It is particularly preferable to use, for the light-emitting and light-receiving device, an active layer of an organic photodiode including a layer containing an organic compound. The light-emitting and light-receiving device of one embodiment of the present invention described in this embodiment can be favorably used for the display apparatus of one embodiment of the present invention.

Specifically, the light-emitting and light-receiving device can be fabricated by combining an organic EL device and an organic photodiode. For example, by adding an active layer of an organic photodiode to a stacked-layer structure of an organic EL device, the light-emitting and light-receiving device can be fabricated. Furthermore, in the light-emitting and light-receiving device fabricated by combining an organic EL device and an organic photodiode, concurrently forming layers that can be shared with the organic EL device can inhibit an increase in the number of deposition steps.

In the display apparatus of one embodiment of the present invention, the light-emitting device can be used as a light source of the sensor. Accordingly, a light-receiving portion and a light source do not need to be provided separately from the display apparatus; hence, the number of components of an electronic device can be reduced.

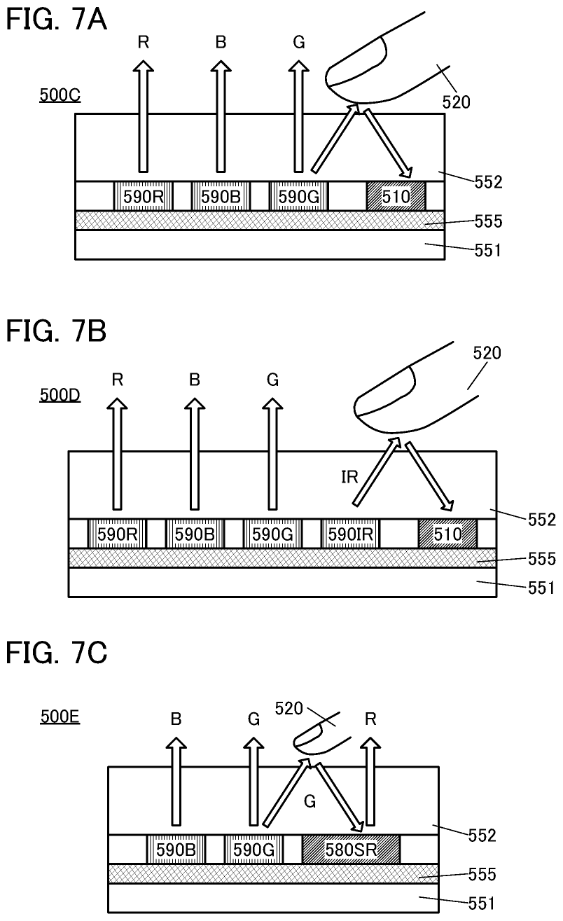

Next, a detailed structure of the display apparatus will be described. A specific structure of the display apparatus is described mainly using FIG. 6C and FIG. 6D, and a specific function of the display apparatus is described mainly using FIG. 7A to FIG. 7C.

### [Display Apparatus 500A]

FIG. 6C is a cross-sectional view of a display apparatus 500A.

The display apparatus 500A includes a light-receiving device 510, a light-emitting device 590, a transistor 531, a transistor 532, and the like between a pair of substrates (a substrate 551 and a substrate 552).

The light-emitting device 590 includes a pixel electrode 591, a buffer layer 512, a light-emitting layer 593, a buffer layer 514, and a common electrode 515 which are stacked in this order. The buffer layer 512 can include one or both of a hole-injection layer and a hole-transport layer. The light-emitting layer 593 includes an organic compound. The buffer layer 514 can include one or both of an electron-injection layer and an electron-transport layer. The light-emitting device 590 has a function of emitting visible light. Note that the display apparatus 500A may also include the light-emitting device 590 having a function of emitting infrared light.

The light-receiving device 510 includes a pixel electrode 511, the buffer layer 512, an active layer 513, the buffer layer 514, and the common electrode 515 which are stacked in this order. The buffer layer 512 in the light-receiving device 510 functions as a hole-transport layer. The active layer 513 includes an organic compound. The light-receiving device 510 has a function of detecting visible light. The buffer layer 514 in the light-receiving device 510 functions as an electron-transport layer. Note that the light-receiving device 510 may also have a function of detecting infrared light.

The buffer layer 512, the buffer layer 514, and the common electrode 515 are common layers shared by the light-emitting device 590 and the light-receiving device 510 and provided across them.

This embodiment is described assuming that the pixel electrode 511 functions as an anode and the common electrode 515 functions as a cathode in both the light-emitting device 590 and the light-receiving device 510. In other words, the light-receiving device 510 is driven by application of reverse bias between the pixel electrode 511 and the common electrode 515, so that the display apparatus 500A can detect light entering the light-receiving device 510, generate charge, and extract it as current.

The pixel electrode 511, the buffer layer 512, the active layer 513, the light-emitting layer 593, the buffer layer 514, and the common electrode 515 may each have a single-layer structure or a stacked-layer structure.

The pixel electrode 511 and the pixel electrode 591 are positioned over an insulating layer 533. An end portion of the pixel electrode 511 and an end portion of the pixel electrode 591 are each covered with an insulating layer 534. The pixel electrode 511 and the pixel electrode 591 that are adjacent to each other are electrically insulated (electrically isolated) from each other by the insulating layer 534.

An organic insulating film is suitable as the insulating layer 534. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 534 may have a function of transmitting visible light or a function of blocking visible light.

The material, thickness, and the like of the pair of electrodes can be the same between the light-receiving device 510 and the light-emitting device 590. Accordingly, the fabrication cost of the display apparatus can be reduced, and the fabrication process of the display apparatus can be simplified.

In the light-receiving device 510, the buffer layer 512, the active layer 513, and the buffer layer 514, which are positioned between the pixel electrode 511 and the common electrode 515, can each be referred to as an organic layer (a layer containing an organic compound). The pixel electrode 511 preferably has a function of reflecting visible light. The common electrode 515 has a function of transmitting visible light. Note that in the case where the light-receiving device 510 is configured to detect infrared light, the common electrode 515 has a function of transmitting infrared light. Furthermore, the pixel electrode 511 preferably has a function of reflecting infrared light.

The light-receiving device 510 has a function of detecting light. Specifically, the light-receiving device 510 is a photoelectric conversion device (also referred to as a photoelectric conversion element) that receives light 522 entering from the outside of the display apparatus 500A and converts the light into an electric signal. The light 522 can also be expressed as light that is emitted by the light-emitting device 590 and then reflected by an object. The light 522 may enter the light-receiving device 510 through a lens or the like provided in the display apparatus 500A.

In the light-emitting device 590, the buffer layer 512, the light-emitting layer 593, and the buffer layer 514, which are positioned between the pixel electrode 591 and the common electrode 515, can be collectively referred to as an EL layer. The EL layer includes at least the light-emitting layer 593. The pixel electrode 591 preferably has a function of reflecting visible light. The common electrode 515 has a function of transmitting visible light. Note that in the case where the display apparatus 500A includes a light-emitting device that emits infrared light, the common electrode 515 has a function of transmitting infrared light. Furthermore, the pixel electrode 591 preferably has a function of reflecting infrared light.

The light-emitting device 590 has a function of emitting visible light. Specifically, the light-emitting device 590 is an electroluminescent device that emits light to the substrate 552 side when voltage is applied between the pixel electrode 591 and the common electrode 515 (see light 521).

The pixel electrode 511 included in the light-receiving device 510 is electrically connected to a source or a drain of the transistor 531 through an opening provided in the insulating layer 533.

The pixel electrode 591 included in the light-emitting device 590 is electrically connected to a source or a drain of the transistor 532 through an opening provided in the insulating layer 533.

The transistor 531 and the transistor 532 are on and in contact with the same layer (the substrate 551 in FIG. 6C).

At least part of a circuit electrically connected to the light-receiving device 510 and a circuit electrically connected to the light-emitting device 590 are preferably formed using the same material in the same step. In this case, the thickness of the display apparatus can be smaller and the fabrication process can be simpler than in the case where the two circuits are separately formed.

The light-receiving device 510 and the light-emitting device 590 are preferably covered with a protective layer 595. In FIG. 6C, the protective layer 595 is provided over and in contact with the common electrode 515. Providing the protective layer 595 can inhibit entry of impurities such as water into the light-receiving device 510 and the light-emitting device 590, so that the reliability of the light-receiving device 510 and the light-emitting device 590 can be increased. The protective layer 595 and the substrate 552 are bonded to each other with an adhesive layer 553.

A light-blocking layer 554 is provided on a surface of the substrate 552 on the substrate 551 side. The light-blocking layer 554 has openings in a position overlapping with the light-emitting device 590 and in a position overlapping with the light-receiving device 510.

Here, the light-receiving device 510 detects light that is emitted from the light-emitting device 590 and then reflected by an object. However, in some cases, light emitted from the light-emitting device 590 is reflected inside the display apparatus 500A and enters the light-receiving device 510 without through an object. The light-blocking layer 554 can reduce the influence of such stray light. Consequently, noise can be reduced, and the sensitivity of a sensor using the light-receiving device 510 can be increased.

For the light-blocking layer 554, a material that blocks light emitted from the light-emitting device can be used. The light-blocking layer 554 preferably absorbs visible light. As the light-blocking layer 554, a black matrix can be formed using a metal material or a resin material containing pigment (e.g., carbon black) or dye, for example. The light-blocking layer 554 may have a stacked-layer structure of at least two layers of a red color filter, a green color filter, and a blue color filter.

### [Display Apparatus 500B]

FIG. 6D is a cross-sectional view of a display apparatus 500B. Note that in the description of the display apparatus 500B, components similar to those of the above-mentioned display apparatus 500A are not described in some cases.

The display apparatus 500B includes a light-emitting device 590B, a light-emitting device 590G, and a light-emitting and light-receiving device 580SR.

The light-emitting device 590B includes a pixel electrode 591B, the buffer layer 512, a light-emitting layer 593B, the buffer layer 514, and the common electrode 515 which are stacked in this order. The light-emitting device 590B has a function of emitting blue light 521B. The light-emitting device 590B is electrically connected to a transistor 532B.

The light-emitting device 590G includes a pixel electrode 591G, the buffer layer 512, a light-emitting layer 593G, the buffer layer 514, and the common electrode 515 which are stacked in this order. The light-emitting device 590G has a function of emitting green light 521G. The light-emitting device 590G is electrically connected to a transistor 532G.

The light-emitting and light-receiving device 580SR includes the pixel electrode 511, the buffer layer 512, the active layer 513, a light-emitting layer 593R, the buffer layer 514, and the common electrode 515 which are stacked in this order. The light-emitting and light-receiving device 580SR has a function of emitting red light 521R and a function of detecting the light 522. The light-emitting and light-receiving device 580SR is electrically connected to the transistor 531.

### [Display Apparatus 500C]

A display apparatus 500C illustrated in FIG. 7A includes the substrate 551, the substrate 552, the light-receiving device 510, a light-emitting device 590R, the light-emitting device 590G, the light-emitting device 590B, a functional layer 555, and the like.

The light-emitting device 590R, the light-emitting device 590G, the light-emitting device 590B, and the light-receiving device 510 are provided between the substrate 551 and the substrate 552. The light-emitting device 590R, the light-emitting device 590G, and the light-emitting device 590B emit red (R) light, green (G) light, and blue (B) light, respectively.

The display apparatus 500C includes a plurality of pixels arranged in a matrix. One pixel includes one or more subpixels. One subpixel includes one light-emitting device. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel also includes the light-receiving device 510. The light-receiving device 510 may be provided in all the pixels or in some of the pixels. In addition, one pixel may include a plurality of light-receiving devices 510.

FIG. 7A illustrates a finger 520 approaching a surface of the substrate 552. Part of light emitted by the light-emitting device 590G is reflected by the finger 520. Then, when part of the reflected light enters the light-receiving device 510, the proximity of the finger 520 to the substrate 552 can be detected. That is, the display apparatus 500C can function as a contactless touch panel. Since a contact to the finger 520 with the substrate 552 can also be detected, the display apparatus 500C also functions as a contact-type touch panel (also simply referred to as a touch panel).

The functional layer 555 includes a circuit that drives the light-emitting device 590R, the light-emitting device 590G, and the light-emitting device 590B, and a circuit that drives the light-receiving device 510. The functional layer 555 is provided with a switch, a transistor, a capacitor, a wiring, and the like. Note that in the case where the light-emitting device 590R, the light-emitting device 590G, the light-emitting device 590B, and the light-receiving device 510 are driven by a passive matrix method, the switch and the transistor are not necessarily provided.

### [Display Apparatus 500D]

A display apparatus 500D illustrated in FIG. 7B includes a light-emitting device 590IR in addition to the components illustrated in the example in FIG. 7A. The light-emitting device 590IR is a light-emitting device emitting infrared light IR. That is, the display apparatus 500D includes light-emitting devices that emit visible light, a light-emitting device that emits infrared light, and a light-receiving device. In this case, the light-receiving device 510 is preferably capable of receiving at least the infrared light IR emitted by the light-emitting device 590IR. The light-receiving device 510 is further preferably capable of receiving both visible light and infrared light.

As illustrated in FIG. 7B, when the finger 520 touches the substrate 552, the infrared light IR emitted from the light-emitting device 590IR is reflected by the finger 520 and part of the reflected light enters the light-receiving device 510, so that the positional information of the finger 520 can be obtained.

### [Display Apparatus 500E]

A display apparatus 500E illustrated in FIG. 7C includes the light-emitting device 590B, the light-emitting device 590G, and the light-emitting and light-receiving device 580SR. The light-emitting and light-receiving device 580SR has a function of a light-emitting device that emits red (R) light, and a function of a photoelectric conversion device that receives visible light. That is, the display apparatus 500E includes light-emitting devices that emit visible light and a light-emitting and light-receiving device that emits and receives visible light. FIG. 7C illustrates an example where the light-emitting and light-receiving device 580SR receives green (G) light emitted by the light-emitting device 590G. Note that the light-emitting and light-receiving device 580SR may receive blue (B) light emitted by the light-emitting device 590B. Alternatively, the light-emitting and light-receiving device 580SR may receive both green light and blue light.

For example, the light-emitting and light-receiving device 580SR preferably receives light having a shorter wavelength than light emitted from itself. The light-emitting and light-receiving device 580SR may receive light (e.g., infrared light) having a longer wavelength than light emitted from itself. The light-emitting and light-receiving device 580SR may receive light having approximately the same wavelength as light emitted from itself, however, in that case, the light-emitting and light-receiving device 580SR also receives light emitted from itself, whereby its emission efficiency might be decreased. Therefore, it is preferable that the peak of the emission spectrum and the peak of the absorption spectrum of the light-emitting and light-receiving device 580SR overlap as little as possible.

The light emitted by the light-emitting and light-receiving device is not limited to red light. Furthermore, the light emitted by the light-emitting devices is not limited to the combination of green light and blue light. For example, the light-emitting and light-receiving device may emit green or blue light and receive light having a wavelength different from that of light emitted from itself.

The light-emitting and light-receiving device 580SR serves as both a light-emitting device and a light-receiving device as described above, whereby the number of devices provided in one pixel can be reduced. Thus, higher resolution, a higher aperture ratio, higher definition, and the like can be easily achieved in the display apparatus.

This embodiment can be combined with the other embodiments as appropriate.

### Embodiment 4

In this embodiment, electronic devices of one embodiment of the present invention will be described with reference to drawings.

Examples of electronic devices include a television set, a monitor of a computer or the like, a digital camera, a digital video camera, a digital photo frame, a mobile phone (also referred to as a cellular phone or a mobile phone device), a portable game machine, a portable information terminal, an audio reproducing device, a large game machine such as a pinball machine, a biometric authentication device, and a testing device.

The electronic devices of one embodiment of the present invention include the light-emitting apparatus of one embodiment of the present invention in its display portion and thus has high emission efficiency and a low driving voltage. Note that the electronic device of one embodiment of the present invention is not limited to including the light-emitting apparatus of one embodiment of the present invention, and may include the light-receiving apparatus of one embodiment of the present invention or a light-emitting and light-receiving apparatus of one embodiment of the present invention.

The display portion of the electronic device in this embodiment can display a video with a resolution of, for example, full high definition, 4K2K, 8K4K, 16K8K, or higher. As a screen size of the display portion, the diagonal size can be greater than or equal to 20 inches, greater than or equal to 30 inches, greater than or equal to 50 inches, greater than or equal to 60 inches, or greater than or equal to 70 inches.

The electronic device of one embodiment of the present invention has flexibility and therefore can be incorporated along a curved surface of an inside or outside wall of a house or a building or a curved surface of an interior or an exterior of an automobile.

The electronic device of one embodiment of the present invention may include a secondary battery. It is preferable that the secondary battery be capable of being charged by contactless power transmission.

Examples of the secondary battery include a lithium ion secondary battery such as a lithium polymer battery using a gel electrolyte (a lithium ion polymer battery), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display a video, information, or the like on a display portion. When the electronic device includes the antenna and a secondary battery, the antenna may be used for contactless power transmission.

The electronic device of this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of kinds of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

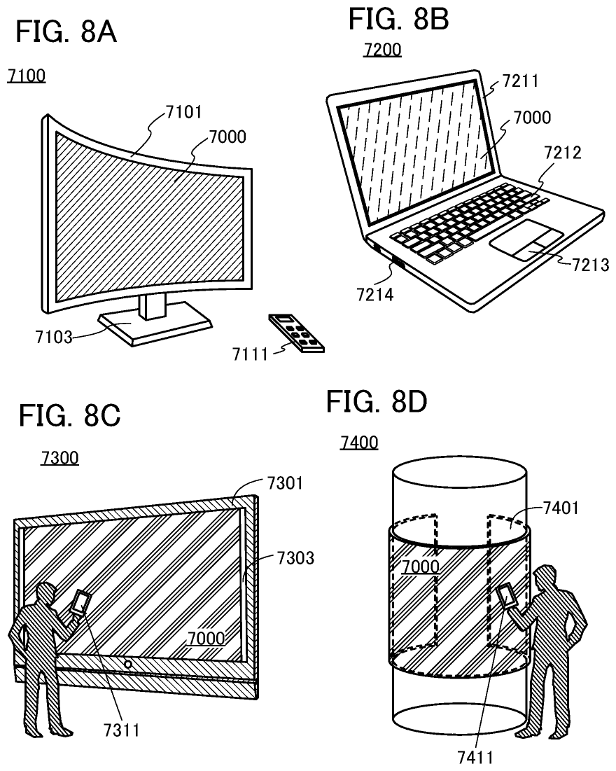

FIG. 8A illustrates an example of a television device. In a television device 7100, a display portion 7000 is incorporated in a housing 7101. Here, a structure in which the housing 7101 is supported by a stand 7103 is illustrated.

The light-emitting apparatus of one embodiment of the present invention can be used for the display portion 7000.

The television device 7100 illustrated in FIG. 8A can be operated with an operation switch provided in the housing 7101 and a separate remote controller 7111; or the display portion 7000 may include a touch sensor, and the television device 7100 can be operated by touching the display portion 7000 with a finger or the like. The remote controller 7111 may include a display portion for displaying information output from the remote controller 7111. With a touch panel or operation keys provided in the remote controller 7111, channels and volume can be controlled, and videos displayed on the display portion 7000 can be controlled.

Note that the television device 7100 is provided with a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 8B illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used for the display portion 7000.

FIG. 8C and FIG. 8D illustrate examples of digital signage.

Digital signage 7300 illustrated in FIG. 8C includes a housing 7301, the display portion 7000, a speaker 7303, and the like. Furthermore, an LED lamp, operation keys (including a power switch or an operation switch), a connection terminal, a variety of sensors, a microphone, and the like can be included.

FIG. 8D illustrates digital signage 7400 mounted on a cylindrical pillar 7401. The digital signage 7400 includes the display portion 7000 provided along a curved surface of the pillar 7401.

The light-emitting apparatus of one embodiment of the present invention can be used for the display portion 7000 in FIG. 8C and FIG. 8D.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. For an application for providing information such as route information or traffic information, usability can be enhanced by intuitive operation.

As illustrated in FIG. 8C and FIG. 8D, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

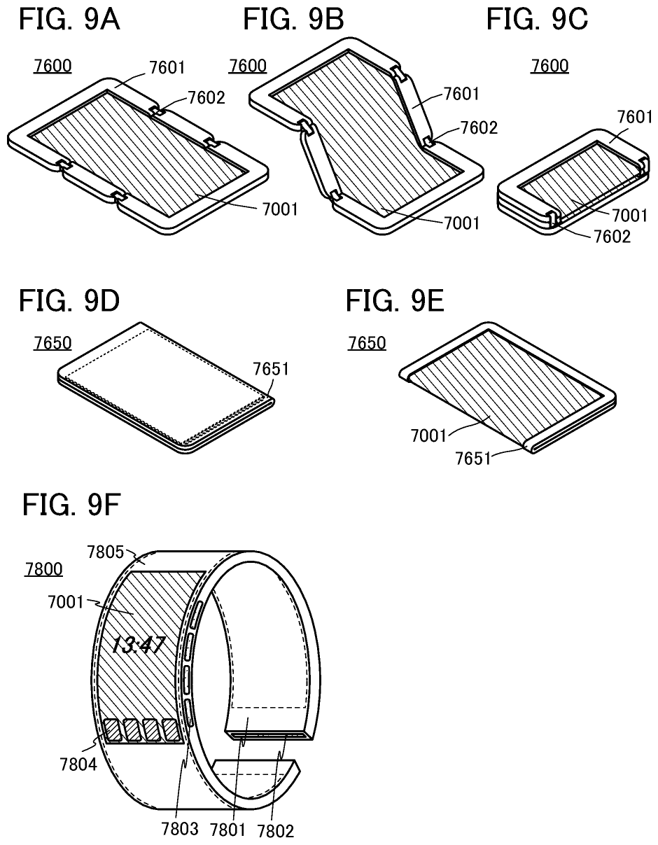

FIG. 9A to FIG. 9F illustrate examples of a portable information terminal including a flexible display portion 7001.

The display portion 7001 is fabricated using the light-emitting apparatus of one embodiment of the present invention. For example, a light-emitting apparatus that can be bent with a radius of curvature greater than or equal to 0.01 mm and less than or equal to 150 mm can be used. The display portion 7001 may include a touch sensor so that the portable information terminal can be operated by touching the display portion 7001 with a finger or the like.

FIG. 9A to FIG. 9C illustrate an example of a foldable portable information terminal. FIG. 9A illustrates an opened state, FIG. 9B illustrates a state in the middle of change from one of an opened state and a folded state to the other, and FIG. 9C illustrates a folded state of a portable information terminal 7600. The portable information terminal 7600 has excellent portability when in a folded state, and has excellent browsability when in an opened state because of its seamless large display region.

The display portion 7001 is supported by three housings 7601 joined together by hinges 7602. By folding a space between two housings 7601 with the hinges 7602, the portable information terminal 7600 can be reversibly changed in shape from an opened state to a folded state.

FIG. 9D and FIG. 9E illustrate an example of a foldable portable information terminal. FIG. 9D illustrates a portable information terminal 7650 that is folded so that the display portion 7001 is on the inside; FIG. 9E illustrates the portable information terminal 7650 that is folded so that the display portion 7001 is on the outside. The portable information terminal 7650 includes the display portion 7001 and a non-display portion 7651. When the portable information terminal 7650 is not used, the portable information terminal 7650 is folded so that the display portion 7001 is on the inside, whereby contamination of or damage to the display portion 7001 can be suppressed.

FIG. 9F illustrated an example of a wrist-watch-type portable information terminal. A portable information terminal 7800 includes a band 7801, the display portion 7001, an input-output terminal 7802, operation buttons 7803, and the like. The band 7801 has a function of a housing. A flexible battery 7805 can be mounted on the portable information terminal 7800. The battery 7805 may be placed to overlap with the display portion 7001 or the band 7801, for example.

The band 7801, the display portion 7001, and the battery 7805 have flexibility. Thus, the portable information terminal 7800 can be easily curved to have a desired shape.

The operation button 7803 can give a variety of functions such as time setting, on/off of the power, on/off of wireless communication, setting and cancellation of silent mode, and setting and cancellation of power saving mode. For example, the functions of the operation button 7803 can be set freely by the operating system incorporated in the portable information terminal 7800.

By touching an icon 7804 displayed on the display portion 7001 with a finger or the like, application can be started.

The portable information terminal 7800 can execute near field communication conformable to a communication standard. For example, mutual communication between the portable information terminal and a headset capable of wireless communication can be performed, and thus hands-free calling is possible.

The portable information terminal 7800 may include the input-output terminal 7802. In the case where the input-output terminal 7802 is included, data can be directly transmitted to and received from another information terminal via a connector. Charging through the input-output terminal 7802 is also possible. Note that charging of the portable information terminal described as an example in this embodiment can be performed by non-contact power transmission without using the input-output terminal.

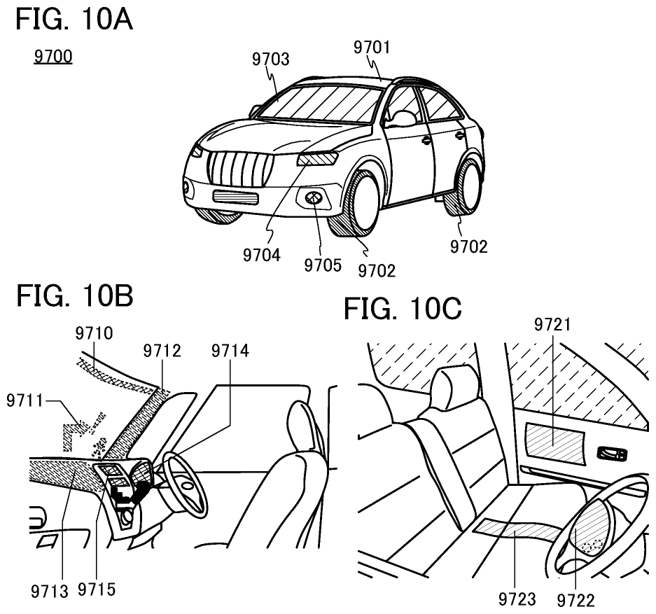

FIG. 10A is an external view of an automobile 9700. FIG. 10B illustrates a driver's seat of the automobile 9700. The automobile 9700 includes a car body 9701, wheels 9702, a windshield 9703, lights 9704, fog lamps 9705, and the like. The light-emitting apparatus of one embodiment of the present invention can be used in, for example, a display portion of the automobile 9700. For example, the light-emitting apparatus of one embodiment of the present invention can be provided for a display portion 9710 to a display portion 9715 illustrated in FIG. 10B; or the light-emitting apparatus of one embodiment of the present invention may be used in the lights 9704 or the fog lamps 9705.

The display portion 9710 and the display portion 9711 are display devices provided in an automobile windshield. The light-emitting apparatus of one embodiment of the present invention can be a see-through apparatus, through which the opposite side can be seen, by using a light-transmitting conductive material for forming its electrodes and wirings. Such a display portion 9710 or 9711 in a see-through state does not hinder driver's vision during driving of the automobile 9700. Therefore, the light-emitting apparatus of one embodiment of the present invention can be provided in the windshield of the automobile 9700. In the case where a transistor for driving the light-emitting apparatus is provided, a transistor having a light-transmitting property, such as an organic transistor using an organic semiconductor material or a transistor using an oxide semiconductor, is preferably used.

The display portion 9712 is a display apparatus provided on a pillar portion. For example, the display portion 9712 can compensate for the view hindered by the pillar by displaying an image taken by an imaging means provided on the car body. The display portion 9713 is a display apparatus provided on a dashboard. For example, the display portion 9713 can compensate for the view hindered by the dashboard by displaying an image taken by an imaging means provided on the car body. That is, display of an image taken by an imaging means provided on the exterior of the automobile can compensate for blind areas and enhance safety. Display of an image that complements the area that cannot be seen makes it possible to confirm safety more naturally and comfortably.

FIG. 10C illustrates the inside of a car in which a bench seat is used as a driver seat and a front passenger seat. A display portion 9721 is a display apparatus provided in a door portion. For example, the display portion 9721 can compensate for the view hindered by the door by displaying an image taken by an imaging means provided on the car body. A display portion 9722 is a display apparatus provided in a steering wheel. A display portion 9723 is a display apparatus provided in the middle of a seating face of the bench seat. Provided on the seating surface, backrest, or the like, the display apparatus can be used as a seat heater with heat generation of the display apparatus as a heat source.

The display portion 9714, the display portion 9715, and the display portion 9722 can provide a variety of kinds of information by displaying navigation data, a speedometer, a tachometer, a mileage, a fuel meter, a gearshift indicator, air-condition setting, and the like. The content, layout, or the like of the display on the display portions can be changed freely by a user as appropriate. The above information can also be displayed on the display portion 9710 to the display portion 9713, the display portion 9721, and the display portion 9723. The display portion 9710 to the display portion 9715 and the display portion 9721 to the display portion 9723 can also be used as lighting devices. The display portion 9710 to the display portion 9715 and the display portion 9721 to the display portion 9723 can also be used as heating devices.

The electronic devices of one embodiment of the present invention include the light-emitting apparatus of one embodiment of the present invention in its light source and thus has high emission efficiency and a low driving voltage. For example, the light-emitting apparatus of one embodiment of the present invention can be used for a light source that emits visible light or near-infrared light. The light-emitting apparatus of one embodiment of the present invention can also be used as a light source of a lighting device.

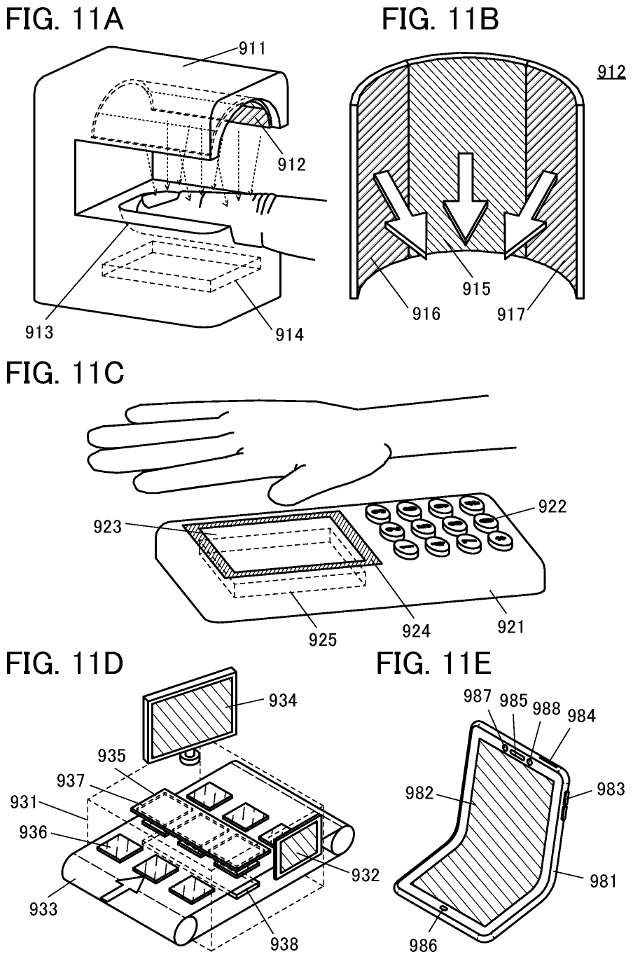

FIG. 11A illustrates a biometric authentication apparatus for sensing a finger vein which includes a housing 911, a light source 912, a sensing stage 913, and the like. By putting a finger on the sensing stage 913, an image of a vein pattern can be captured. The light source 912 that emits near-infrared light is provided above the sensing stage 913, and an imaging device 914 is provided under the sensing stage 913. The sensing stage 913 is formed of a material that transmits near-infrared light, and near-infrared light that is emitted from the light source 912 and passes through the finger can be captured by the imaging device 914. Note that an optical system may be provided between the sensing stage 913 and the imaging device 914. The structure of the apparatus described above can also be applied to a biometric authentication apparatus for sensing a palm vein.

The light-emitting apparatus of one embodiment of the present invention can be used for the light source 912. The light-emitting apparatus of one embodiment of the present invention can be provided to be curved and can emit light uniformly toward a target. In particular, the light-emitting apparatus preferably emits near-infrared light with the maximum peak intensity at a wavelength from 700 nm to 1200 nm. For example, an image is formed from received light that has passed through the finger or palm, whereby the position of the vein can be detected. This action can be utilized for biometric identification. When combined with the global shutter system, highly accurate sensing becomes possible even while an object is moving.

The light source 912 can include a plurality of light-emitting portions, such as light-emitting portions 915, 916, and 917 illustrated in FIG. 11B. The light-emitting portions 915, 916, and 917 may emit light having different wavelengths, and can emit light at different timings. Thus, by changing one or both of wavelengths and angles of light to be delivered, different images can be taken successively; hence, high level of security can be achieved using a plurality of images for the authentication.

FIG. 11C illustrates a biometric authentication apparatus for sensing a palm vein which includes a housing 921, operation buttons 922, a sensing portion 923, a light source 924 that emits near-infrared light, and the like. By holding a hand over the sensing portion 923, a palm vein pattern can be recognized. A security code or the like can be input with the operation buttons. The light source 924 is provided around the sensing portion 923 and irradiates a target (a hand) with light. Then, light reflected by the target enters the sensing portion 923. The light-emitting apparatus of one embodiment of the present invention can be used for the light source 924. An imaging device 925 is placed directly under the sensing portion 923 and can capture an image of the target (an image of the whole hand). Note that an optical system may be placed between the sensing portion 923 and the imaging device 925. The structure of the apparatus described above can also be applied to a biometric authentication apparatus for sensing a finger vein.

FIG. 11D illustrates a non-destructive testing apparatus that includes a housing 931, an operation panel 932, a transport mechanism 933, a monitor 934, a sensing unit 935, a light source 938 that emits near-infrared light, and the like. The light-emitting apparatus of one embodiment of the present invention can be used for the light source 938. Test specimens 936 are transported by the transport mechanism 933 to be located directly beneath the sensing unit 935. The test specimen 936 is irradiated with near-infrared light from the light source 938, and the light passing therethrough is captured by an imaging device 937 provided in the sensing unit 935. The captured image is displayed on the monitor 934. After that, the test specimens 936 are transported to the exit of the housing 931, and defective pieces are sorted and collected. Imaging with the use of near-infrared light enables non-destructive and high-speed sensing of defective elements inside a test specimen, such as defects and foreign substances.

FIG. 11E illustrates a mobile phone that includes a housing 981, a display portion 982, an operation button 983, an external connection port 984, a speaker 985, a microphone 986, a first camera 987, a second camera 988, and the like. The display portion 982 of the mobile phone includes a touch sensor. The housing 981 and the display portion 982 have flexibility. All operations including making a call and inputting text can be performed by touch on the display portion 982 with a finger, a stylus, or the like. The first camera 987 can take a visible light image, and the second camera 988 can take an infrared light image (a near-infrared light image). The mobile phone or the display portion 982 illustrated in FIG. 11E may include the light-emitting apparatus of one embodiment of the present invention.

This embodiment can be combined with the other embodiments as appropriate.

### Example 1

In this example, light-emitting devices of embodiments of the present invention were fabricated, and evaluation results thereof are described.

In this example, Device 1 that is a light-emitting device of one embodiment of the present invention and Comparative device 2 for comparison were fabricated, and evaluation results thereof are described.

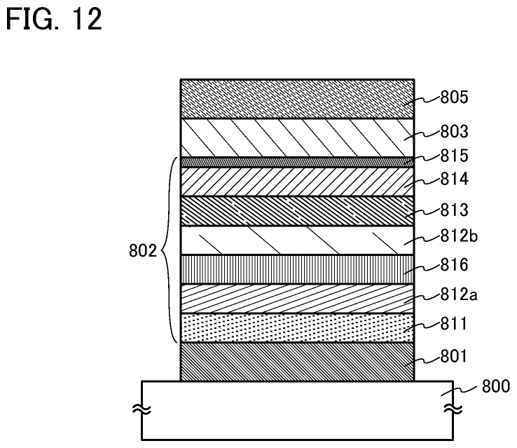

FIG. 12 illustrates the structure of the two light-emitting devices used in this example, and Table 1 shows specific components. The chemical formulae of the materials used in this example are shown below.

TABLE 1

| | | | First | First | Second | | | | | |
|---|---|---|---|---|---|---|---|---|---|---|
| | | | hole- | buffer | hole- | Light- | Electron- | Electron- | | Second |
| | First | Hole-injection | transport | layer | transport | emitting | transport | injection | Second | buffer |
| | electrode | layer | layer | | layer | layer | layer | layer | electrode | layer |
| | 801 | 811 | 812a | 816 | 812b | 813 | 814 | 815 | 803 | 805 |
| Device 1 | APC\ITSO | dchPAF: | dchPAF | OCHD- | oFBiSF | * | 4,6mCzP2Pm\ | LiF | Ag:Mg | DBT3P-II |
| | (100 nm\ | OCHD-001 | (145 nm) | 001 | (20 nm) | | NBPhen | (1 nm) | (1:0.1 | (70 nm) |
| | 10 nm) | (1:0.1 10 nm) | | (1 nm) | | | (25 nm\10 nm) | | 15 nm) | |
| Comparative | | PCBBiF: | PCBBiF | | | | | | | |
| device 2 | | OCHD-001 | (125 nm) | | | | | | | |
| | | (1:0.1 10 nm) | | | | | | | | |

*8BP-4mDBtPBfpm: βNCCP: Ir(ppy)₂(mbfpypy-d₃) (0.6:0.4:0.1 40 nm)

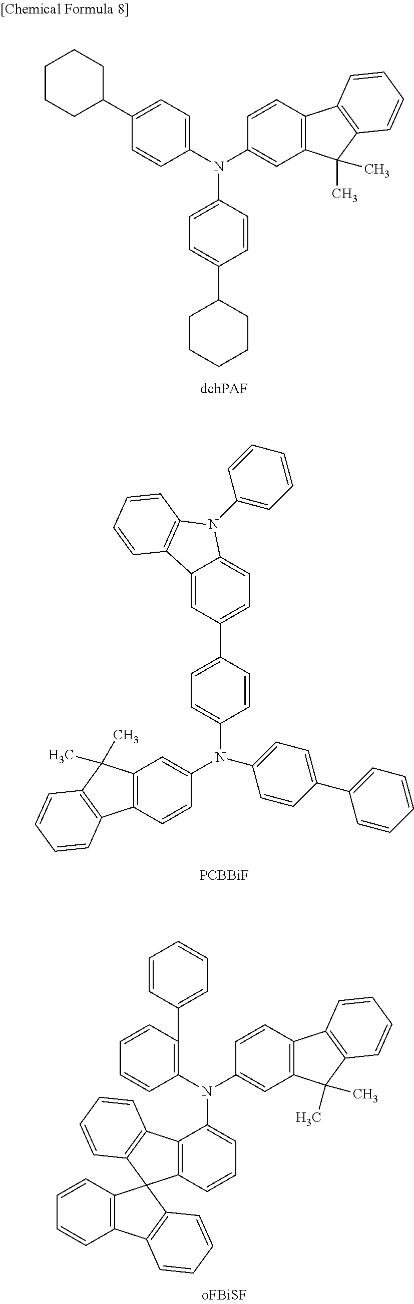

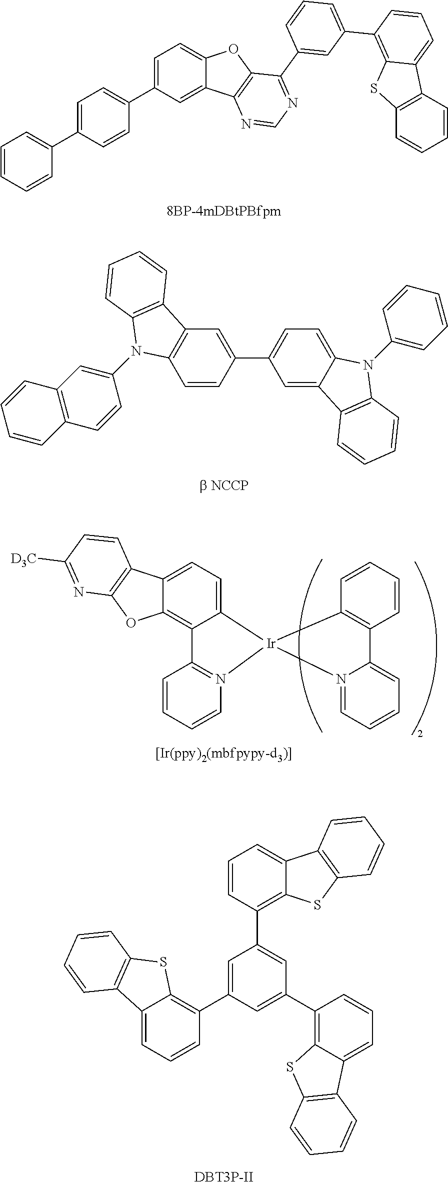

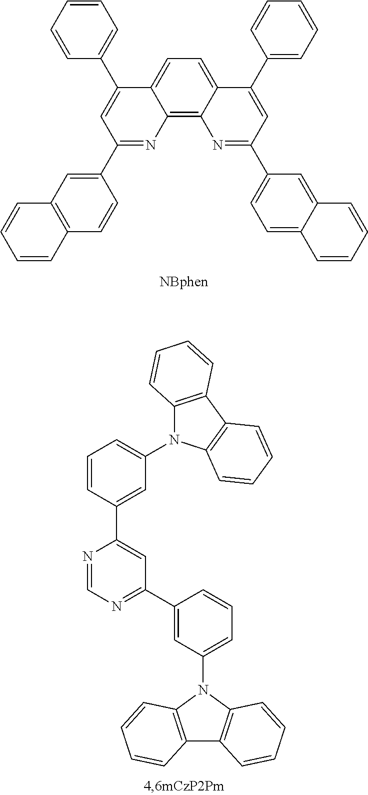 [SMILES: c1ccc(-c2cc(-c3ccc4ccccc4c3)nc3c2ccc2c(-c4ccccc4)cc(-c4ccc5ccccc5c4)nc23)cc1 ; c1cc(-c2cc(-c3cccc(-n4c5ccccc5c5ccccc54)c3)ncn2)cc(-n2c3ccccc3c3ccccc32)c1]

### <<Fabrication of Light-Emitting Devices>>

In each of the light-emitting devices described in this example, as illustrated in FIG. 12, a first electrode 801 is formed over a substrate 800; a hole-injection layer 811, a first hole-transport layer 812a, a first buffer layer 816, a second hole-transport layer 812b, a light-emitting layer 813, an electron-transport layer 814, and an electron-injection layer 815, which constitute an EL layer 802, are stacked in this order over the first electrode 801; a second electrode 803 is formed over the electron-injection layer 815; and a second buffer layer 805 is formed over the second electrode 803. The light-emitting devices described in this example are each a top-emission light-emitting device in which light is emitted toward the second electrode 803 side.

First, the first electrode 801 was formed over the substrate 800. The electrode area was set to 4 mm² (2 mm×2 mm). A glass substrate was used as the substrate 800. The first electrode 801 was formed in such a manner that an alloy film of silver, palladium, and copper (Ag—Pd—Cu, APC) was formed to a thickness of 100 nm by a sputtering method, and a film of indium tin oxide containing silicon oxide (ITSO) was formed to a thickness of 10 nm by a sputtering method. Note that in this example, the first electrode 801 functions as an anode.

As pretreatment, a surface of the substrate was washed with water, baking was performed at 200° C. for one hour, and then UV ozone treatment was performed for 370 seconds. After that, the substrate was transferred into a vacuum evaporation apparatus in which the pressure was reduced to approximately 10⁻⁴ Pa, vacuum baking at 170° C. for 30 minutes was performed in a heating chamber in the vacuum evaporation apparatus, and then the substrate was cooled down for approximately 30 minutes.

Next, the hole-injection layer 811 was formed over the first electrode 801.

The hole-injection layer 811 of Device 1 was formed in such a manner that the pressure in the vacuum evaporation apparatus was reduced to 10⁻⁴ Pa, and then N,N-bis(4-cyclohexylphenyl)-9,9-dimethyl-9H-fluoren-2-amine (abbreviation: dchPAF) and an electron acceptor material (OCHD-001) were deposited by co-evaporation in a weight ratio of dchPAF:OCHD-001=1:0.1 to a thickness of 10 nm. Note that OCHD-001 is an acceptor organic compound containing fluorine.

The hole-injection layer 811 of Comparative device 2 was formed in such a manner that the pressure in the vacuum evaporation apparatus was reduced to 10⁻⁴ Pa, and then N-(1,1′-biphenyl-4-yl)-9,9-dimethyl-N-[4-(9-phenyl-9H-carbazol-3-yl)phenyl]-9H-fluoren-2-amine (abbreviation: PCBBiF) and OCHD-001 were deposited by co-evaporation in a weight ratio of PCBBiF:OCHD-001=1:0.1 to a thickness of 10 nm.

In the hole-injection layer 811 of Device 1 and Comparative device 2, a concentration percentage by weight of OCHD-001 is 10 wt % and a concentration percentage by volume is 7.5 vol %.

Next, the first hole-transport layer 812a was formed over the hole-injection layer 811.

The first hole-transport layer 812a of Device 1 was formed by evaporation of dchPAF to a thickness of 145 nm.

The first hole-transport layer 812a of Comparative device 2 was formed by evaporation of PCBBiF to a thickness of 125 nm.

As described later, dchPAF and PCBBiF have different refractive indices. Thus, the thicknesses of the first hole-transport layers 812a were changed so that the optical path lengths (refractive index×thickness) of the first hole-transport layers 812a become the same.

Then, the first buffer layer 816 was formed over the first hole-transport layer 812a. The first buffer layer 816 was formed by evaporation of OCHD-001 to a thickness of 1 nm.

Then, the second hole-transport layer 812b was formed over the first buffer layer 816. The second hole-transport layer 812b was formed by evaporation of N-(1,1′-biphenyl-2-yl)-N-(9,9-dimethyl-9H-fluoren-2-yl)-9,9′-spirobi[9H-fluoren]-4-amine (abbreviation: oFBiSF) to a thickness of 20 nm.

Next, the light-emitting layer 813 was formed over the second hole-transport layer 812b. The light-emitting layer 813 was formed to a thickness of 40 nm by co-evaporation of 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm) used as a host material (also referred to as a first host material), 9-(2-naphthyl)-9′-phenyl-9H,9′H-3,3′-bicarbazole (abbreviation: βNCCP) used as an assist material (also referred to as a second host material), and [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]) used as a guest material (phosphorescent material) in a weight ratio of 8BP-4mDBtPBfpm:βNCCP:[Ir(ppy)₂(mbfpypy-d₃)=0.6:0.4:0.1.

Next, the electron-transport layer 814 was formed over the light-emitting layer 813. The electron-transport layer 814 was formed by evaporation of 4,6-bis[3-(9H-carbazole-9-yl)phenyl]pyrimidine (abbreviation: 4,6mCzP2Pm) to a thickness of 25 nm and evaporation of 2,9-bis(naphthalen-2-yl)-4,7-diphenyl-1,10-phenanthroline (abbreviation: NBPhen) to a thickness of 10 nm.

Then, the electron-injection layer 815 was formed over the electron-transport layer 814. The electron-injection layer 815 was formed by evaporation of lithium fluoride (LiF) to a thickness of 1 nm.

After that, the second electrode 803 was formed over the electron-injection layer 815. The second electrode 803 was formed by co-evaporation of silver (Ag) and magnesium (Mg) in a volume ratio of Ag:Mg=1:0.1 to a thickness of 15 nm. Note that in this example, the second electrode 803 functions as a cathode.

Next, the second buffer layer 805 was formed over the second electrode 803. The second buffer layer 805 was formed by evaporation of 4,4′,4″-(benzene-1,3,5-triyl)tri(dibenzothiophene) (abbreviation: DBT3P-II) to a thickness of 70 nm.

Through the above steps, the light-emitting devices were formed over the substrate 800. Note that in all the evaporation steps in the above fabrication method, an evaporation method by a resistance-heating method was used.

The fabricated light-emitting devices were each sealed using a different substrate (not illustrated). At the time of the sealing using the different substrate (not illustrated), the different substrate (not illustrated) on which an adhesive that is solidified by ultraviolet light was applied was fixed onto the substrate 800 in a glove box containing a nitrogen atmosphere, and the substrates were bonded to each other such that the adhesive was attached to the periphery of the light-emitting device formed over the substrate 800. At the time of the sealing, the adhesive was irradiated with 365-nm ultraviolet light at 6 J/cm² to be solidified, and the adhesive was subjected to heat treatment at 80° C. for one hour to be stabilized.

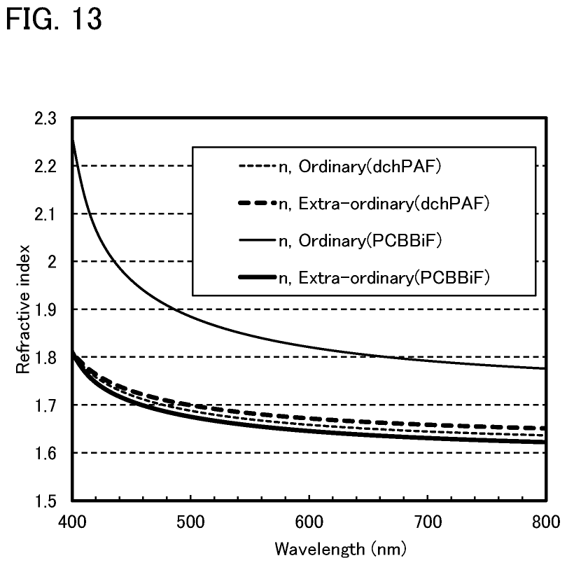

Here, FIG. 13 shows the refractive indices of the low refractive index material (dchPAF) that is used for the hole-injection layer 811 and the first hole-transport layer 812a and PCBBiF that is a comparative material. A spectroscopic ellipsometer (M-2000U, produced by J.A. Woollam Japan Corp.) was used for measurement. A film formed by depositing a material to a thickness of approximately 50 nm over a quartz substrate by a vacuum evaporation method was used as a sample. Note that a refractive index for an ordinary ray, n, Ordinary, and a refractive index for an extraordinary ray, n, Extra-ordinary, are shown in the figure. According to the measurement results, a layer containing dchPAF had an ordinary refractive index of 1.65 with respect to light with a wavelength of 633 nm, and a layer containing PCBBiF had an ordinary refractive index of 1.81 with respect to light with a wavelength of 633 nm. The layer containing dchPAF had an ordinary refractive index of 1.68 with respect to light with a wavelength of 530 nm, and the layer containing PCBBiF had an ordinary refractive index of 1.86 with respect to light with a wavelength of 530 nm. Note that a layer containing oFBiSF used as the second hole-transport layer 812b had an ordinary refractive index of 1.73 with respect to light with a wavelength of 633 nm and an ordinary refractive index of 1.76 with respect to light with a wavelength of 530 nm. That is, dchPAF used for Device 1 is an organic compound with a lower refractive index than oFBiSF.

In addition, the LUMO level of OCHD-001 calculated from the result of cyclic voltammetry (CV) measurement was −5.27 eV when N,N-dimethylformamide (DMF) was a solvent, and −5.40 eV when chloroform was a solvent. When DMF was a solvent, the HOMO level of dchPAF was −5.36 eV, the HOMO level of PCBBiF was −5.36 eV, and the HOMO level of oFBiSF was −5.50 eV. These results indicate that OCHD-001 shows an electron-accepting property with respect to dchPAF, PCBBiF, and oFBiSF. It is also indicated that oFBiSF is an organic compound having a lower HOMO level than dchPAF and PCBBiF. Note that the CV measurement was performed with an electrochemical analyzer (ALS model 600A or 600C manufactured by BAS Inc.) as a measurement apparatus, and the measurement was performed on a solution in which a material to be measured was dissolved in a solvent.

The hole mobility of dchPAF and PCBBiF was measured by impedance spectroscopy (IS method). Specifically, measurement was performed using an element in which a layer of dchPAF or PCBBiF with a thickness of 500 nm is interposed between a pair of electrodes of indium tin oxide (ITSO) and aluminum. Note that OCHD-001 was contained at a concentration of 7 vol % in a region in contact with ITSO, and molybdenum oxide (MoO₃) was contained at a concentration of 17 vol % in a region in contact with aluminum.

According to the measurement results, the hole mobility of dchPAF was 7.0×10⁻⁴ cm²/Vs and the hole-mobility of PCBBiF was 5.6×10⁻⁴ cm²/Vs when the square root of the electric field strength (V/cm) was 200 (V/cm). Thus, dchPAF is a hole-transport material that can be used for the light-emitting device of one embodiment of the present invention, and is a monoamine compound having a high hole mobility.

### <<Operation Characteristics of Light-Emitting Devices>>

Operation characteristics of the light-emitting devices fabricated in this example were measured. Note that measurement was performed with a spectroradiometer (SR-UL1R, manufactured by TOPCON TECHNOHOUSE CORPORATION) at room temperature.

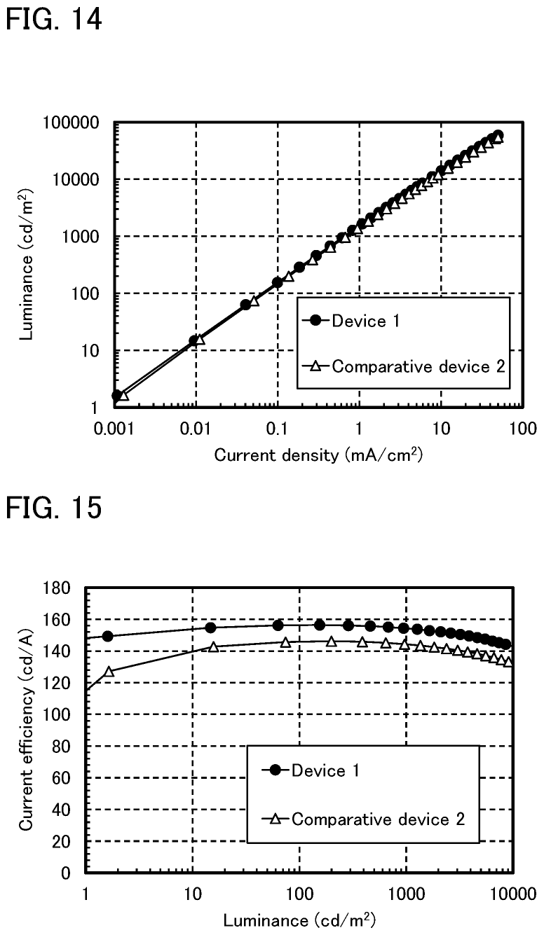

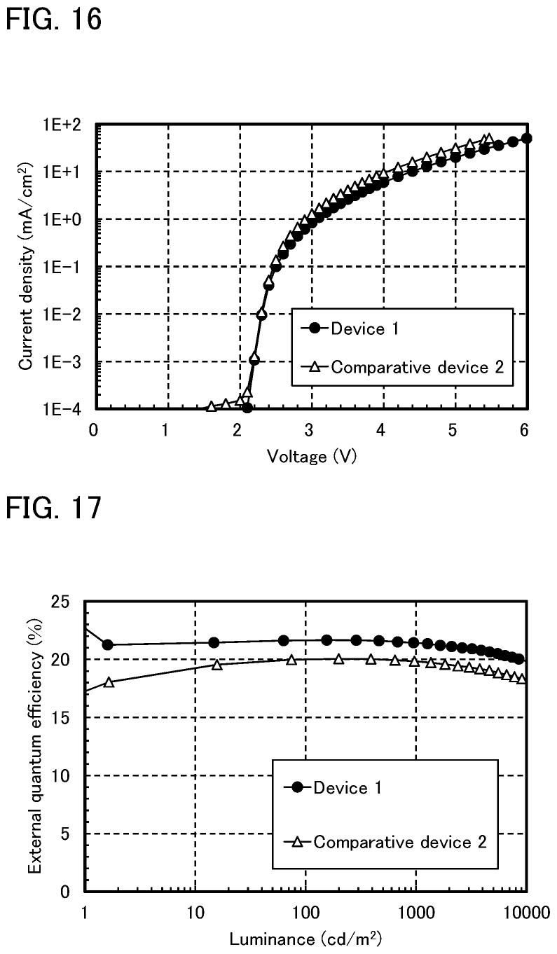

FIG. 14 shows the luminance-current density characteristics of the light-emitting devices. FIG. 15 shows the current efficiency-luminance characteristics of the light-emitting devices. FIG. 16 shows the current density-voltage characteristics of the light-emitting devices. FIG. 17 shows the external quantum efficiency-luminance characteristics of the light-emitting devices. Table 2 shows the initial values of main characteristics of the light-emitting devices at around 1000 cd/m². Note that the external quantum efficiency shown in FIG. 17 and Table 2 and the power efficiency and the energy efficiency shown in Table 2 are true values with the viewing angle characteristics taken into account to a value obtained by measuring light emission from the front direction.

TABLE 2

| | | | | | | | | External | |
|---|---|---|---|---|---|---|---|---|---|
| | | | Current | | | Current | Power | quantum | Energy |
| | Voltage | Current | density | Chromaticity | Luminance | efficiency | efficiency | efficiency | efficiency |
| | (V) | (mA) | (mA/cm²) | (x, y) | (cd/m²) | (cd/A) | (lm/W) | (%) | (%) |
| Device 1 | 2.9 | 0.025 | 0.61 | (0.26, 0.70) | 950 | 154 | 90.4 | 21.4 | 17.0 |
| Comparative | 2.8 | 0.027 | 0.67 | (0.24, 0.72) | 970 | 144 | 85.6 | 19.8 | 16.4 |
| device 2 | | | | | | | | | |

As shown in FIG. 14 to FIG. 17 and Table 2, Device 1 was found to have higher emission efficiency than Comparative device 2. Accordingly, Device 1 was found to have the first hole-transport layer 812a thicker than that of Comparative device 2 and substantially the same driving voltage as Comparative device 2. This indicates that the use of the first buffer layer 816 suppressed an increase in driving voltage.

Note that dchPAF used for Device 1 has a lower refractive index than PCBBiF used for Comparative device 2. Thus, Device 1 showed higher emission efficiency than Comparative device 2.

In the hole-injection layer 811, the concentration of OCHD-001 is low. That is, the hole-injection layer 811 and the first hole-transport layer 812a can be regarded as having substantially the same refractive index. Thus, the refractive index difference can be made small and the light extraction efficiency can be increased.

In dchPAF, the proportion of carbon atoms forming bonds by the sp³ hybrid orbitals to the total number of carbon atoms is 38.5%. Even with the use of such a material having many unsaturated bonds, almost no adverse effect on various characteristics (emission efficiency, reliability to be described later, and the like) of Device 1 was observed.

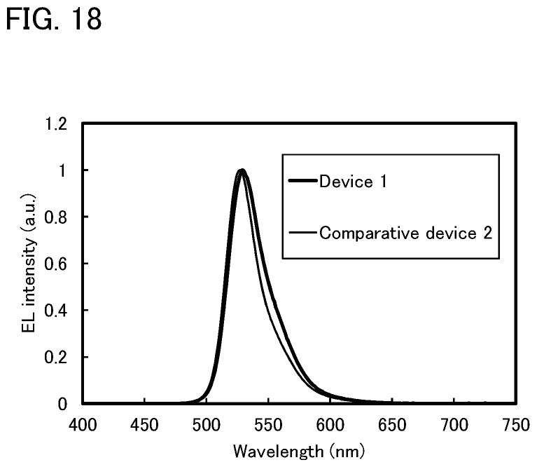

FIG. 18 shows the emission spectra of the light-emitting devices at around 1000 cd/m². As shown in FIG. 18, Device 1 exhibited an emission spectrum having a maximum peak at around 529 nm, which was derived from light emitted from [Ir(ppy)₂(mbfpypy-d₃)] contained in the light-emitting layer 813. Similarly, Comparative device 2 exhibited an emission spectrum having a maximum peak at around 528 nm.

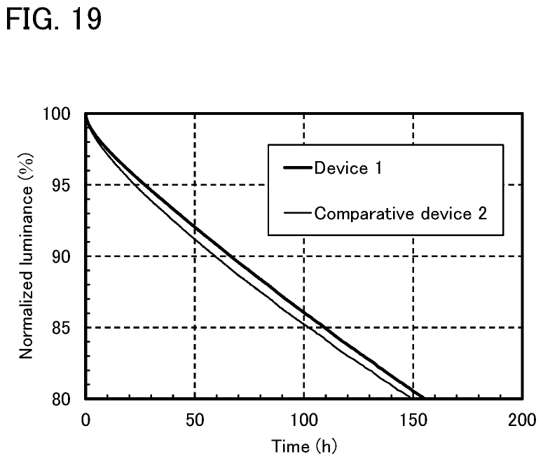

Next, a reliability test was performed on each light-emitting device. Results of the reliability test are shown in FIG. 19. In FIG. 19, the vertical axis represents normalized luminance (%) with an initial luminance of 100%, and the horizontal axis represents driving time (h). In the reliability test, each of the light-emitting devices was driven at room temperature at a current density of 50 mA/cm².

The initial luminance of Device 1 was 59100 cd/m², which is higher than the initial luminance 54600 cd/m² of Device 2. The luminance of Device 1 after 100 hours was 86% of the initial luminance, and the luminance of Comparative device 2 after 100 hours was 85% of the initial luminance. These results show that Device 1 had higher reliability than Comparative device 2.

From the above, Device 1 was found to have higher emission efficiency and higher reliability than Comparative Device 2.

### Example 2

In this example, light-emitting devices of one embodiment of the present invention were fabricated, and evaluation results thereof are described.

In this example, Device 3 that is a light-emitting device of one embodiment of the present invention and Comparative device 4 for comparison were fabricated, and evaluation results thereof are described.

FIG. 12 illustrates the structure of the two light-emitting devices used in this example, and Table 3 shows specific components. The chemical formulae of the materials used in this example are shown below. Note that the second buffer layer 805 illustrated in FIG. 12 was not provided in the light-emitting devices of this example. The light-emitting devices described in this example are each a bottom-emission light-emitting device in which light is emitted toward the first electrode 801 side.

TABLE 3

| | | | First | | Second | | | | | |
|---|---|---|---|---|---|---|---|---|---|---|
| | | | hole- | First | hole- | Light- | | | Electron- | |
| | First | Hole-injection | transport | buffer | transport | emitting | | | injection | Second |
| | electrode | layer | layer | layer | layer | layer | Electron-transport layer | | layer | electrode |
| | 801 | 811 | 812a | 816 | 812b | 813 | 814 | | 815 | 803 |
| Device 3 | ITSO | dchPAF: | dchPAF | OCHD- | * | ** | mFBPTzn | mPn- | LiF | Al |
| | (110 nm) | OCHD-001 | (100 nm) | 001 | | | (10 nm) | mDMePyPTzn:Liq | (1 nm) | (200 nm) |
| | | (1:0.1 10 nm) | | (1 nm) | | | | (1:1 25 nm) | | |
| Comparative | | | | | | | | | | |
| device 4 | | | | | | | | | | |

*mmtBumTPoFBi-04 (40 nm)
**BP-Icz(II)Tzn: PCCP: Ir(ppy)₂(mbfpypy-d₃) (0.5:0.5:0.1 40 nm)

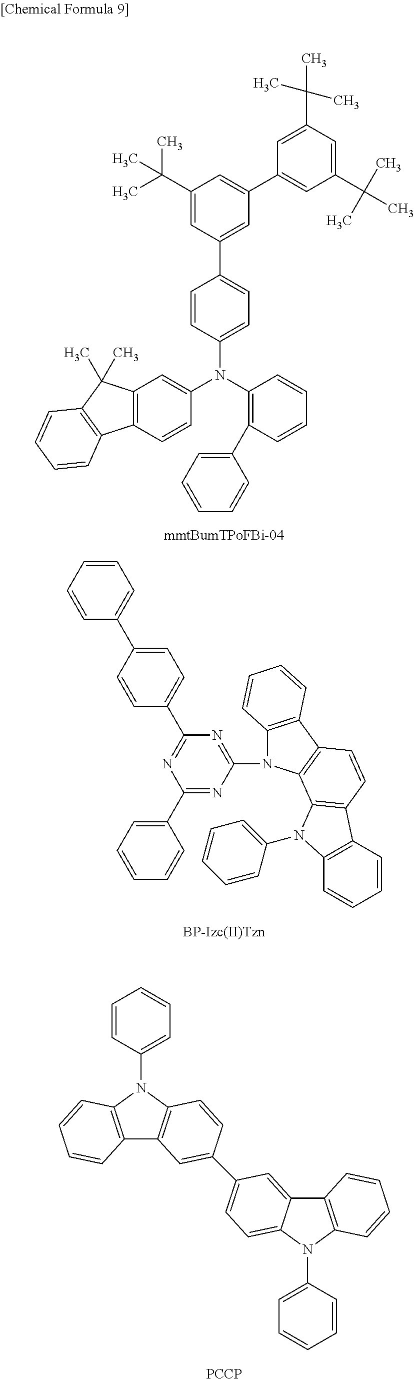 [SMILES: CC(C)(C)c1cc(-c2ccc(N(c3ccc4c(c3)C(C)(C)c3ccccc3-4)c3ccccc3-c3ccccc3)cc2)cc(-c2cc(C(C)(C)C)cc(C(C)(C)C)c2)c1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccccc4)ccc32)cc1 ; "PCCP"]

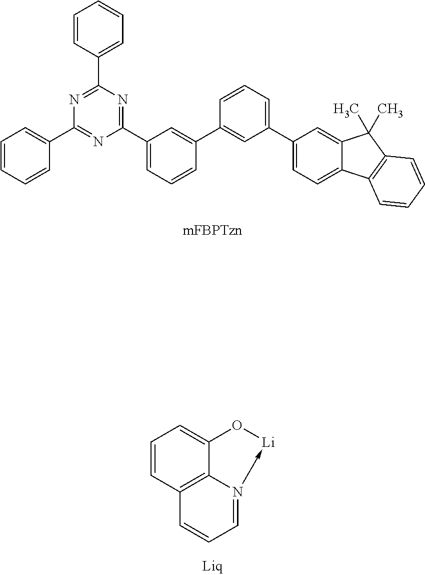

### <<Fabrication of Light-Emitting Devices>>

In the fabrication method of the light-emitting devices in this example, description of portions similar to those in the fabrication method of Device 1 fabricated in Example 1 is omitted because Example 1 can be referred to.

The first electrode 801 of each light-emitting device in this example was formed by deposition of ITSO by a sputtering method to a thickness of 110 nm.

In this example, the first buffer layer 816 was provided in Device 3, and not provided in Comparative device 4.

The second hole-transport layer 812b of each light-emitting device of this example was formed by evaporation of N-(1,1′-biphenyl-2-yl)-N-(3″,5′,5″-tri-tert-butyl-1,1′:3′,1″-terphenyl-4-yl)-9,9-dimethyl-9H-fluoren-2-amine (abbreviation: mmtBumTPoFBi-04) to a thickness of 40 nm.

The light-emitting layer 813 of each light-emitting device of this example was formed to a thickness of 40 nm by co-evaporation of 11-(4-[1,1′-diphenyl]-4-yl-6-phenyl-1,3,5-triazin-2-yl)-11,12-dihydro-12-phenyl-indolo[2,3-a]carbazole (abbreviation: BP-Icz(II)Tzn) used as a host material, 3,3′-bis(9-phenyl-9H-carbazole) (abbreviation: PCCP) used as an assist material, and [Ir(ppy)₂(mbfpypy-d₃)] used as a guest material in a weight ratio of BP-Icz(II)Tzn:PCCP:[Ir(ppy)₂(mbfpypy-d₃)]=0.5:0.5:0.1.

The electron-transport layer 814 of each light-emitting device of this example was formed by evaporation of 2-[3′-(9,9-dimethyl-9H-fluoren-2-yl)-1,1′-biphenyl-3-yl]-4,6-diphenyl-1,3,5-triazine (abbreviation: mFBPTzn) to a thickness of 10 nm, and co-evaporation of 2-[3-(2,6-dimethyl-3-pyridyl)-5-(9-phenanthryl)phenyl)-4,6-diphenyl-1,3,5-triazine (abbreviation: mPn-mDMePyPTzn) and 8-quinolinolato-lithium (abbreviation: Liq) in a weight ratio of 1:1 to a thickness of 25 nm.

The second electrode 803 of each light-emitting device of this example was formed using aluminum to a thickness of 200 nm by an evaporation method.

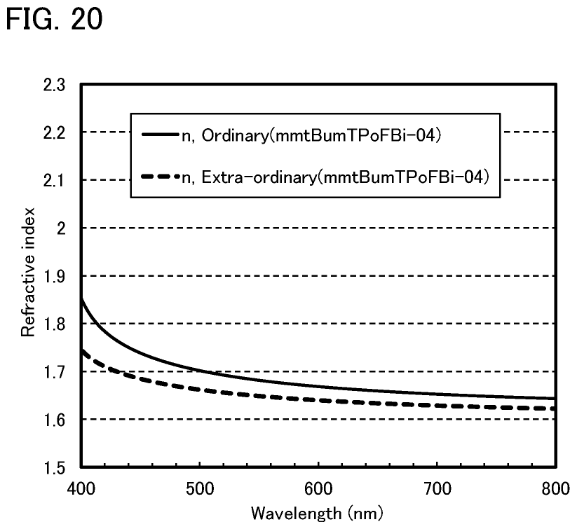

Here, FIG. 20 shows the refractive indices of the low refractive index material (mmtBumTPoFBi-04) used for the second hole-transport layer 812b. A spectroscopic ellipsometer (M-2000U, produced by J.A. Woollam Japan Corp.) was used for measurement. A film formed by depositing a material to a thickness of approximately 50 nm over a quartz substrate by a vacuum evaporation method was used as a sample. Note that a refractive index for an ordinary ray, n, Ordinary, and a refractive index for an extraordinary ray, n, Extra-ordinary, are shown in the figure. According to the measurement results, a layer containing mmtBumTPoFBi-04 had an ordinary refractive index of 1.66 with respect to light with a wavelength of 633 nm. The layer containing mmtBumTPoFBi-04 had an ordinary refractive index of 1.69 with respect to light with a wavelength of 530 nm. As described in Example 1, the layer containing dchPAF had an ordinary refractive index of 1.65 with respect to light with a wavelength of 633 nm and an ordinary refractive index of 1.68 with respect to light with a wavelength of 530 nm. That is, dchPAF used for Device 3 is an organic compound with a lower refractive index than mmtBumTPoFBi-04.

As described in Example 1, the LUMO level of OCHD-001 calculated from the result of the CV measurement was −5.27 when DMF was a solvent, and −5.40 eV when chloroform was a solvent. When DMF was a solvent, the HOMO level of dchPAF was −5.36 eV, and the HOMO level of mmtBumTPoFBi-04 was −5.42 eV. These results indicate that mmtBumTPoFBi-04 is an organic compound having a lower HOMO level than dchPAF. It is also indicated that OCHD-001 shows an electron-accepting property with respect to dchPAF and mmtBumTPoFBi-04.

### <<Operation Characteristics of Light-Emitting Devices>>

Operation characteristics of the light-emitting devices fabricated in this example were measured. Note that measurement was performed with a spectroradiometer (SR-UL1R, manufactured by TOPCON TECHNOHOUSE CORPORATION) at room temperature.

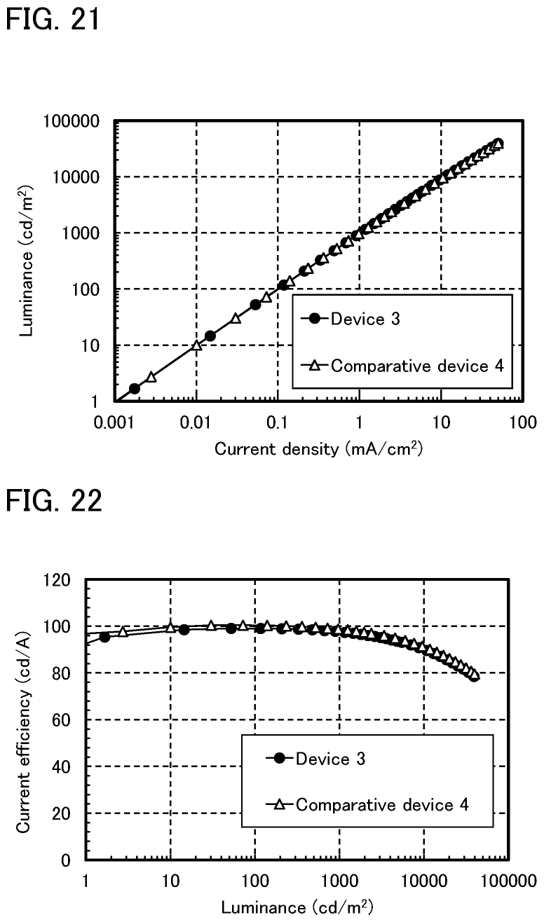

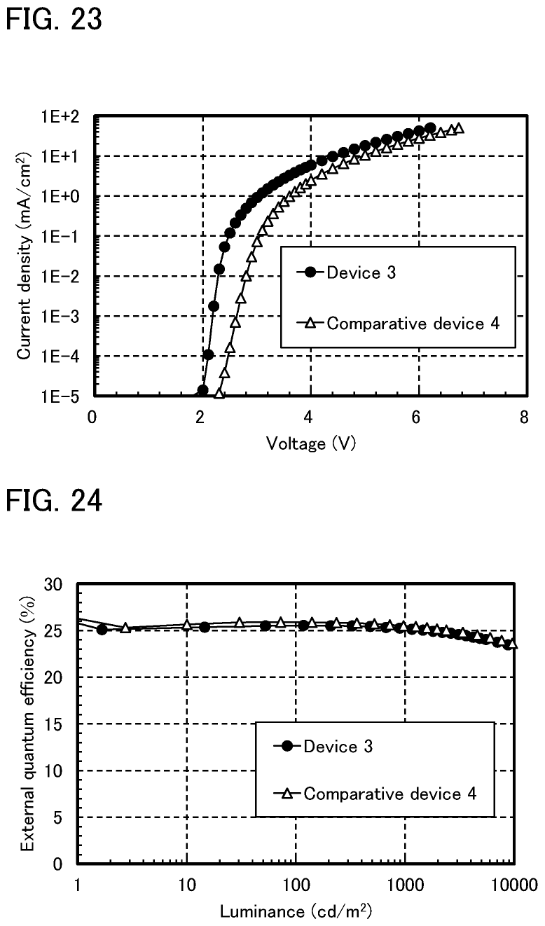

FIG. 21 shows the luminance-current density characteristics of the light-emitting devices. FIG. 22 shows the current efficiency-luminance characteristics of the light-emitting devices. FIG. 23 shows the current density-voltage characteristics of the light-emitting devices. FIG. 24 shows the external quantum efficiency-luminance characteristics of the light-emitting devices.

Table 4 shows the initial values of main characteristics of the light-emitting devices at around 1000 cd/m².

TABLE 4

| | | | | | | | | External | |
|---|---|---|---|---|---|---|---|---|---|
| | | | Current | | | Current | Power | quantum | Energy |
| | Voltage | Current | density | Chromaticity | Luminance | efficiency | efficiency | efficiency | efficiency |
| | (V) | (mA) | (mA/cm²) | (x, y) | (cd/m²) | (cd/A) | (lm/W) | (%) | (%) |
| Device 3 | 3.0 | 0.037 | 0.91 | (0.33, 0.64) | 890 | 98 | 102 | 25.3 | 18.9 |
| Comparative | 3.6 | 0.039 | 0.98 | (0.33, 0.64) | 970 | 99 | 86 | 25.5 | 15.9 |
| device 4 | | | | | | | | | |

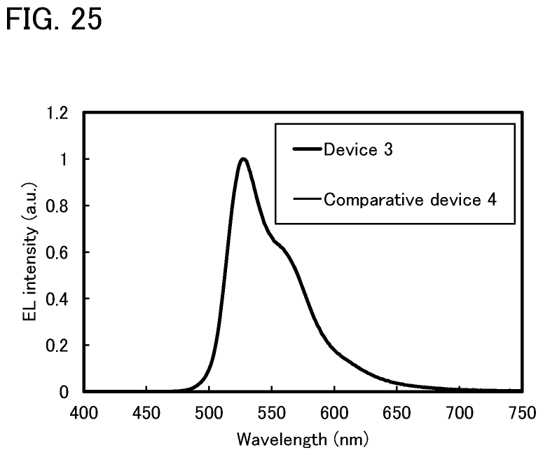

FIG. 25 shows the emission spectra of the light-emitting devices at around 1000 cd/m². As shown in FIG. 25, Device 3 and Comparative device 4 each exhibited an emission spectrum having a maximum peak at around 527 nm, which was derived from light emitted from [Ir(ppy)₂(mbfpypy-d₃)] contained in the light-emitting layer 813.

As shown in FIG. 21 to FIG. 24 and Table 4, Device 3 was found to show substantially the same emission efficiency as Comparative device 4 and have a low driving voltage. Accordingly, Device 3 was found to show high power efficiency and be driven with low power consumption as compared to Comparative device 4. Device 3 is different from Comparative device 4 in including the first buffer layer 816. This reveals that Device 3 has a lower driving voltage than Comparative device 4 owing to the first buffer layer 816.

In mmtBumTPoFBi-04, the proportion of carbon atoms forming bonds by the sp³ hybrid orbitals to the total number of carbon atoms is 26.3%. Even with the use of such a material having many unsaturated bonds, almost no adverse effect on various characteristics (e.g., emission efficiency) of Device 3 including the first buffer layer 816 was observed.

### Reference Example

This reference example describes synthesis methods of organic compounds that can be used as the first organic compound described in Embodiment 1. These organic compounds are examples of a material having a low refractive index and a high hole-transport property. Specifically, as shown in Table 5, each of these organic compounds has an ordinary refractive index higher than or equal to 1.50 and lower than or equal to 1.75 with respect to a wavelength in the blue-light-emitting region (greater than or equal to 455 nm and less than or equal to 465 nm), an ordinary refractive index higher than or equal to 1.48 and lower than or equal to 1.73 with respect to a wavelength in the green-light-emitting region (greater than or equal to 525 nm and less than or equal to 535 nm), and an ordinary refractive index higher than or equal to 1.45 and lower than or equal to 1.70 with respect to light with a wavelength of 633 nm that is usually used for refractive index measurement. As shown in Table 5, in each of these organic compounds, the proportion of carbon atoms forming bonds by the sp³ hybrid orbitals to the total number of carbon atoms is higher than or equal to 23% and lower than or equal to 55%.

TABLE 5

| | | Ordinary refractive index | | | |
|---|---|---|---|---|---|
| | | Wavelength | Wavelength | | |
| Structural | | 455 nm to | 525 nm to | Wavelength | sp³ carbon/ |
| formula | Abbreviation | 465 nm | 535 nm | 633 nm | total carbon |
| (100) | dchPAF | 1.71-1.72 | 1.67-1.68 | 1.65 | 38.5% |
| (101) | mmtBuBichPAF | 1.72-1.73 | 1.68 | 1.65 | 36.2% |
| (102) | mmtBumTPchPAF | 1.67-1.68 | 1.64 | 1.62 | 41.0% |
| (103) | mmtBumBichPAF | 1.67 | 1.64 | 1.62 | 41.2% |
| (104) | mmtBumBioFBi | 1.69-1.70 | 1.66 | 1.64 | 29.4% |
| (105) | mmtBumTPtBuPAF | 1.66-1.67 | 1.64 | 1.62 | 39.0% |
| (106) | mmtBumTPoFBi-02 | 1.69-1.70 | 1.66 | 1.64 | 31.1% |
| (107) | mmtBumTPchPAF-02 | 1.67-1.68 | 1.64 | 1.62 | 41.0% |
| (108) | mmtBumTPoFBi-03 | 1.69-1.70 | 1.66 | 1.64 | 26.3% |
| (109) | mmtBumTPchPAF-03 | 1.69-1.70 | 1.66 | 1.64 | 36.8% |
| (110) | mmtBumTPoFBi-04 | 1.72-1.73 | 1.69 | 1.66 | 26.3% |
| (111) | mmtBumTPchPAF-04 | 1.71-1.72 | 1.67-1.68 | 1.65 | 36.8% |

First, a synthesis method of N,N-bis(4-cyclohexylphenyl)-9,9-dimethyl-9H-fluoren-2-amine (abbreviation: dchPAF) represented by Structural Formula (100) below is described.

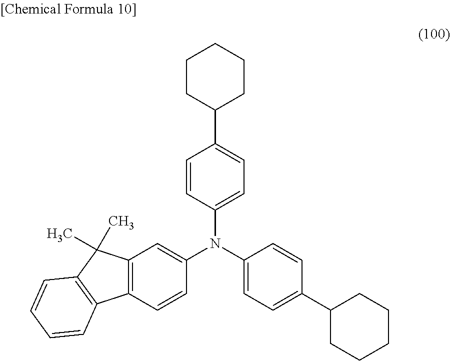 [SMILES: CC1(C)c2ccccc2-c2ccc(N(c3ccc(C4CCCCC4)cc3)c3ccc(C4CCCCC4)cc3)cc21]

In a three-neck flask were put 10.6 g (51 mmol) of 9,9-dimethyl-9H-fluoren-2-amine, 18.2 g (76 mmol) of 4-cyclohexyl-1-bromobenzene, 21.9 g (228 mmol) of sodium-tert-butoxide, and 255 mL of xylene. The mixture was degassed under reduced pressure, and then the air in the flask was replaced with nitrogen. The mixture was stirred while being heated to approximately 50° C. Then, 370 mg (1.0 mmol) of allylpalladium(II) chloride dimer (abbreviation: [(Allyl)PdCl]₂) and 1660 mg (4.0 mmol) of di-tert-butyl(1-methyl-2,2-diphenylcyclopropyl)phosphine (abbreviation: cBRIDP (registered trademark)) were added, and the mixture was heated at 120° C. for 5 hours. After that, the temperature of the flask was lowered to approximately 60° C., and approximately 4 mL of water was added to the mixture, so that a solid was precipitated. A precipitated solid was separated by filtration. The filtrate was concentrated, and the obtained solution was purified by silica gel column chromatography. The obtained solution was concentrated to give a concentrated toluene solution. The toluene solution was dropped into ethanol for reprecipitation. The precipitate was filtrated at approximately 10° C. and the obtained solid was dried at approximately 80° C. under reduced pressure, so that 10.1 g of a target white solid was obtained in a yield of 40%. The synthesis scheme of dchPAF is shown below.

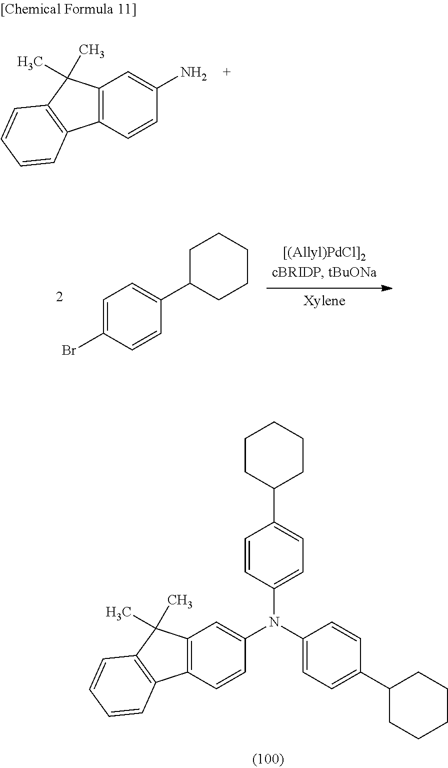 [SMILES: CC1(C)c2ccccc2-c2ccc(N)cc21 ; Brc1ccc(C2CCCCC2)cc1 ; CC1(C)c2ccccc2-c2ccc(N(c3ccc(C4CCCCC4)cc3)c3ccc(C4CCCCC4)cc3)cc21]

Analysis results of the obtained white solid by nuclear magnetic resonance spectroscopy (¹H-NMR) are shown below. The results revealed that dchPAF was synthesized.

¹H-NMR. δ (CDCl₃): 7.60 (d, 1H, J=7.5 Hz), 7.53 (d, 1H, J=8.0 Hz), 7.37 (d, 2H, J=7.5 Hz), 7.29 (td, 1H, J=7.5 Hz, 1.0 Hz), 7.23 (td, 1H, J=7.5 Hz, 1.0 Hz), 7.19 (d, 1H, J=1.5 Hz), 7.06 (m, 8H), 6.97 (dd, 1H, J=8.0 Hz, 1.5 Hz), 2.41-2.51 (brm, 2H), 1.79-1.95 (m, 8H), 1.70-1.77 (m, 2H), 1.33-1.45 (brm, 14H), 1.19-1.30 (brm, 2H).

Similarly, the organic compounds represented by Structural Formula (101) to Structural Formula (111) were synthesized.

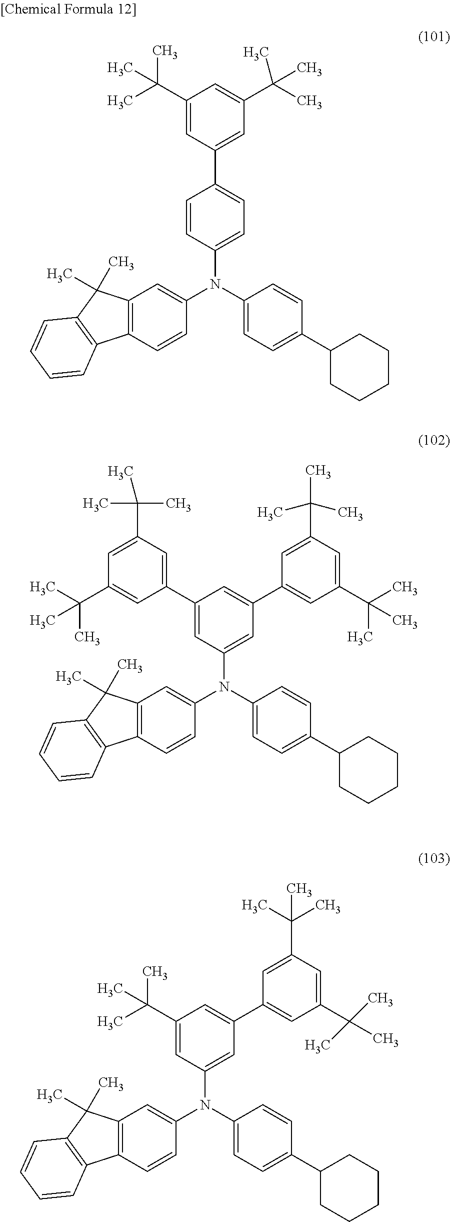 [SMILES: CC(C)(C)c1cc(-c2ccc(N(c3ccc(C4CCCCC4)cc3)c3ccc4c(c3)C(C)(C)c3ccccc3-4)cc2)cc(C(C)(C)C)c1 ; CC(C)(C)c1cc(-c2cc(-c3cc(C(C)(C)C)cc(C(C)(C)C)c3)cc(N(c3ccc(C4CCCCC4)cc3)c3ccc4c(c3)C(C)(C)c3ccccc3-4)c2)cc(C(C)(C)C)c1 ; CC(C)(C)c1cc(-c2cc(C(C)(C)C)cc(C(C)(C)C)c2)cc(N(c2ccc(C3CCCCC3)cc2)c2ccc3c(c2)C(C)(C)c2ccccc2-3)c1]

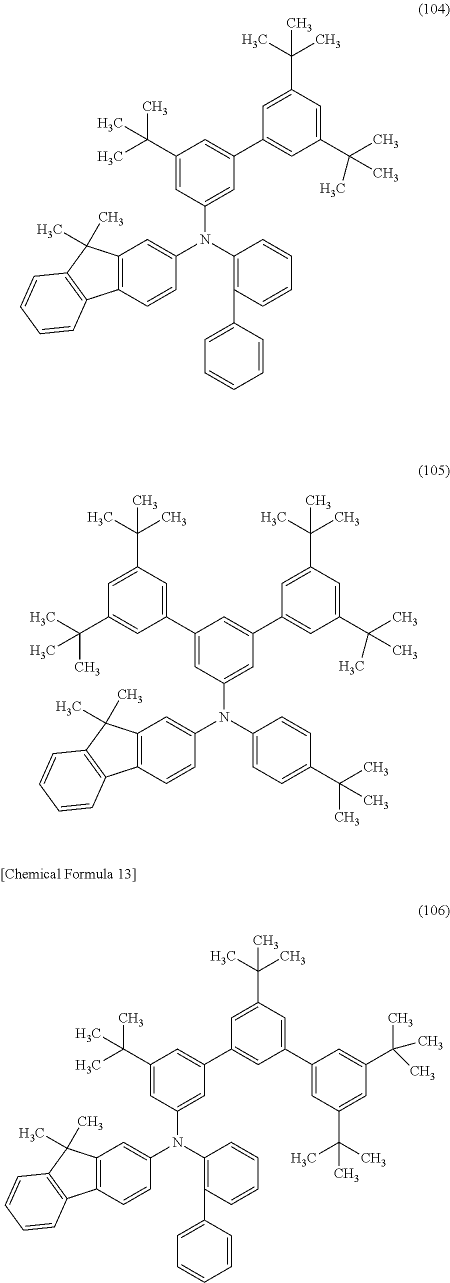 [SMILES: CC(C)(C)c1cc(-c2cc(C(C)(C)C)cc(C(C)(C)C)c2)cc(N(c2ccc3c(c2)C(C)(C)c2ccccc2-3)c2ccccc2-c2ccccc2)c1 ; CC(C)(C)c1ccc(N(c2cc(-c3cc(C(C)(C)C)cc(C(C)(C)C)c3)cc(-c3cc(C(C)(C)C)cc(C(C)(C)C)c3)c2)c2ccc3c(c2)C(C)(C)c2ccccc2-3)cc1 ; CC(C)(C)c1cc(-c2cc(N(c3ccc4c(c3)C(C)(C)c3ccccc3-4)c3ccccc3-c3ccccc3)cc(C(C)(C)C)c2)cc(-c2cc(C(C)(C)C)cc(C(C)(C)C)c2)c1]

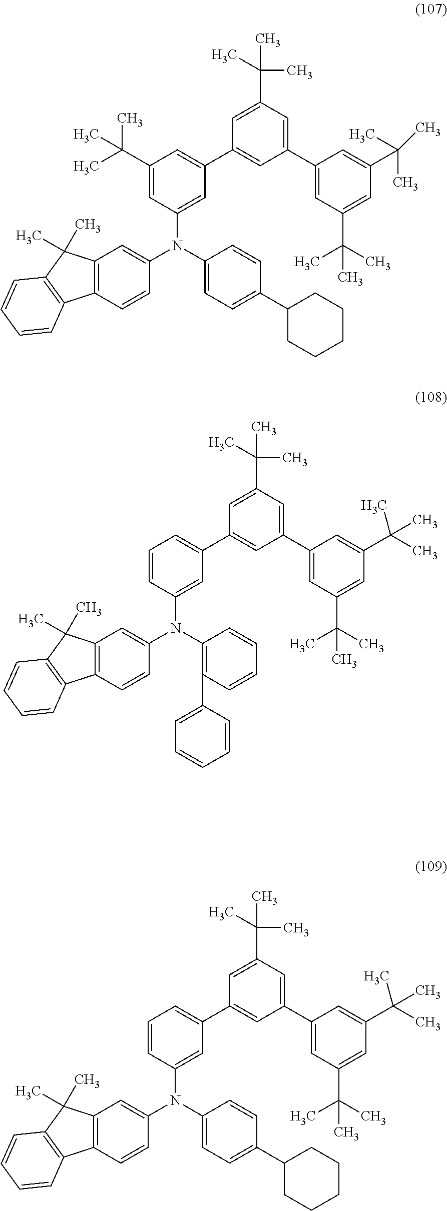 [SMILES: CC(C)(C)c1cc(-c2cc(N(c3ccc(C4CCCCC4)cc3)c3ccc4c(c3)C(C)(C)c3ccccc3-4)cc(C(C)(C)C)c2)cc(-c2cc(C(C)(C)C)cc(C(C)(C)C)c2)c1 ; CC(C)(C)c1cc(-c2cccc(N(c3ccc4c(c3)C(C)(C)c3ccccc3-4)c3ccccc3-c3ccccc3)c2)cc(-c2cc(C(C)(C)C)cc(C(C)(C)C)c2)c1 ; CC(C)(C)c1cc(-c2cccc(N(c3ccc(C4CCCCC4)cc3)c3ccc4c(c3)C(C)(C)c3ccccc3-4)c2)cc(-c2cc(C(C)(C)C)cc(C(C)(C)C)c2)c1]

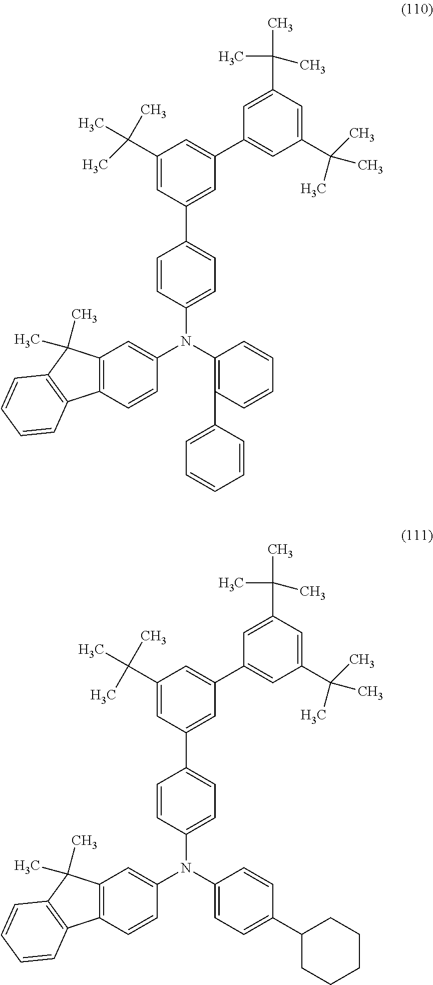 [SMILES: CC(C)(C)c1cc(-c2ccc(N(c3ccc4c(c3)C(C)(C)c3ccccc3-4)c3ccccc3-c3ccccc3)cc2)cc(-c2cc(C(C)(C)C)cc(C(C)(C)C)c2)c1 ; CC(C)(C)c1cc(-c2ccc(N(c3ccc(C4CCCCC4)cc3)c3ccc4c(c3)C(C)(C)c3ccccc3-4)cc2)cc(-c2cc(C(C)(C)C)cc(C(C)(C)C)c2)c1]

Analysis results of these organic compounds by nuclear magnetic resonance spectroscopy (¹H-NMR) are shown below. The glass transition temperatures of some of the organic compounds are also shown.

The following is results of N-[(3′,5′-ditertiarybutyl)-1,1′-biphenyl-4-yl]-N-(4-cyclohexylphenyl)-9,9-dimethyl-9H-fluoren-2-amine (abbreviation: mmtBuBichPAF) represented by Structural Formula (101).

¹H-NMR. δ (CDCl₃): 7.63 (d, 1H, J=7.5 Hz), 7.57 (d, 1H, J=8.0 Hz), 7.44-7.49 (m, 2H), 7.37-7.42 (m, 4H), 7.31 (td, 1H, J=7.5 Hz, 2.0 Hz), 7.23-7.27 (m, 2H), 7.15-7.19 (m, 2H), 7.08-7.14 (m, 4H), 7.05 (dd, 1H, J=8.0 Hz, 2.0 Hz), 2.43-2.53 (brm, 1H), 1.81-1.96 (m, 4H), 1.75 (d, 1H, J=12.5 Hz), 1.32-1.48 (m, 28H), 1.20-1.31 (brm, 1H).

Note that the glass transition temperature of mmtBuBichPAF represented by Structural Formula (101) was 102° C.

The following is results of N-(3,3″,5′,5″-tetra-tert-butyl-1,1′:3′,1″-terphenyl-5′-yl)-N-(4-cyclohexylphenyl)-9,9-dimethyl-9H-fluoren-2-amine (abbreviation: mmtBumTPchPAF) represented by Structural Formula (102).

¹H-NMR. δ (CDCl₃): =7.63 (d, J=6.6 Hz, 1H), 7.58 (d, J=8.1 Hz, 1H), 7.42-7.37 (m, 4H), 7.36-7.09 (m, 14H), 2.55-2.39 (m, 1H), 1.98-1.20 (m, 51H).

Note that the glass transition temperature of mmtBumTPchPAF represented by Structural Formula (102) was 124° C.

The following is results of N-[(3,3′,5′-tri-tert-butyl)-1,1′-biphenyl-5-yl]-N-(4-cyclohexylphenyl)-9,9-dimethyl-9H-fluoren-2-amine (abbreviation: mmtBumBichPAF) represented by Structural Formula (103).

¹H-NMR. δ (CDCl₃): 7.63 (d, 1H, J=7.5 Hz), 7.56 (d, 1H, J=8.5 Hz), 7.37-40 (m, 2H), 7.27-7.32 (m, 4H), 7.22-7.25 (m, 1H), 7.16-7.19 (brm, 2H), 7.08-7.15 (m, 4H), 7.02-7.06 (m, 2H), 2.43-2.51 (brm, 1H), 1.80-1.93 (brm, 4H), 1.71-1.77 (brm, 1H), 1.36-1.46 (brm, 10H), 1.33 (s, 18H), 1.22-1.30 (brm, 10H).

Note that the glass transition temperature of mmtBumBichPAF represented by Structural Formula (103) was 103° C.

The following is results of N-(1,1′-biphenyl-2-yl)-N-[(3,3′,5′-tri-tert-butyl)-1,1′-biphenyl-5-yl]-9,9-dimethyl-9H-fluoren-2-amine (abbreviation: mmtBumBioFBi) represented by Structural Formula (104).

¹H-NMR. δ (CDCl₃): 7.57 (d, 1H, J=7.5 Hz), 7.40-7.47 (m, 2H), 7.32-7.39 (m, 4H), 7.27-7.31 (m, 2H), 7.27-7.24 (m, 5H), 6.94-7.09 (m, 6H), 6.83 (brs, 2H), 1.33 (s, 18H), 1.32 (s, 6H), 1.20 (s, 9H).

Note that the glass transition temperature of mmtBumBioFBi represented by Structural Formula (104) was 102° C.

The following is results of N-(4-tert-butylphenyl)-N-(3,3″,5′,5″-tetra-tert-butyl-1,1′:3′,1″-terphenyl-5′-yl)-9,9-dimethyl-9H-fluoren-2-amine (abbreviation: mmtBumTPtBuPAF) represented by Structural Formula (105).

¹H-NMR. δ (CDCl₃): 7.64 (d, 1H, J=7.5 Hz), 7.59 (d, 1H, J=8.0 Hz), 7.38-7.43 (m, 4H), 7.29-7.36 (m, 8H), 7.24-7.28 (m, 3H), 7.19 (d, 2H, J=8.5 Hz), 7.13 (dd, 1H, J=1.5 Hz, 8.0 Hz), 1.47 (s, 6H), 1.32 (s, 45H).

Note that the glass transition temperature of mmtBumTPtBuPAF represented by Structural Formula (105) was 123° C.

The following is results of N-(1,1′-biphenyl-2-yl)-N-(3,3″,5′,5″-tetra-tert-butyl-1,1′:3′,1″-terphenyl-5-yl)-9,9-dimethyl-9H-fluoren-2-amine (abbreviation: mmtBumTPoFBi-02) represented by Structural Formula (106).

¹H-NMR. δ (CDCl₃): 7.56 (d, 1H, J=7.4 Hz), 7.50 (dd, 1H, J=1.7 Hz), 7.33-7.46 (m, 11H), 7.27-7.29 (m, 2H), 7.22 (dd, 1H, J=2.3 Hz), 7.15 (d, 1H, J=6.9 Hz), 6.98-7.07 (m, 7H), 6.93 (s, 1H), 6.84 (d, 1H, J=6.3 Hz), 1.38 (s, 9H), 1.37 (s, 18H), 1.31 (s, 6H), 1.20 (s, 9H).

Note that the glass transition temperature of mmtBumTPoFBi-02 represented by Structural Formula (106) was 126° C.

The following is results of N-(4-cyclohexylphenyl)-N-(3,3″,5′,5″-tetra-tert-butyl-1,1′:3′,1″-terphenyl-5-yl)-9,9-dimethyl-9H-fluoren-2-amine (abbreviation: mmtBumTPchPAF-02) represented by Structural Formula (107).

¹H-NMR. δ (CDCl₃): 7.62 (d, 1H, J=7.5 Hz), 7.56 (d, 1H, J=8.0 Hz), 7.50 (dd, 1H, J=1.7 Hz), 7.46-7.47 (m, 2H), 7.43 (dd, 1H, J=1.7 Hz), 7.37-7.39 (m, 3H), 7.29-7.32 (m, 2H), 7.23-7.25 (m, 2H), 7.20 (dd, 1H, J=1.7 Hz), 7.09-7.14 (m, 5H), 7.05 (dd, 1H, J=2.3 Hz), 2.46 (brm, 1H), 1.83-1.88 (m, 4H), 1.73-1.75 (brm, 1H), 1.42 (s, 6H), 1.38 (s, 9H), 1.36 (s, 18H), 1.29 (s, 9H).

Note that the glass transition temperature of mmtBumTPchPAF-02 represented by Structural Formula (107) was 127° C.

The following is results of N-(1,1′-biphenyl-2-yl)-N-(3″,5′,5″-tri-tert-butyl-1,1′:3′,1″-terphenyl-5-yl)-9,9-dimethyl-9H-fluoren-2-amine (abbreviation: mmtBumTPoFBi-03) represented by Structural Formula (108).

¹H-NMR. δ (CDCl₃): 7.55 (d, 1H, J=7.4 Hz), 7.50 (dd, 1H, J=1.7 Hz), 7.42-7.43 (m, 3H), 7.27-7.39 (m, 10H), 7.18-7.25 (m, 4H), 7.00-7.12 (m, 4H), 6.97 (dd, 1H, J=6.3 Hz, 1.7 Hz), 6.93 (d, 1H, J=1.7 Hz), 6.82 (dd, 1H, J=7.3 Hz, 2.3 Hz), 1.37 (s, 9H), 1.36 (s, 18H), 1.29 (s, 6H).

The following is results of N-(4-cyclohexylphenyl)-N-(3″,5′,5″-tri-tert-butyl-1,1′:3′,1″-terphenyl-5-yl)-9,9-dimethyl-9H-fluoren-2-amine (abbreviation: mmtBumTPchPAF-03) represented by Structural Formula (109).

¹H-NMR. δ (CDCl₃): 7.62 (d, 1H, J=7.5 Hz), 7.56 (d, 1H, J=8.6 Hz), 7.51 (dd, 1H, J=1.7 Hz), 7.48 (dd, 1H, J=1.7 Hz), 7.46 (dd, 1H, J=1.7 Hz), 7.42 (dd, 1H, J=1.7 Hz), 7.37-7.39 (m, 4H), 7.27-7.33 (m, 2H), 7.23-7.25 (m, 2H), 7.05-7.13 (m, 7H), 2.46 (brm, 1H), 1.83-1.90 (m, 4H), 1.73-1.75 (brm, 1H), 1.41 (s, 6H), 1.37 (s, 9H), 1.35 (s, 18H).

The following is results of N-(1,1′-biphenyl-2-yl)-N-(3″,5′,5″-tri-tert-butyl-1,1′:3′,1″-terphenyl-4-yl)-9,9-dimethyl-9H-fluoren-2-amine (abbreviation: mmtBumTPoFBi-04) represented by Structural Formula (110).

¹H-NMR. δ (CDCl₃): 7.54-7.56 (m, 1H), 7.53 (dd, 1H, J=1.7 Hz), 7.50 (dd, 1H, J=1.7 Hz), 7.27-7.47 (m, 12H), 7.23 (dd, 1H, J=6.3 Hz, 1.2 Hz), 7.18-7.19 (m, 2H), 7.08-7.00 (m, 5H), 6.88 (d, 1H, J=1.7 Hz) 6.77 (dd, 1H, J=8.0 Hz, 2.3 Hz), 1.42 (s, 9H), 1.39 (s, 18H), 1.29 (s, 6H).

The following is results of N-(4-cyclohexylphenyl)-N-(3″,5′,5″-tri-tert-butyl-1,1′:3′,1″-terphenyl-4-yl)-9,9-dimethyl-9H-fluoren-2-amine (abbreviation: mmtBumTPchPAF-04) represented by Structural Formula (111).

¹H-NMR. δ (CDCl₃): 7.63 (d, 1H, J=7.5 Hz), 7.52-7.59 (m, 7H), 7.44-7.45 (m, 4H), 7.39 (d, 1H, J=7.4 Hz), 7.31 (dd, 1H, J=7.4 Hz), 7.19 (d, 2H, J=6.6 Hz), 7.12 (m, 4H), 7.07 (d, 1H, J=9.7 Hz), 2.48 (brm, 1H), 1.84-1.93 (brm, 4H), 1.74-1.76 (brm, 1H), 1.43 (s, 18H), 1.39 (brm, 19H) 1.24-1.30 (brm, 1H).

### REFERENCE NUMERALS

101: first electrode, 102: second electrode, 103a: EL layer, 103b: EL layer, 103c: EL layer, 103: EL layer, 104: charge-generation layer, 105: layer including organic compound, 109: buffer layer, 111: hole-injection layer, 112a: first hole-transport layer, 112b: second hole-transport layer, 113: light-emitting layer, 114: electron-transport layer, 115: electron-injection layer, 116: hole-transport layer, 117: active layer, 118: electron-transport layer, 119: buffer layer, 201: substrate, 202a: insulating layer, 202b: insulating layer, 202: insulating layer, 203B: light-emitting device, 203G: light-emitting device, 203R: light-emitting device, 203W: light-emitting device, 204: insulating layer, 205: substrate, 206B: color filter, 206G: color filter, 206R: color filter, 207: space, 208: adhesive layer, 209: black matrix, 210: transistor, 211: first electrode, 212G: conductive layer, 212R: conductive layer, 213B: EL layer, 213G: EL layer, 213R: EL layer, 213: EL layer, 215: second electrode, 220B: optical path length, 220G: optical path length, 220R: optical path length, 301: first substrate, 302: pixel portion, 303: circuit portion, 304a: circuit portion, 304b: circuit portion, 305: sealant, 306: second substrate, 307: lead wiring, 308: FPC, 309: transistor, 310: transistor, 311: transistor, 312: transistor, 313: first electrode, 314: insulating layer, 315: EL layer, 316: second electrode, 317: organic EL device, 318: space, 320: transistor, 321: conductive layer, 322a: conductive layer, 322b: conductive layer, 323: conductive layer, 324: insulating layer, 325: insulating layer, 326: insulating layer, 327i: channel formation region, 327n: low-resistance region, 327: semiconductor layer, 328: insulating layer, 330: transistor, 331: conductive layer, 332a: conductive layer, 332b: conductive layer, 333: conductive layer, 334: insulating layer, 335: insulating layer, 337: semiconductor layer, 338: insulating layer, 401: first electrode, 402: EL layer, 403: second electrode, 405: insulating layer, 406: conductive layer, 407: adhesive layer, 416: conductive layer, 420: substrate, 422: adhesive layer, 423: barrier layer, 424: insulating layer, 450: organic EL device, 490a: substrate, 490b: substrate, 490c: barrier layer, 500A: display apparatus, 500B: display apparatus, 500C: display apparatus, 500D: display apparatus, 500E: display apparatus, 510: light-receiving device, 511: pixel electrode, 512: buffer layer, 513: active layer, 514: buffer layer, 515: common electrode, 520: fingerprint, 521: light, 521B: light, 521G: light, 521R: light, 522: light, 531: transistor, 532B: transistor, 532G: transistor, 532: transistor, 533: insulating layer, 534: insulating layer, 551: substrate, 552: substrate, 553: adhesive layer, 554: light-blocking layer, 555: functional layer, 580SR: light-emitting and light-receiving device, 590B: light-emitting device, 590G: light-emitting device, 590IR: light-emitting device, 590R: light-emitting device, 590: light-emitting device, 591B: pixel electrode, 591G: pixel electrode, 591: pixel electrode, 593B: light-emitting layer, 593G: light-emitting layer, 593R: light-emitting layer, 593: light-emitting layer, 595: protective layer, 800: substrate, 801: first electrode, 802: EL layer, 803: second electrode, 805: second buffer layer, 811: hole-injection layer, 812a: first hole-transport layer, 812b: second hole-transport layer, 813: light-emitting layer, 814: electron-transport layer, 815: electron-injection layer, 816: first buffer layer, 911: housing, 912: light source, 913: sensing stage, 914: imaging device, 915: light-emitting portion, 916: light-emitting portion, 917: light-emitting portion, 921: housing, 922: operation button, 923: sensor portion, 924: light source, 925: imaging device, 931: housing, 932: operation panel, 933: transport mechanism, 934: monitor, 935: sensing unit, 936: test specimen, 937: imaging device, 938: light source, 981: housing, 982: display portion, 983: operation button, 984: external connection port, 985: speaker, 986: microphone, 987: first camera, 988: second camera, 7000: display portion, 7001: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 7600: portable information terminal, 7601: housing, 7602: hinge, 7650: portable information terminal, 7651: non-display portion, 7800: portable information terminal, 7801: band, 7802: input-output terminal, 7803: operation button, 7804: icon, 7805: battery, 9700: automobile, 9701: car body, 9702: wheel, 9703: windshield, 9704: light, 9705: fog lamp, 9710: display portion, 9711: display portion, 9712: display portion, 9713: display portion, 9714: display portion, 9715: display portion, 9721: display portion, 9722: display portion, 9723: display portion

1. A light-emitting device comprising:
a first electrode;
a first layer over the first electrode;
a second layer over the first layer;
a light-emitting layer over the second layer; and
a second electrode over the light-emitting layer,
wherein the first layer comprises a first organic compound,
wherein the second layer comprises a second organic compound,
wherein a proportion of carbon atoms forming bonds by sp³ hybrid orbitals to the total number of carbon atoms in the first organic compound is higher than or equal to 23% and lower than or equal to 55%, and
wherein the second organic compound comprises fluorine.

2. The light-emitting device according to claim 1,
wherein a refractive index of a layer comprising the first organic compound with respect to light with a wavelength of 633 nm is higher than or equal to 1.45 and lower than or equal to 1.70.

3. A light-emitting device comprising:
a first electrode;
a first layer over the first electrode;
a second layer over the first layer;
a light-emitting layer over the second layer; and
a second electrode over the light-emitting layer,
wherein the first layer comprises a first organic compound,
wherein the second layer comprises a second organic compound,
wherein a glass transition temperature of the first organic compound is higher than or equal to 90° C.,
wherein a refractive index of a layer comprising the first organic compound with respect to light with a wavelength of 633 nm is higher than or equal to 1.45 and lower than or equal to 1.70, and
wherein the second organic compound comprises fluorine.

4. The light-emitting device according to claim 1,
wherein the first organic compound is an amine compound.

5. The light-emitting device according to claim 4,
wherein the first organic compound is a monoamine compound.

6. A light-emitting device comprising:
a first electrode;
a first layer over the first electrode;
a second layer over the first layer;
a light-emitting layer over the second layer; and
a second electrode over the light-emitting layer,
wherein the first layer comprises a first organic compound,
wherein the second layer comprises a second organic compound,
wherein the first organic compound is a monoamine compound,
wherein a refractive index of a layer comprising the first organic compound with respect to light with a wavelength of 633 nm is higher than or equal to 1.45 and lower than or equal to 1.70, and
wherein the second organic compound comprises fluorine.

7. The light-emitting device according to claim 1,
wherein the second layer further comprises a third organic compound, and
wherein a HOMO level of the third organic compound is lower than a HOMO level of the first organic compound.

8. The light-emitting device according to claim 1,
further comprising a third layer,
wherein the third layer is positioned between the second layer and the light-emitting layer,
wherein the third layer comprises a third organic compound, and
wherein a HOMO level of the third organic compound is lower than a HOMO level of the first organic compound.

9. The light-emitting device according to claim 8,
wherein the second layer further comprises the third organic compound.

10. A light-emitting device comprising:
a first electrode;
a first layer over the first electrode;
a second layer over the first layer;
a third layer over the second layer;
a light-emitting layer over the third layer; and
a second electrode over the light-emitting layer,
wherein the first layer comprises a first organic compound,
wherein the second layer comprises a second organic compound,
wherein the third layer comprises a third organic compound,
wherein a HOMO level of the third organic compound is lower than a HOMO level of the first organic compound,
wherein a refractive index of a layer comprising the first organic compound is lower than a refractive index of a layer comprising the third organic compound, and
wherein the second organic compound comprises fluorine.

11-18. (canceled)

19. The light-emitting device according to claim 10,
wherein a proportion of carbon atoms forming bonds by sp³ hybrid orbitals to the total number of carbon atoms in the third organic compound is higher than or equal to 23% and lower than or equal to 55%.

20-21. (canceled)

22. The light-emitting device according to claim 1,
wherein the first layer is in contact with the second layer.

23. The light-emitting device according to claim 10,
further comprising a fourth layer,
wherein the fourth layer is positioned between the first electrode and the first layer, and
wherein the fourth layer comprises the first organic compound and the second organic compound.

24. The light-emitting device according to claim 23,
wherein the fourth layer is in contact with the first electrode.

25. The light-emitting device according to claim 24,
wherein the fourth layer is in contact with the first layer.

26. The light-emitting device according to claim 1,
wherein a molecular weight of the first organic compound is greater than or equal to 650 and less than or equal to 1200.

27. The light-emitting device according to claim 1,
wherein the first organic compound is a triaryl monoamine compound.

28. The light-emitting device according to claim 1,
wherein an integral value of signals lower than 4 ppm exceeds an integral value of signals 4 ppm or higher in a result of ¹H-NMR measurement of the first organic compound.

29. (canceled)

30. The light-emitting device according to claim 1,
wherein the first organic compound comprises at least one of an alkyl group comprising 3 to 8 carbon atoms and a cycloalkyl group comprising 6 to 12 carbon atoms.

31. The light-emitting device according to claim 1,
wherein the second organic compound comprises a cyano group,
wherein a LUMO level of the second organic compound is lower than or equal to −5.0 eV,
wherein the second organic compound shows an electron-accepting property with respect to the first organic compound, and
wherein the second organic compound comprises no metal element.

32-38. (canceled)
